(19) United States
(12) Patent Application Publication
(10) Pub. No.: US 2023/0335660 A1
(43) Pub. Date: Oct. 19, 2023

(54) SOLAR CELL DEVICE AND OPTICAL DEVICE

(71) Applicant: OSAKA UNIVERSITY, Osaka (JP)

(72) Inventor: Hiroyuki YOSHIDA, Suita-shi (JP)

(73) Assignee: OSAKA UNIVERSITY, Osaka (JP)

(21) Appl. No.: 17/757,987

(22) PCT Filed: Dec. 25, 2020
(86) PCT No.: PCT/JP2020/048870

§ 371 Date: Jun. 24, 2022

(30) Foreign Application Priority Data
Dec. 26, 2019 (JP) 2019-236817

(51) Int. Cl. H01L 31/054

(52) U.S. Cl. CPC H01L 31/0547

(57) ABSTRACT

A solar cell device (100) includes an optical waveguide section (1), a solar cell (5), and a light diffracting section (3). The light diffracting section (3) is disposed in a different layer level from the optical waveguide section (1) and is opposite to the optical waveguide section (1). The light diffracting section (3) diffracts light (LT2) in at least a portion of a wavelength band of light (LT1) incident to the light diffracting section (3) toward the optical waveguide section (1) and allows the light (LT2) in at least the portion of the wavelength band to enter the optical waveguide section (1). The optical waveguide section (1) guides the light (LT2) diffracted by the light diffracting section (3) and entering inside the optical waveguide section (1). The solar cell (5) receives the light (LT2) guided by the optical waveguide section (1) and converts energy of the light (LT2) to electrical power.

### TECHNICAL FIELD

The present invention relates to a solar cell device and an optical device.

### BACKGROUND ART

Non-patent Literature 1 describes luminescent solar concentrators. In each of the luminescent solar concentrators, a large number of phosphors are included in a window glass (optical waveguide section) as a waveguide. The phosphors then absorb sunlight and emit light. Furthermore, a portion of the light emitted by the phosphors is guided through the window glass and received by a solar cell installed in a window frame. As a result, the solar cell generates electricity.

### CITATION LIST

### Non-Patent Literature

### Non-patent Literature 1

F. Meinardi, F. Bruni and S. Brovelli, “Luminescent solar concentrators for building-integrated photovoltaics”, Nature Reviews Materials, Volume 2, Article Number 17072 (2017)

### SUMMARY OF INVENTION

### Technical Problem

However, the luminous efficiency of a phosphor is not 100%. Additionally, the light emitted by the phosphor is absorbed back into the phosphor and used as energy for luminescence. Therefore, in the above luminescent solar concentrator, the light quantity emitted by the phosphors and guided toward the solar cell may not be sufficient. That is, the light quantity received by the solar cell may not be sufficient. As a result, an amount of electricity generated by the solar cell may also not be sufficient.

That is, in the above luminescent solar concentrator, the phosphors may cause a disadvantage.

The present invention was made in view of the above problem, and an objective thereof is to provide a solar cell device and an optical device capable of guiding light from an optical waveguide section toward a solar cell without including a phosphor in the optical waveguide section.

### Solution to Problem

A solar cell device according to an aspect of the present invention includes an optical waveguide section, a solar cell, and a light diffracting section. The light diffracting section is disposed in a different layer level from the optical waveguide section and is opposite to the optical waveguide section. The light diffracting section diffracts light in at least a portion of a wavelength band of light incident to the light diffracting section toward the optical waveguide section according to a distribution of orientations of the optic axes, and allows the light in at least the portion of the wavelength band to enter the optical waveguide section. The optical waveguide section guides the light entering inside the optical waveguide section by diffraction by the light diffracting section. The solar cell the light guided by the optical waveguide section and converts energy of the received light to electrical power.

In the solar cell device of the present invention, the light diffracting section preferably has optical anisotropy and a plurality of optic axes. The light diffracting section preferably diffracts the light in at least the portion of the wavelength band of the light incident to the light diffracting section toward the optical waveguide section according to a distribution of orientations of the optic axes.

In the solar cell device of the present invention, the optical waveguide section preferably transmits light including visible light. The light diffracting section preferably reflects and diffracts the light in at least the portion of the wavelength band of the light incident to the light diffracting section through the optical waveguide section toward the optical waveguide section. The light diffracting section preferably transmits light in at least a portion of a wavelength band of a visible light region of the light incident to the light diffracting section. The optical waveguide section preferably guides the light entering inside the optical waveguide section by reflection and diffraction by the light diffracting section.

In the solar cell device of the present invention, the light diffracting section preferably transmits and diffracts transmits and diffracts the light in at least the portion of the wavelength band of the light incident to the light diffracting section toward the optical waveguide section. The optical waveguide section preferably guides the light entering inside the optical waveguide section by transmission and diffraction by the light diffracting section.

The solar cell device of the present invention preferably further includes a light concentrating section. The optical waveguide section is preferably disposed between the light diffracting section and the light concentrating section. The light diffracting section preferably covers a portion of a main surface of the optical waveguide section. The light concentrating section preferably allows, while concentrating toward the light diffracting section, the light in at least a portion of a wavelength band of light incident to the light concentrating section through the optical waveguide section from a side on which the light diffracting section is located to be incident to the light diffracting section.

The solar cell device of the present invention preferably includes a plurality of light diffracting sections. The light diffracting sections are preferably layered. The light diffracting sections preferably diffract either or both of light rays in mutually different wavelength bands and light rays having mutually different polarization toward the optical waveguide section, and allow the light rays to enter inside the optical waveguide section.

The solar cell device of the present invention preferably further includes at least one light reflecting section. The at least one light reflecting section preferably reflects the light entering the optical waveguide section from the light diffracting section toward the optical waveguide section so that the light entering the optical waveguide section is totally reflected in the optical waveguide section. Or, the at least one light reflecting section preferably reflects, of the light entering the optical waveguide section from the light diffracting section, light emitted from the optical waveguide section toward the optical waveguide section so that the light emitted from the optical waveguide section is totally reflected in the optical waveguide section.

In the solar cell device of the present invention, a refractive index of the at least one light reflecting section is preferably smaller than a refractive index of the optical waveguide section.

In the solar cell device of the present invention, the light reflecting section is preferably a mirror with a dependency on a wavelength of light in light reflection and a dependency on an incident angle of light in the light reflection.

In the solar cell device of the present invention, the light diffracting section preferably diffracts the light in at least the portion of the wavelength band toward the optical waveguide section so that the light guided by the optical waveguide section is concentrated toward the solar cell, and allows the light in at least the portion of the wavelength band to enter inside the optical waveguide section.

The solar cell device of the present invention preferably includes a plurality of solar cells, and a plurality of light diffracting sections arranged on the same layer level as each other. The optical waveguide section is preferably divided into a plurality of optical waveguide regions. The solar cells are preferably arranged corresponding to the respective optical waveguide regions. The light diffracting sections are preferably arranged corresponding to the respective optical waveguide regions. The light diffracting sections each are preferably opposite to a corresponding one of the optical waveguide regions. The light diffracting sections preferably each diffract light toward the corresponding one of the optical waveguide regions so that the light is guided inside the corresponding one of the optical waveguide regions toward a corresponding one of the solar cells and allows the light to enter inside the corresponding one of the optical waveguide regions. The solar cells preferably each receive the light guided by the corresponding one of the optical waveguide regions.

In the solar cell device of the present invention, the light diffracting section preferably includes a plurality of helical structures. Helical axes of the helical structures are preferably, substantially perpendicular to the optical waveguide section and spatial phases of two or more of the helical structures are mutually different. Or, the helical axes of the helical structures are preferably inclined relative to the optical waveguide section.

An optical device according to another aspect of the present invention includes an optical waveguide section, a light receiving body, and a light diffracting section. The light diffracting section is disposed in a different layer level from the optical waveguide section and located opposite to the optical waveguide section. The light diffracting section has optical anisotropy and a plurality of optic axes. The light diffracting section diffracts light in at least a portion of a wavelength band of light incident to the light diffracting section toward the optical waveguide section according to a distribution of orientations of the optic axes, and allows the light in at least the portion of the wavelength band to enter the optical waveguide section. The optical waveguide section guides the light entering inside the optical waveguide section by diffraction by the light diffracting section. The light receiving body receives the light guided by the optical waveguide section.

In the optical device of the present invention, the light diffracting section is preferably made of liquid crystal.

### Advantageous Effects of Invention

According to the present invention, an optical device and a solar cell device can be provided which can guide light from an optical waveguide section toward a solar cell without including a phosphor in the optical waveguide section.

### BRIEF DESCRIPTION OF DRAWINGS

FIG. 1 is a schematic cross-sectional view of an optical device according to a first embodiment of the present invention.

FIG. 2 is a schematic cross-sectional view of a structure of a light diffraction layer according to the first embodiment.

FIG. 3A is a schematic plan view of the optical device according to the first embodiment. FIG. 3B is a diagram illustrating an incident angle and a reflection angle of light in the light diffraction layer according to the first embodiment.

FIG. 4 is a diagram illustrating a distribution of optic axes of the light diffraction layer according to the first embodiment.

FIG. 5 is a diagram illustrating light transmittance characteristics of the light diffraction layer according to the first embodiment.

FIG. 6A is a schematic cross-sectional view of a variation of the light diffraction layer according to the first embodiment. FIG. 6B is a diagram illustrating light transmittance characteristics of the variation of the light diffraction layer according to the first embodiment.

FIG. 7 is a schematic cross-sectional view of the structure of the light diffraction layer in the optical device according to the variation of the first embodiment.

FIG. 8 is a diagram schematically illustrating a distribution of optic axes of the light diffraction layer in the optical device according to the variation of the first embodiment.

FIG. 9 is a schematic cross-sectional view of an optical device according to a second embodiment of the present invention.

FIG. 10 is a schematic plan view of a light diffraction layer according to the second embodiment.

FIG. 11 is a schematic cross-sectional view of an optical device according to a third embodiment of the present invention.

FIG. 12 is a schematic plan view of an optical device according to a fourth embodiment of the present invention.

FIG. 13 is a schematic plan view of an optical device according to a fifth embodiment of the present invention.

FIG. 14 is a schematic plan view of the optical device according to a variation of the fifth embodiment.

FIG. 15 is a schematic cross-sectional view of an optical device according to a sixth embodiment of the present invention.

FIG. 16 is a schematic cross-sectional view of a light diffraction layer according to the sixth embodiment.

FIG. 17 is a diagram schematically illustrating a distribution of optic axes of the light diffraction layer according to the sixth embodiment.

FIG. 18 is a schematic cross-sectional view of the light diffraction layer according to a variation of the sixth embodiment.

FIG. 19 is a diagram schematically illustrating a distribution of optic axes of the light diffraction layer according to the variation of the sixth embodiment.

FIG. 20 is a schematic cross-sectional view of an optical device according to a seventh embodiment of the present invention.

FIG. 21 is a schematic plan view of the optical device according to the seventh embodiment.

FIGS. 22A to 22C are diagrams for describing operation of the optical device according to the seventh embodiment.

FIG. 23A is a schematic cross-sectional view of an example of a light diffracting section and a retention layer according to the seventh embodiment. FIG. 23B is a schematic cross-sectional view of another example of the light diffracting section and the retention layer according to the seventh embodiment.

FIG. 24 is a schematic cross-sectional view of a light concentration unit of a light concentration layer according to the seventh embodiment.

FIG. 25A is a schematic perspective view of reflective surfaces of the light concentration layer according to the seventh embodiment. FIG. 25B is a schematic plan view of a reflective surface of the light concentration layer according to the seventh embodiment.

FIG. 26 is a schematic cross-sectional view of the optical device according to a variation of the seventh embodiment.

FIG. 27A to 27C are diagrams for describing operation of the optical device according to the variation of the seventh embodiment.

FIG. 28 is a diagram illustrating light transmittance characteristics (near-infrared wavelength band) of a light diffraction layer according to a practical example of the present invention.

FIG. 29 is a diagram illustrating light transmittance characteristics (visible wavelength band) of the light diffraction layer according to the practical example.

FIG. 30 is a diagram illustrating facilities for performing operation experiments with the optical device including the light diffraction layer and the optical waveguide layer according to the present practical example.

### DESCRIPTION OF EMBODIMENTS

The following describes embodiments of the present invention with reference to the accompanying drawings. In the drawings, elements that are the same or equivalent are labeled the same reference signs and description thereof is not repeated. Also in the drawings, mutually orthogonal X, Y, and Z axes are shown for ease of understanding. Note that for simplification of the drawings, slanted lines indicating cross-sections are appropriately omitted.

### First Embodiment

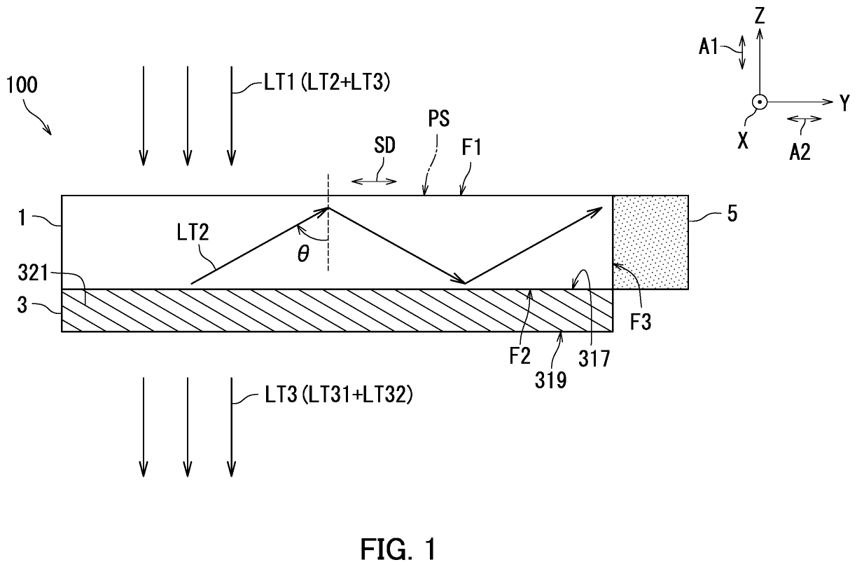

An optical device 100 according to a first embodiment of the present invention is described with reference to FIGS. 1 to 6B. First, the optical device 100 is described with reference to FIG. 1. FIG. 1 is a schematic cross-sectional view of the optical device 100 according to the first embodiment.

As illustrated in FIG. 1, the optical device 100 includes an optical waveguide layer 1, a light diffraction layer 3, and a light receiving body 5. The optical waveguide layer 1 corresponds to an example of an “optical waveguide section”. The light diffraction layer 3 corresponds to an example of a “light diffracting section”.

The optical waveguide layer 1 transmits light LT1. The optical waveguide layer 1 preferably includes visible light. In this preferable example, the optical waveguide layer 1 is crystal clear and transparent. In the present specification, “transparent” preferably means colorless and transparent. However, “transparent” may mean semi-transparent or colored and transparent. For example, the optical waveguide layer 1 includes a transparent glass plate or a transparent synthetic resin plate. For example, the optical waveguide layer 1 may include flexible transparent synthetic resin. The optical waveguide layer 1 may have any shape. For example, the optical waveguide layer 1 may be curved. The refractive index of the optical waveguide layer 1 is greater than that of air, for example. For example, the optical waveguide layer 1 functions as window glass.

The optical waveguide layer 1 guides light LT2 which satisfies an optical waveguide condition in the optical waveguide layer 1. Therefore, the light LT2 is propagated inside the optical waveguide layer 1 while being repeatedly reflected. Specifically, the light LT2 is propagated inside the optical waveguide layer 1 while being totally reflected in a repeated manner. Inside the optical waveguide layer 1, the light LT2 being guided is synonymous with the light LT2 being propagated in the present specification. The optical waveguide condition indicates that an approach angle θ of the light LT2 entering the optical waveguide layer 1 by diffraction (specifically, reflected and diffracted) by the light diffraction layer 3 is equal to or greater than a critical angle θc at which total reflection occurs. The approach angle θ indicates an angle relative to a perpendicular line perpendicular to the optical waveguide layer 1.

The optical waveguide layer 1 has a first main surface F1, a second main surface F2, and an end surface F3. The first main surface F1 and the second main surface F2 are substantially parallel and opposite to each other. The end surface F3 indicates a surface of an end of the optical waveguide layer 1 in a direction SD in which the first main surface F1 spreads. In the example of FIG. 1, the end surface F3 indicates a surface of an end of the optical waveguide layer 1 in a second direction A2 which is orthogonal to a first direction A1. The first direction A1 is substantially perpendicular to the optical waveguide layer 1. That is, the first direction A1 is substantially perpendicular to the first main surface F1. The light LT2 guided inside the optical waveguide layer 1 is emitted from the end surface F3.

The light diffraction layer 3 diffracts the light LT2 in at least a portion of the wavelength band of the light LT1 incident to the light diffraction layer 3 toward the optical waveguide layer 1 and allows the light LT2 to enter the optical waveguide layer 1. Specifically, the light diffraction layer 3 has optical anisotropy (birefringence) and a plurality of optic axes (referred to in the following as “optic axes 400”). The optical anisotropy is uniaxial optical anisotropy, for example. The light diffraction layer 3 is disposed in a different layer level from the optical waveguide layer 1. The light diffraction layer 3 is opposite to the optical waveguide layer 1 (specifically, the second main surface F2) in the first direction A1. The light diffraction layer 3 has a first boundary surface 317 and a second boundary surface 319.

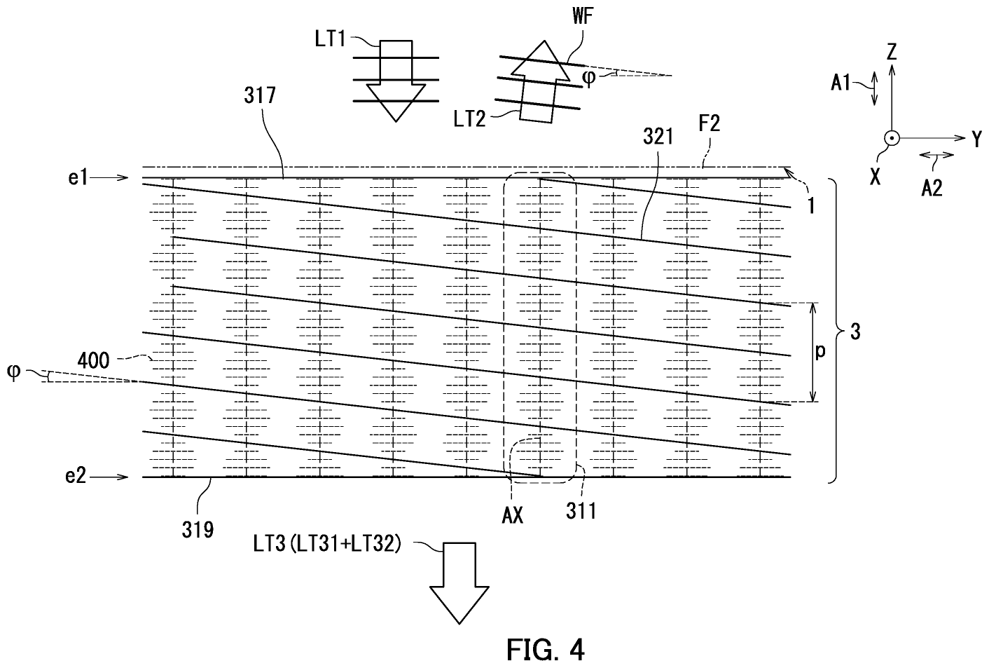

Then, the light diffraction layer 3 diffracts the light LT2 in at least a portion of the wavelength band of the light LT1 incident to the light diffraction layer 3 toward the optical waveguide layer 1 according to the distribution of the orientations of the optic axes 400 (FIG. 4 as described below) and allows the light LT2 to enter the optical waveguide layer 1. In this case, the light diffraction layer 3 allows the light LT2 to enter the optical waveguide layer 1 at an acute angle. Then, the optical waveguide layer 1 guides light diffracted by the light diffraction layer 3 and entering inside the optical waveguide layer 1. By contrast, the light diffraction layer 3 transmits light LT3, which is a portion of the incident light LT1, through the optical waveguide layer 1.

In particular, in the first embodiment, the light diffraction layer 3 reflects the light LT2 in at least a portion of the wavelength band of the light LT1 incident to the light diffraction layer 3 through the optical waveguide layer 1. In reflecting the light LT2, the light diffraction layer 3 diffracts the light LT2 toward the optical waveguide layer 1 according to the distribution of the orientations of the optic axes 400 and allows the light LT2 to enter the optical waveguide layer 1 at an acute angle. By contrast, the light diffraction layer 3 preferably transmits the light LT3 in at least a portion of the wavelength band of a visible light region of the light LT1 incident to the light diffraction layer 3. The light LT3 includes visible light, and therefore the light diffraction layer 3 is transparent.

Here, the light LT2 entering the optical waveguide layer 1 from the light diffraction layer 3 is totally reflected at the interface between air and the first main surface F1 of the optical waveguide layer 1. By contrast, light as a portion (referred to in the following as “light LTP”) of the light LT2 may enter the light diffraction layer 3 without being totally reflected. This is because the incident angle of the light LTP to the light diffraction layer 3 differs from the incident angle (substantially 90 degrees in the example of FIG. 1) of the light LT1 to the light diffraction layer 3. That is, the light diffraction layer 3 is set to reflect and diffract the light LT1, and therefore the light LTP as a portion of the light LT2 may enter the optical waveguide layer 1. However, even in this case, the light LTP is totally reflected at the interface between the second boundary surface 319 of the light diffraction layer 3 and air, and enters the optical waveguide layer 1 so as to satisfy the optical waveguide condition of the optical waveguide layer 1.

The light diffraction layer 3 may also be flexible, for example. In addition, the light diffraction layer 3 may be in contact with the optical waveguide layer 1 (specifically, the second main surface F2) or a transparent layer such as an adhesive layer may be interposed between the light diffraction layer 3 and the optical waveguide layer 1. Preferably, the refractive index of the layer interposed between the light diffraction layer 3 and the optical waveguide layer 1 is substantially equal to the refractive index of the optical waveguide layer 1. The light diffraction layer 3 is configured as a film, for example.

The light receiving body 5 receives the light LT2 guided inside the optical waveguide layer 1. In the example of FIG. 1, the light receiving body 5 receives the light LT2 emitted from the end surface F3 of the optical waveguide layer 1. Specifically, the light receiving body 5 is opposite to the end surface F3 of the optical waveguide layer 1 in the direction SD. In the example of FIG. 1, the light receiving body 5 is opposite to the end surface F3 of the optical waveguide layer 1 in the second direction A2.

The light receiving body 5 is directly or indirectly connected to the optical waveguide layer 1. For example, the light receiving body 5 is directly or indirectly connected to the end surface F3 of the optical waveguide layer 1. When the light receiving body 5 is indirectly connected to the end surface F3 of the optical waveguide layer 1, for example, a transparent layer or an optical component (e.g., a lens) is interposed between the light receiving body 5 and the end surface F3 of the optical waveguide layer 1.

The light receiving body 5 receives the light LT2 guided inside the optical waveguide layer 1 and converts the light LT2 to a physical quantity related to electricity. In the first embodiment, the light receiving body 5 is a solar cell. The solar cell receives the light LT2 guided by the optical waveguide layer 1 and converts the energy of the received light LT2 to electrical power. That is, the solar cell generates electricity using the received light LT2. The solar cell is not limited by type, and examples of the solar cell include a silicon solar cell, a compound solar cell, an organic solar cell, a perovskite solar cell, and a quantum dot solar cell. Note that as long as the light LT2 guided inside the optical waveguide layer 1 is received and converted to a physical quantity related to electricity, the light receiving body 5 is not particularly limited, and examples thereof include an optical sensor that detects light and an image sensor that captures an image of a subject. Examples of the optical sensor include a photodiode and a phototransistor. Examples of the image sensor include a charge-coupled device (CCD) image sensor and a complementary metal-oxide-semiconductor (CMOS) image sensor.

Operation of the optical device 100 is described with continued reference to FIG. 1. The light LT1 is incident to the optical waveguide layer 1 (specifically, the first main surface F1) from a side opposite to the side on which the light diffraction layer 3 is disposed. In the first embodiment, the light LT1 is sunlight. In the example of FIG. 1, the light LT1 is substantially perpendicularly incident to the optical waveguide layer 1 for facilitating understanding. Note that the incident angle of the light LT1 to the optical waveguide layer 1 is not particularly limited. For example, the light LT1 may be incident to the optical waveguide layer 1 at a plurality of mutually different incident angles.

The light LT1 enters inside the optical waveguide layer 1 from the first main surface F1 and is incident to the light diffraction layer 3 from the second main surface F2. Then, the light diffraction layer 3 reflects and diffracts the light LT2 in at least a portion of the wavelength band of the light LT1 incident to the light diffraction layer 3 through the optical waveguide layer 1 toward the optical waveguide layer 1. Specifically, the light diffraction layer 3 reflects and diffracts the light LT2 in at least a portion of the wavelength band of the light LT1 incident to the light diffraction layer 3 through the optical waveguide layer 1 toward the optical waveguide layer 1 at the approach angle θ which yields total reflection inside the optical waveguide layer 1. That is, the light diffraction layer 3 reflects and diffracts the light LT2 toward the optical waveguide layer 1 at the approach angle θ which satisfies the optical waveguide condition in the optical waveguide layer 1. In this case, the light LT2 enters inside the optical waveguide layer 1 from the second main surface F2.

Then, the optical waveguide layer 1 guides the light LT2 reflected and diffracted by the light diffraction layer 3 and entering inside the optical waveguide layer 1 and guides the light LT2 to the light receiving body 5. As a result, the light receiving body 5 receives the light LT2 guided by the optical waveguide layer 1.

By contrast, the light diffraction layer 3 preferably transmits the light LT3 in at least a portion of the wavelength band of the visible light region among the light LT1 incident to the light diffraction layer 3 through the optical waveguide layer 1. Therefore, in this preferable example, the light diffraction layer 3 is transparent. Note that the light diffraction layer 3 may transmit the light LT3 in the entire wavelength band of the visible light region of the light LT1 incident to the light diffraction layer 3 through the optical waveguide layer 1. For example, the lower limit of the wavelength in the visible light region is at least 360 nm and no greater than 400 nm, and the upper limit of the wavelength in the visible light region is at least 760 nm and no greater than 830 nm. Details of the light LT3 are described below.

According to the first embodiment as described above with reference to FIG. 1, the light diffraction layer 3 allows the light LT2 to enter the optical waveguide layer 1 by diffracting the light LT2, and allows the optical waveguide layer 1 to guide the light LT2. Therefore, the optical device 100 can guide the light LT2 from the optical waveguide layer 1 toward the light receiving body 5 without including a phosphor in the optical waveguide layer 1. In particular, in the first embodiment, the light receiving body 5 is a solar cell. Therefore, the solar cell can receive the light LT2 guided by the optical waveguide layer 1 and generate electricity.

In particular, according to the first embodiment, the optical waveguide layer 1 and the light diffraction layer 3 transmit the light LT3 in the visible light region. In addition, the light diffraction layer 3 allows the light LT2 to enter the optical waveguide layer 1 and allow the optical waveguide layer 1 to guide the light LT2. Therefore, the light LT2 can be guided from the optical waveguide layer 1 toward the light receiving body 5 without including a phosphor in the optical waveguide layer 1. As a result, light can be guided from the optical waveguide layer 1 toward the light receiving body 5 without reducing the transparency of the optical waveguide layer 1.

In the first embodiment, the light diffraction layer 3 preferably reflects and diffracts the light LT2 which includes invisible light. The light diffraction layer 3 more preferably reflects the light LT2 which includes no visible light and only invisible light. This is because invisible light does not affect the transparency of the light diffraction layer 3, and thus the light LT2 can be guided toward the light receiving body while maintaining the transparency of the light diffraction layer 3. Furthermore, when the light LT2 is invisible light, the transparency of the optical device 100 can be further improved because the light LT2 guided by the optical waveguide layer 1 is not visible. Invisible light is light in a wavelength band different from that of the visible light region. For example, invisible light is infrared (e.g., near-infrared) or ultraviolet light. For example, the wavelength band of near-infrared light is at least 0.7 μm and no greater than 2.5 μm.

When the optical device 100 is required to be transparent, the light diffraction layer 3 may reflect the light LT2 including visible light as long as the light diffraction layer 3 transmits the light LT3 in a wavelength band which is at least part of the wavelength band of the visible light region of the light LT1 incident to the light diffraction layer 3. In this case, the proportion of visible light transmitted by the light diffraction layer 3 is preferably greater than the proportion of visible light reflected by the light diffraction layer 3. This is to improve the transparency of the light diffraction layer 3.

In the first embodiment, the light receiving body 5 is a solar cell. In addition, the optical waveguide layer 1 and the light diffraction layer 3 are transparent because the optical waveguide layer 1 and the light diffraction layer 3 transmit visible light. That is, the optical waveguide layer 1 and the light diffraction layer 3, which have a relatively large surface area that mainly contributes to light concentration, are transparent. Accordingly, when the light receiving body 5 is a solar cell, a large part pf the optical device 100 functions as a transparent solar cell device.

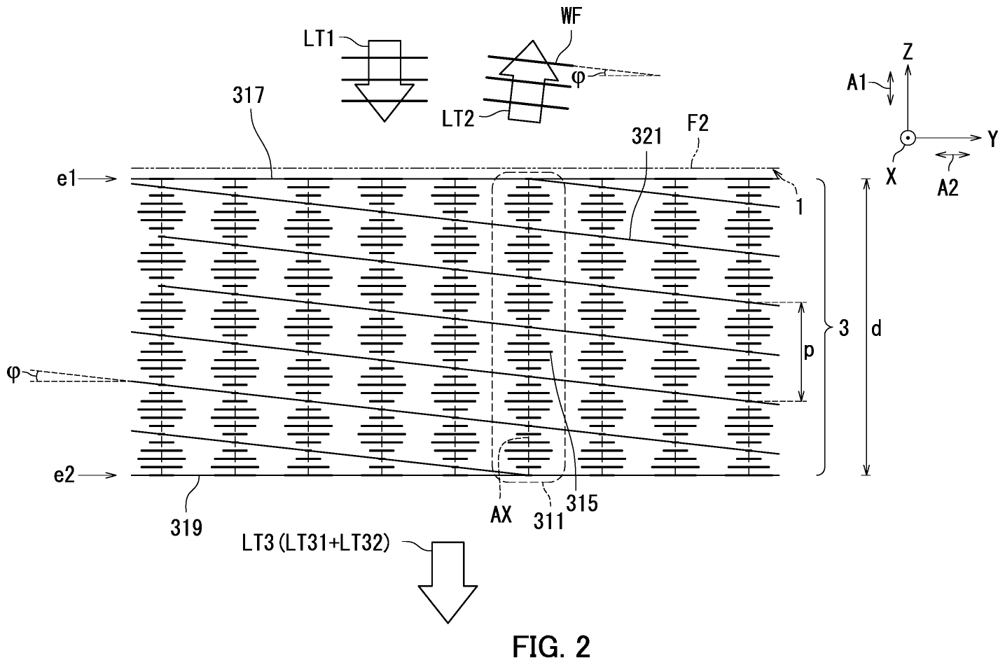

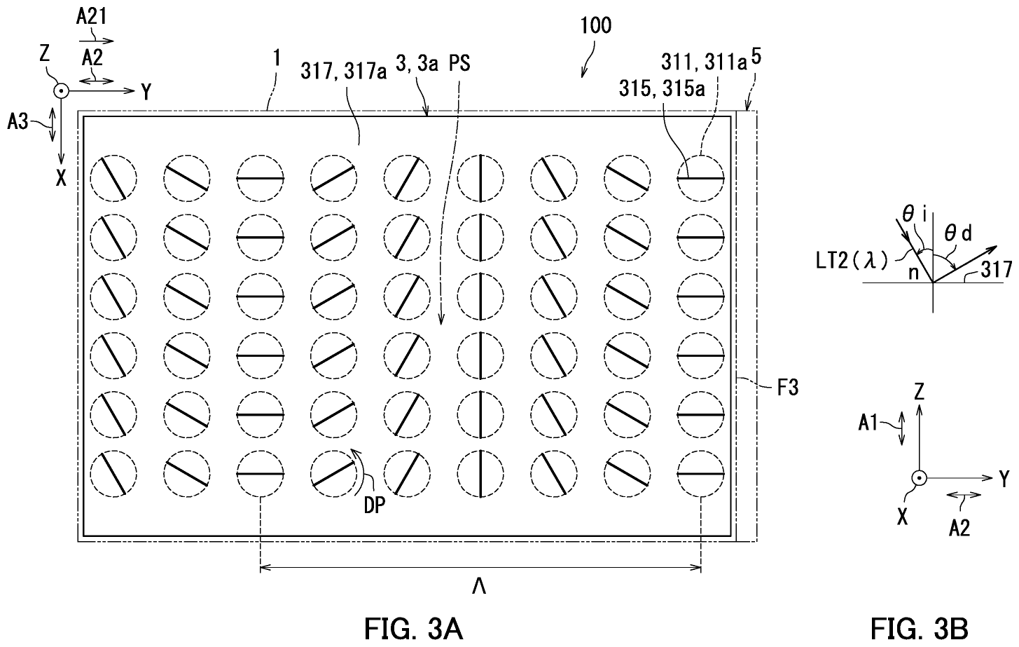

Next, the light diffraction layer 3 is described with reference to FIGS. 2 to 3B. FIG. 2 is a schematic cross-sectional view of the structure of the light diffraction layer 3. FIG. 3A is a schematic plan view of the optical device 100. FIG. 3B is a diagram illustrating an incident angle θi and a reflection angle θd of the light LT2 to the light diffraction layer 3. The incident angle θi and the reflection angle θd are angles relative to a perpendicular line perpendicular to the light diffraction layer 3.

As illustrated in FIG. 2, the light diffraction layer 3 includes a plurality of helical structures 311. Each of the helical structures 311 extends in the first direction A1. That is, a helical axis AX of each of the helical structures 311 is substantially perpendicular to the optical waveguide layer 1 (specifically, the second main surface F2). The helical axis AX is substantially parallel to the first direction A1. Each of the helical structures 311 has a pitch p. The pitch p indicates one helical period (360 degrees). Each of the helical structures 311 includes a plurality of elements 315. The elements 315 are layered in a twisted manner in the first direction A1.

An element 315 is a molecule, for example. Specifically, to simplify the drawings, one element 315 represents and indicates a molecule which is oriented in a direction of average orientation among a plurality of molecules (referred to in the following as a “molecule group”) located on one plane orthogonal to the first direction A1 in the drawings of the present application. Accordingly, in each helical structure 311, a molecule group is located on one plane orthogonal to the first direction A1. In each helical structure 311, a plurality of molecule groups are aligned in a helix in the first direction A1 with the directions of orientation twisting. Therefore, the element 315 can also be perceived as a molecule group. “Average” in the direction of average orientation refers to “average in time and space”. Here, when the elements 315 are liquid crystal molecules, for example, the one element 315 represents and indicates a liquid crystal molecule oriented toward a director among the plurality of liquid crystal molecules (referred to in the following as a “liquid crystal molecule group”) located on one plane orthogonal to the first direction A1. Therefore, the elements 315 can also be perceived as liquid crystal molecule groups.

The number of helical periods in a helical structure 311 is relatively large in the first direction A1. When the number of helical periods in the helical structure 311 is relatively large, the light diffraction layer 3 functions as a reflective diffraction element that reflects light. Specifically, the number of helical periods in the helical structure 311 is a large number.

Each of the helical structures 311 reflects the light LT2 having a wavelength in a band (may be referred to in the following as a “selective reflection band”) according to the structure and optical properties of the helical structure 311 and that is in a polarization state corresponding to the helical direction of the helix of the helical structure 311. Such reflection of light may be referred to as selective reflection, and the characteristics of selective reflection of light may be referred to as selective reflectivity. Furthermore, each of the helical structures 311 transmits the light LT3. The light LT3 includes light LT31 and light LT32. The light LT31 has a wavelength in the selective reflection band and a polarization state contrary to the helical direction of the helix of the helical structure 311. The light LT32 has a wavelength outside the selective reflection band. The light LT32 preferably has a wavelength in at least a portion of the wavelength band of the visible light region. Note that the light LT32 more preferably has a wavelength in the entire wavelength band of the visible light region.

Specifically, the selective reflection is as follows. That is, each of the helical structures 311 reflects the light LT2 having a wavelength in a band (i.e., the selective reflection band) corresponding to the helical pitch p and the refractive index of the helical structure 311 and having circular polarization in a direction of circulation that is the same direction as the helical direction of the helix of the helical structure 311. By contrast, each of the helical structures 311 transmits the light LT3. The light LT31 of the light LT3 has the same wavelength as the wavelength of the reflected light LT2 and has circular polarization in a direction of circulation that is opposite to the helical direction of the helix of the helical structure 311. The light LT32 of the light LT3 has a wavelength different from the wavelength of the reflected light LT2. Note that in the present specification, circular polarization may be strictly circular polarization or elliptical polarization approximating circular polarization.

For example, the helical pitch p and the refractive index of each helical structure 311 are set according to the wavelength of invisible light so that the helical structure 311 reflects invisible light. In this case, for example, the helical pitch p and the refractive index of the helical structure 311 are set according to the wavelength of infrared light (e.g., near-infrared light) or ultraviolet light so that the helical structure 311 reflects infrared light (e.g., near-infrared light) or ultraviolet light.

In addition to the first and second boundary surfaces 317 and 319, the light diffraction layer 3 further has a plurality of reflective surfaces 321. The light LT1 emitted from the optical waveguide layer 1 (specifically, the second main surface F2) is incident to the first boundary surface 317. Each of the first and second boundary surfaces 317 and 319 is substantially perpendicular to the helical axis AX of the helical structure 311. Each of the first and second boundary surfaces 317 and 319 is substantially parallel to the optical waveguide layer 1 (specifically, the second main surface F2).

The first boundary surface 317 includes one end e1 (specifically, an element 315 located at the one end e1) among both ends of each of the helical structures 311. The first boundary surface 317 is located at the boundary between the optical waveguide layer 1 and the light diffraction layer 3. The second boundary surface 319 includes the other end e2 (specifically, an element 315 located at the other end e2) among both ends of each of the helical structures 311. The second boundary surface 319 is located at the boundary between the light diffraction layer 3 and air.

In the first embodiment, the reflective surfaces 321 are substantially parallel to each other. Each reflective surface 321 is inclined with respect to the first boundary surface 317 and the optical waveguide layer 1 (specifically, the second main surface F2), and has a substantially planar shape extending in a constant direction. The reflective surface 321 selectively reflects the light LT2 of the light LT1 incident from the first boundary surface 317 according to Bragg's law. Specifically, the reflective surface 321 reflects the light LT2 such that a wavefront WF of the light LT2 is substantially parallel to the reflective surface 321. More specifically, the reflective surface 321 reflects the light LT2 according to an inclination angle φ of the reflective surface 321 relative to the first boundary surface 317. For example, when the incident angle θi illustrated in FIG. 3B=0, an inclination angle θd (=reflection angle θd) of the wavefront WF (FIG. 2) of the light LT2 with respect to the first boundary surface 317 and the inclination angle φ of the reflective surface 321 are related in formula (1).

θd=sin⁻¹(2λ·tan(φ)/n·p) (1)

In formula (1), λ indicates the wavelength of the light LT2, n indicates the refractive index of the optical waveguide layer 1, and p indicates the pitch. As such, the reflective surface 321 deflects the light LT2. That is, the light diffraction layer 3 functions as a deflection element.

More specifically, the reflective surface 321 can be defined as follows. That is, as the light LT2 (e.g., circularly polarized light) progresses in the light diffraction layer 3, the refractive index perceived by the light LT2 in the light diffraction layer 3 gradually changes, and thus Fresnel reflection gradually occurs in the light diffraction layer 3. Then, Fresnel reflection is strongest at a position where the refractive index perceived by the light LT2 in the light diffraction layer 3 (helical structures 311) changes the most. The reflective surface 321 is a surface on which Fresnel reflection is strongest in the light diffraction layer 3.

In each of the reflective surfaces 321, the directions of orientation of the elements 315 located on the reflective surface 321 are aligned across the helical structures 311. In addition, the spatial phases of two or more of the helical structures 311 are mutually different. As a result, a plurality of reflective surfaces 321 are formed. Therefore, the optical properties of a reflective surface 321 indicate the optical properties of a helical structure 311.

Specifically, as illustrated in FIG. 3A, a spatial phase of each helical structure 311 indicates the direction of orientation of an element 315 included in the helical structure 311 at the first boundary surface 317. That is, the spatial phase of the helical structure 311 indicates the direction of orientation of the element 315 located at the end e1 (FIG. 2) of the helical structure 311.

According to the first embodiment, a reflective surface 321 (FIG. 2) inclined with respect to the first boundary surface 317 and the optical waveguide layer 1 can be easily formed in the light diffraction layer 3 by mutually differentiating the spatial phases of two or more helical structures 311. In particular, occurrence of defects or discontinuities in the helical structures 311 is inhibited because a reflective surface 321 is formed by differentiating the spatial phases of two or more helical structures 311. As a result, anomalies in the light LT2 caused by defects or discontinuities can be inhibited.

More specifically, in the helical structures 311 aligned in the second direction A2, the directions of orientation of the elements 315 located on the first boundary surface 317 are different. Therefore, the spatial phases of the helical structures 311 aligned in the second direction A2 are different in the second direction A2. By contrast, in the helical structures 311 aligned in a third direction A3, the directions of orientation of the elements 315 located on the first boundary surface 317 are substantially identical. Therefore, the spatial phases of the helical structures 311 aligned in the third direction A3 are substantially identical in the third direction A3. The third direction A3 is orthogonal to the first direction A1 and the second direction A2.

In particular, when focusing on the second direction A2, the directions of orientation of the elements 315 aligned in the second direction A2 at the first boundary surface 317 change by a constant angle in the second direction A2. That is, the directions of orientation of the elements 315 aligned in the second direction A2 at the first boundary surface 317 are changing linearly in the second direction A2. Therefore, the spatial phases of the helical structures 311 aligned in the second direction A2 are changing linearly in the second direction A2. As a result, a reflective surface 321 (FIG. 2) inclined with respect to the first boundary surface 317 and the optical waveguide layer 1 can be formed in the light diffraction layer 3. “Changing linearly” indicates that an amount of change in the direction of orientation of an element 315 is represented by a linear function, for example.

Here, as illustrated in FIG. 3A, a distance between two helical structures 311 when the directions of orientation of the elements 315 differ by 180 degrees in a constant direction (the second direction A2 in the example of FIG. 3A) at the first boundary surface 317 is defined as a period Λ of a helical structure 311. In the example in FIG. 3A, the period Λ of the helical structure 311 is the interval between both ends of the helical structure 311 when the directions of orientation of the elements 315 of the helical structure 311 differ from 0 to 180 degrees in the second direction A2 at the first boundary surface 317.

As illustrated in FIG. 2 and FIG. 3A, the inclination angle φ of the reflective surface 321 is indicated by formula (2).

φ=arctan(p/2Λ) (2)

As illustrated in FIG. 3B, the relationship between the incident angle θi of the light LT2 to the first boundary surface 317, the reflection angle (diffraction angle) θd of the light LT2 from the first boundary surface 317, a wavelength λ of the light LT2, a refractive index n of the optical waveguide layer 1, and the period Λ of the helical structure 311 are indicated by formula (3). Therefore, the shorter the period Λ is, the larger the reflection angle θd can be. In other words, since the approach angle θ (FIG. 1) of the light LT2 to the optical waveguide layer 1 is an angle according to the reflection angle θd (e.g., θ≈θd), the shorter the period Λ is, the larger the approach angle θ can be. Note that in the example of FIG. 1, the light LT1 is substantially perpendicularly incident to the optical device 100, and therefore the incident angle θi is substantially zero degrees.

sinθi+sinθd=λ/nΛ (3)

In FIGS. 2 and 3A, the spatial phases of the helical structures 311 for forming a reflective surface 321 which is inclined relative to the first boundary surface 317 and the optical waveguide layer 1 are described. However, the shape of the reflective surface 321 (reflective form) and the spatial phases of the helical structures 311 are not particularly limited as long as the approach angle θ of the light LT2 to the optical waveguide layer 1 is the critical angle θc or greater. Therefore, by differentiating the spatial phases of two or more of the helical structures 311, a reflective surface 321 of any shape (reflective surface 321 of any reflective form) can be configured. Note that in FIG. 1, slanted lines indicating the light diffraction layer 3 are not slanted lines indicating a cross-section but rather the reflective surfaces 321.

As long as the approach angle θ of the light LT2 to the optical waveguide layer 1 is equal to or greater than the critical angle θc, the reflective surfaces 321 may not be regularly aligned and may have an artifact. For example, a reflective surface 321 may be convex and concave, the inclination of the reflective surfaces 321 may not be uniform, or the angle of a reflective surface 321 may be changing in the third direction A3 (FIG. 3A). In particular, in the vicinity of the light diffraction layer 3 where the first boundary surface 317 touches the second main surface F2 of the optical waveguide layer 1 and inside the light diffraction layer 3, the reflective surface 321 is inclined relative to the first boundary surface 317. However, in the vicinity of the second boundary surface 319 on the side from which the light LT3 is emitted, the reflective surface 321 may not be inclined relative to the second boundary surface 319. That is, in the vicinity of the second boundary surface 319 on the side from which the light LT3 is emitted, the reflective surface 321 may be substantially parallel to the second boundary surface 319. In this case, a light dispersion phenomenon that occurs when the optical device 100 is viewed from the side from which the light LT3 is emitted (from the side of the second boundary surface 319) can be inhibited. For example, the helical pitch p may be different in the second direction A2, or the interval between the reflective surfaces 321 may not be constant. Furthermore, the orientation of the elements 315 at the first boundary surface 317 and the orientation of the elements 315 at the second boundary surface 319 may be the same or different.

Here, in the first embodiment, the light diffraction layer 3 is made of liquid crystal. Specifically, the light diffraction layer 3 is made of cholesteric liquid crystal. That is, the helical structures 311 of the light diffraction layer 3 each are cholesteric liquid crystal. Therefore, each of the elements 315 included in the helical structures 311 is a liquid crystal molecule, for example. Cholesteric liquid crystal reflects light having the wavelength of the selective reflection band and having circular polarization in a direction of circulation that is the same direction as the helical direction of the helix of the cholesteric liquid crystal.

When the helical pitch of cholesteric liquid crystal is referred to as p, the refractive index of the liquid crystal molecules to extraordinary light is referred to as ne, and the refractive index of the liquid crystal molecules to ordinary light is referred to as no, the selective reflection band of the cholesteric liquid crystal for perpendicularly incident light is generally indicated by “no×p to ne×p”. In detail, the selective reflection band of the cholesteric liquid crystal changes according to approximately cos²φ (FIG. 2) for the range “no×p to ne×p”. Furthermore, the selective reflection band of the cholesteric liquid crystal changes according to approximately cosθi (FIG. 3B) for the range “no×p to ne×p”. In addition, since the cholesteric liquid crystal has optical anisotropy, the refractive indices (no, ne) actually perceived by the light reflected on the cholesteric liquid crystal are set to values according to the incident angle θi and the polarization state of the light LT2. That is, the selective reflection bandwidth of the cholesteric liquid crystal is determined according to no, ne, p, φ, and θi.

The helical structures 311 of the light diffraction layer 3 are not limited to being made of cholesteric liquid crystal. The helical structures 311 may be made of chiral liquid crystal other than cholesteric liquid crystal. Examples of chiral liquid crystal other than cholesteric liquid crystal include chiral smectic C phase, twisted grain boundary phase, and cholesteric blue phase. Cholesteric liquid crystal may also be helicoidal cholesteric phase, for example.

When the light diffraction layer 3 is made of liquid crystal, for example, the light diffraction layer 3 is formed as a film.

The light diffraction layer 3 as a film is formed, for example, by polymerizing the helical structures 311. Specifically, the light diffraction layer 3 as a film is formed by polymerizing the liquid crystal molecules which are the elements 315 included in the light diffraction layer 3. For example, the liquid crystal molecules are polymerized by irradiating the liquid crystal molecules with light.

Alternatively, the light diffraction layer 3 as a film is formed, for example, by controlling the orientation of polymer liquid crystal material that exhibits a liquid crystal state at a predetermined temperature or concentration so as to form the helical structures 311 in a liquid crystal state, and then transitioning the material to a solid state while maintaining the orientation.

In the light diffraction layer 3 as a film, adjacent helical structures 311 are bound to each other due to polymerization or transition to solid while maintaining the orientation of the helical structures 311, that is, the spatial phases of the helical structures 311. As a result, in the light diffraction layer 3 as a film, the direction of orientation of each liquid crystal molecule is fixed.

The helical structures 311 of the light diffraction layer 3 are not limited to being liquid crystal. For example, the helical structures 311 may form chiral structures. Examples of chiral structures include helical inorganic, helical metal, and helical crystal.

A helical inorganic material is a chiral sculptured film (referred to in the following as a “CSF”), for example. A CSF is an optical thin film in which an inorganic material is vapor deposited on a substrate while the substrate is rotated, and has a helical microstructure. As a result, CSF exhibits the same optical properties as cholesteric liquid crystal.

A helical metal is a helix metamaterial (referred to in the following as an “HM”), for example. An HM is a material in which metal is processed into fine helical structures, and reflects circularly polarized light like cholesteric liquid crystal.

Helical crystal is gyroid photonic crystal (referred to in the following as “GPC”), for example. GPC has a three-dimensional helical structure. Some insects or artificial structures include GPC's. A GPC reflects circularly polarized light like the cholesteric blue phase.

In FIGS. 1 to 3B above, the light LT1 was incident to the optical waveguide layer 1 (specifically, the first main surface F1) from a side opposite to the side on which the light diffraction layer 3 is disposed. However, the light LT1 may be incident to the optical waveguide layer 1 (specifically, the second main surface F2) through the light diffraction layer 3 from the side on which the light diffraction layer 3 illustrated in FIG. 1 is disposed. That is, the light LT1 may be incident from a side opposite to the side on which the optical waveguide layer 1 is disposed.

In this case, light transmitted through the light diffraction layer 3 and incident to the optical waveguide layer 1 is reflected by the first main surface F1 of the optical waveguide layer 1 and is incident to the light diffraction layer 3 from the second main surface F2. Therefore, the light diffraction layer 3 reflects and diffracts the light incident to the light diffraction layer 3 toward the optical waveguide layer 1. Then, the optical waveguide layer 1 guides the light reflected and diffracted by the light diffraction layer 3 and entering inside the optical waveguide layer 1, and the light is guided to the light receiving body 5.

For example, when the helical direction of the helix of a helical structure 311 of the light diffraction layer 3 indicates a rightward direction of circulation, the light diffraction layer 3 reflects right-handed circularly polarized light and transmits left-handed circularly polarized light of the light incident to the light diffraction layer 3 from outside the optical device 100. Accordingly, the left-handed circularly polarized light is incident to the optical waveguide layer 1. Then, the left-handed circularly polarized light becomes right-handed circularly polarized light when reflected by the first main surface F1 of the optical waveguide layer 1. Accordingly, the right-handed circularly polarized light is incident to the light diffraction layer 3 from the second main surface F2. Then, the light diffraction layer 3 reflects the right-handed circularly polarized light toward the optical waveguide layer 1. As a result, the optical waveguide layer 1 guides the right-handed circularly polarized light toward the light receiving body 5.

Next, an optic axis 400 of the light diffraction layer 3 is described with reference to FIGS. 2 and 4. FIG. 4 is a schematic cross-sectional view of the optic axis 400 of the light diffraction layer 3. In FIG. 4, the optic axis 400 is indicated by a dashed line. As illustrated in FIGS. 2 and 4, a plurality of optic axes 400 correspond to a plurality of elements (plurality of liquid crystal molecules) 315. That is, each of the elements 315 has an optic axis 400. The orientation of the optic axis 400 substantially coincides with the direction of orientation of the corresponding element 315. Specifically, the orientation of the optic axis 400 substantially coincides with the orientation of the major axis of the corresponding element 315.

The plurality of optic axes 400 includes two or more optic axes 400 with mutually different orientations. Specifically, the orientations of two or more of the optic axes 400 correspond to two or more elements 315 with mutually different directions of orientation among the elements 315. Therefore, a plurality of optic axes 400 are distributed in the light diffraction layer 3. Specifically, the optic axes 400 are distributed corresponding to the spatial phases of the helical structures 311. The light diffraction layer 3 then diffracts the light LT2 according to the distribution of the optic axes 400. In the first embodiment, the light diffraction layer 3 reflects and diffracts the light LT2 according to the distribution of the optic axes 400.

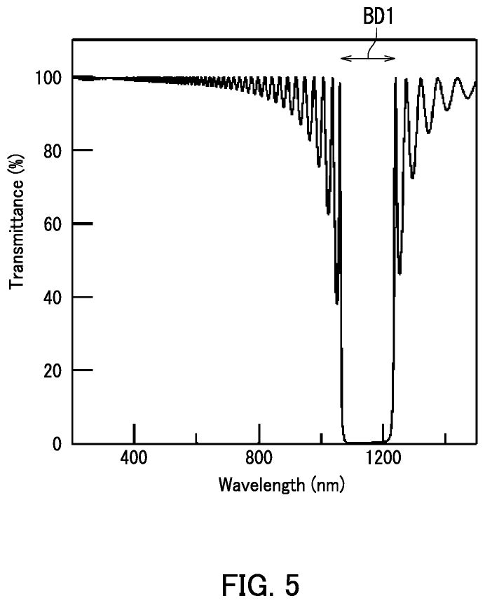

Next, the light diffraction layer 3 illustrated in FIG. 4 and a variation of the light diffraction layer 3 (referred to in the following as a “light diffraction layer 800”) are compared and described with reference to FIGS. 3 to 6B. FIG. 5 illustrates the light transmittance characteristics of the light diffraction layer 3. In FIG. 5, the vertical axis indicates light transmittance and the horizontal axis indicates light wavelength. FIG. 5 illustrates simulated results of light transmittance when the light diffraction layer 3 is made of cholesteric liquid crystal. ne=1.75, no=1.53, p=700 nm, and d=9 μm. As illustrated in FIG. 2, p indicates the pitch and d indicates the length of the light diffraction layer 3 in the first direction A1, that is, the thickness of the light diffraction layer 3. Note that for simplicity of calculation, the inclination angle φ=0.

As illustrated in FIG. 5, the transmittance of the light diffraction layer 3 is approximately 0% in a target reflection band (selective reflection band) BD1 of the light diffraction layer 3. That is, the reflectance of the light diffraction layer 3 is approximately 100% in the target reflection band BD1 of the light diffraction layer 3.

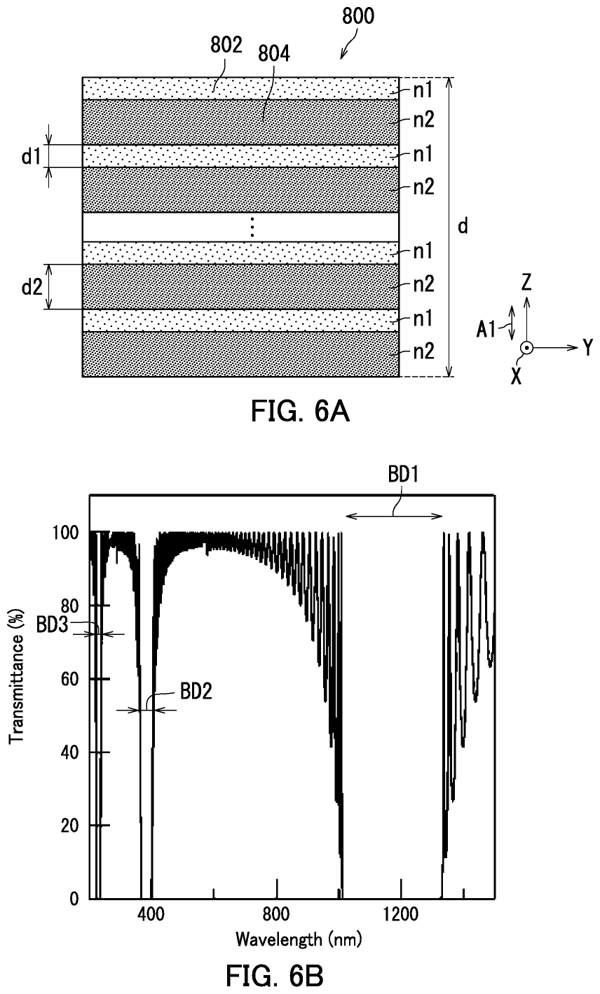

FIG. 6A is a schematic cross-sectional view of the light diffraction layer 800. As illustrated in FIG. 6A, the light diffraction layer 800 includes a plurality of first refractive index regions 802 and a plurality of second refractive index regions 804. In the light diffraction layer 800, the first refractive index regions 802 and the second refractive index regions 804 are alternately arranged in the first direction A1. Each first refractive index region 802 has a refractive index n1 and a thickness d1. Each second refractive index region 804 has a refractive index n2 and a thickness d2. The refractive indices n1 and n2 are different from each other. The thicknesses d1 and d2 are different from each other.

The light diffraction layer 800 is not birefringent or is less birefringent than the light diffraction layer 3. That is, the light diffraction layer 800 is substantially optically isotropic. For example, the light diffraction layer 800 includes a photosensitive polymer.

The light diffraction layer 800 has a periodic distribution of the refractive indices n1 and n2 in the first direction A1 by alternately layering the first and second refractive index regions 802 and 804. The light diffraction layer 800 then reflects and diffracts light according to the periodic distribution of the refractive indices n1 and n2 in the first direction A1.

FIG. 6B is a diagram illustrating the light transmittance characteristics of the light diffraction layer 800. In FIG. 6B, the vertical axis indicates light transmittance and the horizontal axis indicates light wavelength. FIG. 6B illustrates simulated results of light transmittance in the light diffraction layer 800. n1=2.35, n2=1.53, d1=122 nm, d2=188 nm, and d=9 μm. The reference sign d indicates the thickness of the light diffraction layer 800.

As illustrated in FIG. 6B, there are three bands in which the transmittance of the light diffraction layer 800 is substantially 0% (i.e., bands with a reflectivity of the light diffraction layer 800 of substantially 100%). That is, there are high order reflection bands BD2 and BD3 besides the target reflection band BD1. The high order reflection bands BD2 and BD3 appear in a wavelength band of one integer part of the target reflection band.

The light diffraction layers 3 and 800 can be applied to the present invention, but the light diffraction layer 3 (FIG. 2) is more suitable than the light diffraction layer 800 (FIG. 6A). The first reason is as follows.

That is, as can be understood from the comparison of FIGS. 5 and 6B, there are no high order reflection bands in the light diffraction layer 3, and reflections in high order reflection bands can be inhibited. This is because the light diffraction layer 3 has optical anisotropy and diffracts and reflects light according to the distribution of the optic axes 400. In the light diffraction layer 3, only light in the target reflection band BD1 can be reflected because reflection in high order reflection bands can be inhibited. In the example of FIG. 5, the light diffraction layer 3 reflects infrared light (near-infrared light) corresponding to the target reflection band BD1 but transmits visible light without reflecting it. Therefore, a dispersion phenomenon of visible wavelength light in the optical device 100 including the light diffraction layer 3 can be inhibited when the optical device 100 is viewed from a side of the optical waveguide layer 1.

In the example of FIG. 6B by contrast, reflection and diffraction of light occur in the visible light region because there is the high order reflection band BD2 in the visible light region in the light diffraction layer 800. Since the diffraction angle θd of the reflected light depends on the wavelength of the reflected light according to formula (3), rays of visible light with different wavelengths are deflected at different angles. This results in a “coloring phenomenon”. The “coloring phenomenon” is a phenomenon in which light is dispersed iridescently, for example. By contrast, as illustrated in FIG. 5, since there is no high order reflection band in the visible light region, light reflection and dispersion can be inhibited over a relatively wide wavelength band (e.g., a wavelength band of approximately 300 nm in the visible light region) in the light diffraction layer 3. As a result, high transmittance (low reflectivity) can be attained in an off-purpose wavelength range while attaining high reflectivity and diffraction efficiency in the target reflection band BD1.

The second reason why the light diffraction layer 3 is more suitable than the light diffraction layer 800 is as follows.

That is, in the light diffraction layer 800 constituted by a photosensitive polymer, a change in refractive index (n1−n2) is actually less than 0.1. Note that in the simulation illustrated in FIG. 6B, the change in refractive index (n1−n2) is deliberately set as large for ease of understanding. By contrast, in the light diffraction layer 3 in which the optic axes 400 with optical anisotropy are distributed, a relatively large change in refractive index (ne−no) of 0.1 or more can be easily attained. When a relatively large change in refractive index (ne−no) can be attained, desired optical properties (diffraction, reflection, and transmission) can be achieved with the light diffraction layer 3 which has a relatively small thickness d.

The third reason why the light diffraction layer 3 is more suitable than the light diffraction layer 800 is as follows.

That is, the optically anisotropic light diffraction layer 3 can be prepared by a coating method. Therefore, it is suitable to produce the light diffraction layer 3 with a relatively large surface area.

(Variation)

The optical device 100 according to a variation of the first embodiment of the present invention is described with reference to FIGS. 1, 7, and 8. The variation mainly differs from the first embodiment described with reference to FIGS. 1 to 4 in that the helix axes AX of the helical structures 311 according to the variant are inclined relative to the optical waveguide layer 1. The following describes the main points of difference between the variation and the first embodiment.

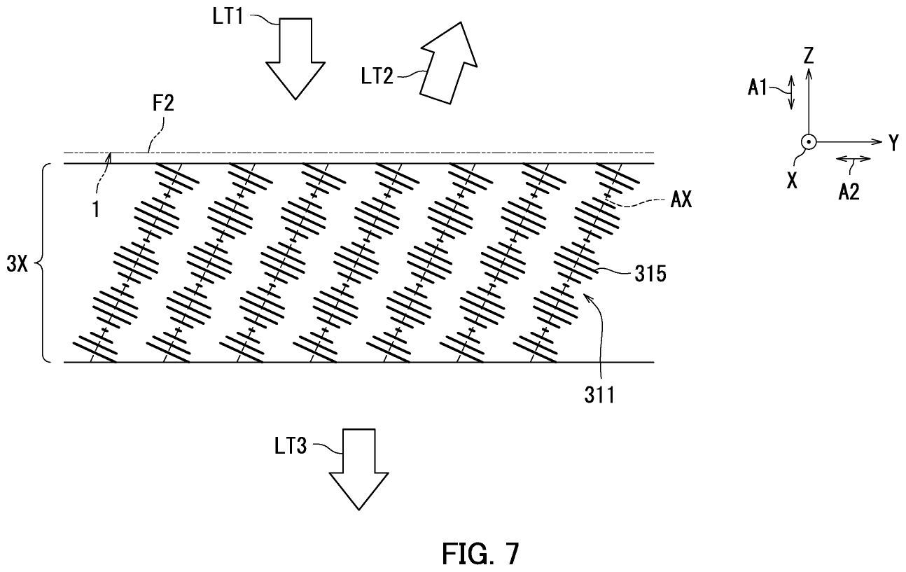

FIG. 7 is a schematic cross-sectional view of a light diffraction layer 3X of the optical device 100 according to the variation. As illustrated in FIG. 7, the light diffraction layer 3X includes a plurality of helical structures 311. The light diffraction layer 3X corresponds to an example of a “light diffracting section”. The helical axis AX of each helical structure 311 is inclined relative to the optical waveguide layer 1 (specifically, the second main surface F2). Therefore, according to the variation, the light diffraction layer 3X can reflect and diffract the light LT2 at the reflection angle θd (FIG. 3B) corresponding to the inclination of the helical axis AX. That is, the light diffraction layer 3X can deflect the light LT2 at the reflection angle θd corresponding to the inclination of the helical axis AX. Otherwise, the helical structures 311 according to the variation have similar characteristics to the helical structures 311 according to the first embodiment.

In the example in FIG. 7, the helical axes AX of the helical structures 311 are substantially parallel. However, the helical axes AX of the helical structures 311 need not be substantially parallel and are not particularly limited as long as the approach angle θ of the light LT2 to the optical waveguide layer 1 is equal to or larger than the critical angle θc.

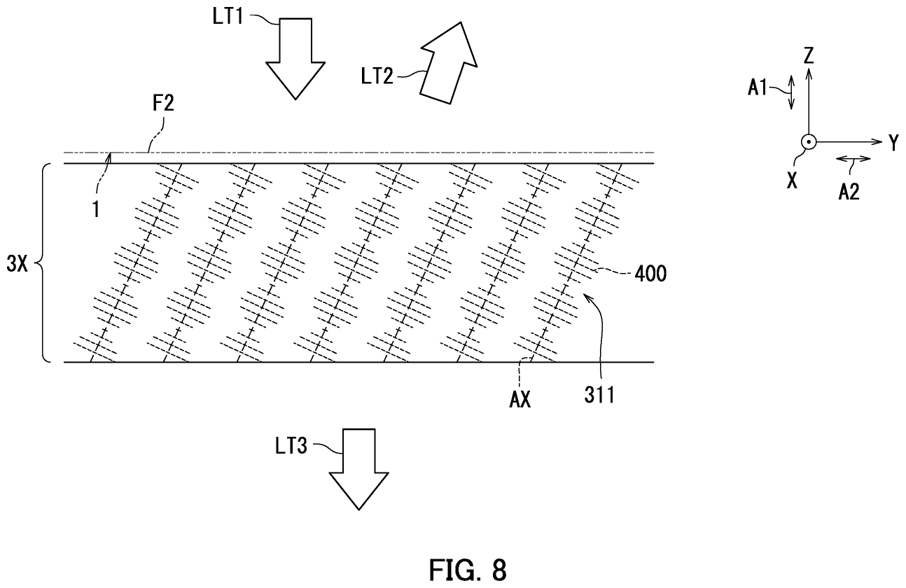

Next, an optic axis 400 of the light diffraction layer 3X is described with reference to FIGS. 7 and 8. FIG. 8 is a schematic cross-sectional view of the optic axis 400 of the light diffraction layer 3X. In FIG. 8, the optic axis 400 is indicated by a dashed line. The light diffraction layer 3X illustrated in FIGS. 7 and 8 has optical anisotropy and a plurality of optic axes 400. The optic axes 400 correspond to a plurality of respective elements (plurality of liquid crystal molecules) 315. The relationship between the optic axes 400 and the elements 315 is similar to the relationship between the optic axes 400 and the elements 315 described with reference to FIG. 4.

In the variation, the optic axes 400 are distributed corresponding to the inclination of the helical structures 311. The light diffraction layer 3 then reflects and diffracts the light LT2 according to the distribution of the optic axes 400.

### Second Embodiment

An optical device 100A according to a second embodiment of the present invention is described with reference to FIGS. 2, 3, 4, 9, and 10. The second embodiment mainly differs from the first embodiment in that the optical device 100A according to the second embodiment includes a plurality of light diffraction layers 3. The following describes the main points of difference between the second embodiment and the first embodiment. Furthermore, in the following, FIGS. 2 to 4 are referred to in the description of the helical structures 311.

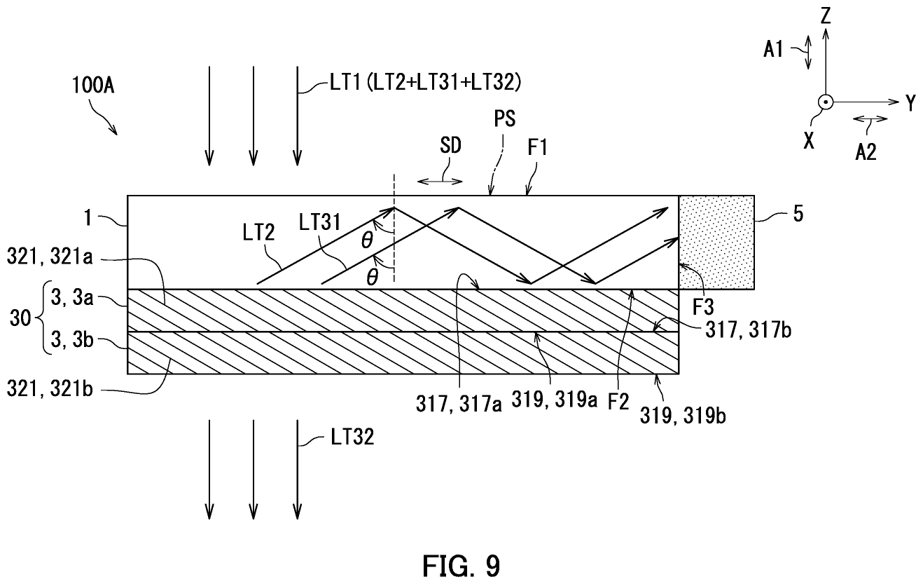

FIG. 9 is a schematic cross-sectional view of the optical device 100A according to the second embodiment. As illustrated in FIG. 9, the optical device 100A includes an optical waveguide layer 1, a plurality of light diffraction layers 3, and a light receiving body 5. In the example illustrated in FIG. 9, the optical device 100A includes two light diffraction layers 3. The optical waveguide layer 1 corresponds to an example of an “optical waveguide section”. The light diffraction layer 3 corresponds to an example of a “light diffracting section”. The light diffraction layers 3 are layered in the first direction A1. Thus, the light diffraction layers 3 are arranged in different layer levels from each other. Note that a transparent layer such as an adhesive layer may be interposed between one of the light diffraction layers 3 and another light diffraction layer 3 adjacent thereto in the first direction A1.

The light diffraction layers 3 perform either or both of diffracting (specifically, reflecting and diffracting) the light LT2 and light LT31, of the light LT1 incident to a light diffraction layer 3 through the optical waveguide layer 1, with mutually different wavelength bands toward the optical waveguide layer 1 and diffracting (specifically, reflecting and diffracting) light LT2 and LT31 with mutually different polarization toward the optical waveguide layer 1, and allow the light LT2 and LT31 to enter inside the optical waveguide layer 1. Then, the optical waveguide layer 1 guides the light LT2 and LT31 diffracted (specifically reflected and diffracted) by the light diffraction layers 3 and entering inside the optical waveguide layer 1, and the light LT2 and LT31 is guided to the light receiving body 5. As a result, the light receiving body 5 receives the light LT2 and LT31. The light LT2 is similar to the light LT2 described with reference to FIG. 2. The light LT31 preferably includes invisible light. The light LT31 more preferably includes no visible light, but only invisible light.

By contrast, the light diffraction layers 3 transmit the light LT32 with a wavelength band which is a portion of wavelength band of the light LT1 incident through the optical waveguide layer 1. The light diffraction layers 3 preferably transmit the light LT32 in at least a portion of the wavelength band of the visible light region of the light LT1 incident through the optical waveguide layer 1. Note that the light diffraction layers 3 more preferably transmit the light LT32 with a wavelength band which is the entire wavelength band of the visible light region of the light LT1 incident to the light diffraction layers 3 through the optical waveguide layer 1.

According to the second embodiment as described above with reference to FIG. 9, by arranging a plurality of light diffraction layers 3 which diffract either or both rays of light with mutually different wavelength bands and rays of light having mutually different polarization, the light quantity (light quantity of light LT2+light quantity of light LT31) of light guided to the optical waveguide layer 1 can be increased compared to a case where a single light diffraction layer 3 is provided. As a result, the light receiving body 5 can receive light of a greater light quantity. That is, in the second embodiment, the transfer efficiency of light to the optical waveguide layer 1 can be improved. The transfer efficiency of light to the optical waveguide layer 1 is the ratio of the “light quantity of the light LT1 entering inside the optical waveguide layer 1 due to reflection by all of the light diffraction layers 3” to the “light quantity of the light LT1 incident to the optical device 100A”.

Next, a case where among the two light diffraction layers 3, a light diffraction layer 3a on a side closer to the optical waveguide layer 1 and a light diffraction layer 3b on a side farther from the optical waveguide layer 1 reflect and diffract the light LT2 and LT31 with mutually different polarization toward the optical waveguide layer 1 is described in detail with reference to FIGS. 2 and 9.

The helical direction of the helix of the helical structures 311 included in the light diffraction layer 3a is opposite to the helical direction of the helix of the helical structures 311 included in the light diffraction layer 3b. The light diffraction layers 3a and 3b are opposite to each other in the first direction A1. The helical pitch p and the refractive index of the helical structures 311 included in the light diffraction layer 3a are substantially identical to the helical pitch p and the refractive index of the helical structures 311 included in the light diffraction layer 3b, respectively.

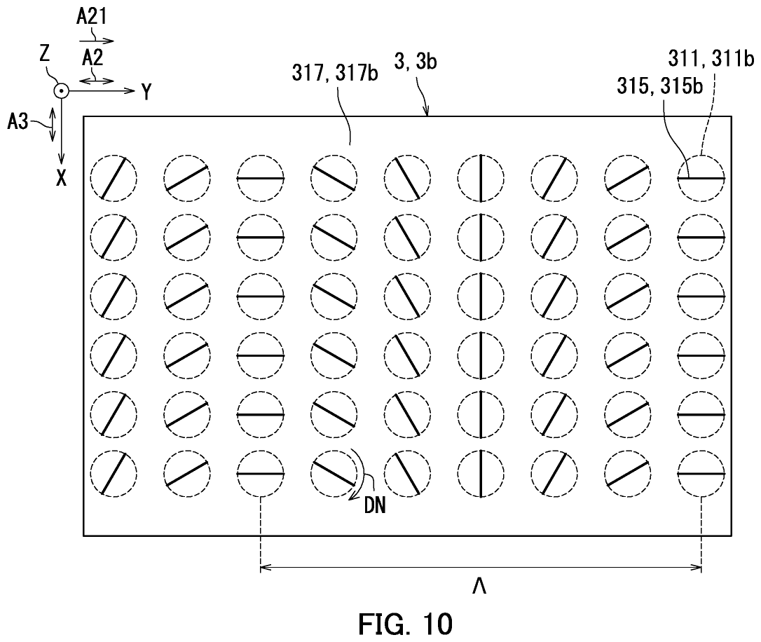

Since the helical direction of the helix of the helical structures 311 included in the light diffraction layer 3a is opposite to the helical direction of the helix of the helical structures 311 included in the light diffraction layer 3b, the spatial phases of the helical structures 311 included in the light diffraction layer 3a differ from the spatial phases of the helical structures 311 included in the light diffraction layer 3b. Therefore, the form (direction, inclination) of the reflective surfaces 321 of the light diffraction layer 3a and the form (direction, inclination) of the reflective surfaces 321 of the light diffraction layer 3b are substantially identical. Details on this point are described later with reference to FIG. 10. Note that in FIG. 9, slanted lines indicating the light diffraction layers 3 are not slanted lines indicating a cross-section but rather the reflective surfaces 321.

The light diffraction layer 3a reflects and diffracts the light LT2 having a wavelength in a band (i.e., selective reflection band) according to the helical pitch p and the refractive index of the helical structures 311 of the light diffraction layer 3a, the inclination angle φ and light incident angle θi of the reflecting surface 321, and having circular polarization (e.g., right-handed circular polarization) in a direction of circulation that is the same direction as the helical direction (e.g., rightward direction of circulation) of the helix of the helical structures 311 of the light diffraction layer 3a.

By contrast, the light diffraction layer 3a transmits the light LT31 and LT32. The light LT31 has the same wavelength as the wavelength of the light LT2 reflected by the helical structures 311 of the light diffraction layer 3a and has circular polarization (e.g., left-handed circular polarization) in a direction of circulation (e.g., leftward direction of circulation) that is opposite to the helical direction of the helix of the helical structures 311 of the light diffraction layer 3a. The light LT32 has a wavelength different from the wavelength of the light LT2 reflected by the light diffraction layer 3a.

Furthermore, the light diffraction layer 3b reflects and diffracts the light LT31 having a wavelength in a band (i.e., selective reflection band) according to the helical pitch p and the refractive index of the helical structures 311 of the light diffraction layer 3b and having circular polarization (e.g., left-handed circular polarization) in a direction of circulation that is the same direction as the helical direction (e.g., leftward direction of circulation) of the helix of the helical structures 311 of the light diffraction layer 3b. In other words, the light diffraction layer 3b reflects and diffracts the light LT31 having a polarization state opposite to the polarization state of the light LT2 reflected by the light diffraction layer 3a. In yet other words, the light diffraction layers 3a and 3b have a complementary relationship with respect to the reflection of light depending on the polarization state of light.

By contrast, the light diffraction layer 3b transmits the light LT32. The light LT32 has a wavelength differing from the wavelength of the light LT31 reflected by the light diffraction layer 3b.

According to the second embodiment as described above with reference to FIGS. 2 and 9, by arranging the light diffraction layers 3a and 3b, which have a complementary relationship with respect to reflection of light dependent on the polarization state of the light, not only one of right-handed circularly polarized light and left-handed circularly polarized light but both right-handed circularly polarized light and left-handed circularly polarized light can be allowed to enter the optical waveguide layer 1. That is, light can be allowed to enter the optical waveguide layer 1 regardless of the polarization state of the light. As a result, the transfer efficiency of light to the optical waveguide layer 1 can be improved.

When the transfer efficiency of light to the optical waveguide layer 1 can be improved, the light quantity received per unit of time by the light receiving body 5 can be increased. Thus, for example, in a case where the light receiving body 5 is a solar cell, the amount of electricity generated by the solar cell can be increased. In a case where the light receiving body 5 is a solar cell, the optical device 100A functions as a “solar cell device”. For another example, in a case where the light receiving body 5 is an optical sensor, the detection accuracy of the optical sensor can be improved.

By contrast, in the optical device 100A, similarly to the first embodiment, since light can be guided from the optical waveguide layer 1 toward the light receiving body 5 without including a phosphor in the optical waveguide layer 1, the transparency of the optical waveguide layer 1 can be further improved compared to a case where the optical waveguide layer 1 includes a phosphor.

That is, according to the second embodiment, the amount of electricity generated by the light receiving body 5 as a solar cell can be increased while ensuring the transparency of the optical waveguide layer 1, for example. In addition, the detection accuracy of the light receiving body 5 as an optical sensor can be improved while ensuring the transparency of the optical waveguide layer 1, for example.

Three or more light diffraction layers 3 may be arranged in the optical device 100A. In this case, it is preferable to arrange an even number of light diffraction layers 3 in the optical device 100A. Even in this preferable example, the light diffraction layers 3a and 3b opposite to each other in the first direction A1 preferably have a complementary relationship with respect to reflection of light depending on the polarization state of light.

Here, the light diffraction layers 3a and 3b constitute a “light diffraction layer pair 30”. Then, in a case where the optical device 100A includes a plurality of light diffraction layer pairs 30, either or both the helical pitch p of the helical structures 311 and the refractive index of the elements 315 preferably differ between the light diffraction layer pairs 30. This is because by differentiating the reflection wavelength range (specifically, the selective reflection band) between the light diffraction layer pairs 30, more rays of the light LT1 incident to the optical device 100A can be allowed to enter the optical waveguide layer 1 from the light diffraction layer pairs 30. That is, because the transfer efficiency of light to the optical waveguide layer 1 can be further improved.

Next, the spatial phases of the helical structures 311 for achieving reflection and diffraction of the light LT2 and LT31 with mutually different polarization by the light diffraction layers 3a and 3b are described with reference to FIGS. 3A and 10.

In the following description of the spatial phase, the letter “a” may be appended to the reference sign of each constituent of the light diffraction layer 3a and the letter “b” may be appended to the reference sign of each constituent of the light diffraction layer 3b as necessary. Furthermore, the schematic cross-sectional view of the light diffraction layer 3b is the same as in FIG. 2, which is a schematic cross-sectional view of the light diffraction layer 3a.

FIG. 3A is a schematic plan view of the light diffraction layer 3a. FIG. 10 is a schematic plan view of the light diffraction layer 3b. As illustrated in FIGS. 3A and 10, the spatial phases of helical structures 311a in the light diffraction layer 3a differ from the spatial phases of helical structures 311b in the light diffraction layer 3b. Specifically, a direction of circulation DN of elements 315b at a first boundary surface 317b of the light diffraction layer 3b is opposite to a direction of circulation DP of elements 315a at a first boundary surface 317a of the light diffraction layer 3a in a specific direction A21. The specific direction A21 is substantially parallel to the second direction A2 and toward the positive direction of the Y axis.

In detail, at the first boundary surface 317a of the light diffraction layer 3a illustrated in FIG. 3A, the direction of orientation of the elements 315a (direction of the long axis of the elements 315a) of the helical structures 311a is changing in the rotation direction DP (e.g., anti-clockwise direction) with respect to the second direction A2 as a reference toward the specific direction A21. For example, in the period A, the direction of orientation of the elements 315a is changing from 0 degrees to +180 degrees in the specific direction A21. At the first boundary surface 317a, the sign of the spatial phase of each helical structure 311a is defined as “positive” when the elements 315a change in the rotation direction DP toward in the specific direction A21. Note that, for example, the direction of orientation of each element 315a at a second boundary surface 319a (FIG. 9) of the light diffraction layer 3a is substantially identical to the direction of orientation of each element 315a at the first boundary surface 317a of the light diffraction layer 3a.

By contrast, as illustrated in FIG. 10, at the first boundary surface 317b of the light diffraction layer 3b, the direction of orientation of the elements 315b (the directions of the long axis of the elements 315b) of the helical structures 311b is changing in the rotation direction DN (e.g., clockwise direction) with respect to the second direction A2 toward the specific direction A21. For example, in the period A, the directions of orientation of the elements 315b are changing from 0 degrees to −180 degrees toward the specific direction A21. The direction of circulation DN is a direction opposite to the direction of circulation DP. At the first boundary surface 317b, the sign of the spatial phase of each helical structure 311b is defined as “negative” when the elements 315b change in the rotation direction DN toward the specific direction A21. Note that, for example, the direction of orientation of each element 315b at a second boundary surface 319b (FIG. 9) of the light diffraction layer 3b is substantially identical to the direction of orientation of each element 315b at the first boundary surface 317b of the light diffraction layer 3b.

As described above with reference to FIGS. 3A and 10, the amount of change in the direction of orientation of each elements 315a at the first boundary surface 317a of the light diffraction layer 3a is substantially the same as the amount of change in the direction of orientation of each elements 315b at the first boundary surface 317b of the light diffraction layer 3b in the period A. Then, by reversing the sign of the spatial phase of each helical structure 311b of the light diffraction layer 3b to the sign of the spatial phase of each helical structure 311a of the light diffraction layer 3a, the form of reflective surfaces 321b of the light diffraction layer 3b can be made substantially identical to the form of reflective surfaces 321a of the light diffraction layer 3a as illustrated in FIG. 9 even when the helical direction of circulation of the helical structures 311b of the light diffraction layer 3b is opposite to the helical direction of circulation of the helical structures 311a of the light diffraction layer 3a. The form of the reflective surfaces 321a and 321b indicates the direction (inclination) of the reflective surfaces 321a and 321b in the examples of FIGS. 3A and 10.

In a case where the helical direction of circulation of the helical structures 311b of the light diffraction layer 3b is opposite to the helical direction of circulation of the helical structures 311a of the light diffraction layer 3a, when the sign of the spatial phase of each helical structure 311b in the light diffraction layer 3b is the same as the sign of the spatial phase of each helical structure 311a in the light diffraction layer 3a, the form of the reflective surfaces 321b of the light diffraction layer 3b is inverted relative to the form of the reflective surfaces 321a of the light diffraction layer 3a about the helical axis AX. That is, the direction (inclination) of the reflective surfaces 321b of the light diffraction layer 3b is inverted relative to the reflective surfaces 321a of the light diffraction layer 3a about the helical axis AX.

Next, a case where the light diffraction layers 3a and 3b reflect and diffract the light LT2 and LT31 having mutually different wavelength bands toward the optical waveguide layer 1 is described in detail with repeated reference to FIGS. 2 and 9.

Referring to FIGS. 2 and 9, the helical direction of the helix of the helical structures 311 included in the light diffraction layer 3a is the same as the helical direction of the helix of the helical structures 311 included in the light diffraction layer 3b. At least one of the helical pitch p of the helical structures 311 and the refractive index of the elements 315 differs between the light diffraction layers 3a and 3b. That is, the selective reflection band of the light diffraction layer 3a differs from the selective reflection band of the light diffraction layer 3b.

The light diffraction layer 3a reflects and diffracts the light LT2 having a wavelength in the selective reflection band according to the helical pitch p of the helical structures 311 and the refractive index of the elements 315 of the light diffraction layer 3a and having circular polarization (e.g., right-handed circular polarization) in a direction of circulation that is the same direction as the helical direction (e.g., rightward direction of circulation) of the helix of the helical structures 311 of the light diffraction layer 3a.

By contrast, the light diffraction layer 3a transmits the light LT31 and LT32. The light LT31 has circular polarization (e.g., right-handed circular polarization) in a direction of circulation that is the same direction as the helical direction (e.g., rightward direction of circulation) of the helix of the helical structures 311 of the light diffraction layer 3a and a wavelength different from the wavelength of the light LT2 reflected by the light diffraction layer 3a. The light LT32 has circular polarization (e.g., left-handed circular polarization) in a direction of circulation (e.g., leftward direction of circulation) that is opposite to the helical direction (e.g., rightward direction of circulation) of the helix of the helical structures 311 of the light diffraction layer 3a.

Furthermore, the light diffraction layer 3b reflects and diffracts the light LT31 having a wavelength of a selective reflection band according to the helical pitch p of the helical structures 311 and the refractive index of the elements 315 of the light diffraction layer 3b and having circular polarization (e.g. right-handed circular polarization) in a direction of circulation that is the same direction as the helical direction (e.g. rightward direction of circulation) of the helix of the helical structures 311 of the light diffraction layer 3b. The selective reflection band of the light diffraction layer 3b differs from the selective reflection band of the light diffraction layer 3a. In this case, the selective reflection bands of the light diffraction layers 3b and 3a may partially overlap as long as they include mutually different wavelengths.

By contrast, the light diffraction layer 3b transmits the light LT32 and light having a wavelength different from the wavelength of the light LT31 reflected by the light diffraction layer 3b among circularly polarized light with a direction of circulation that is the same direction as the helical direction of the helix of the helical structures 311 of the light diffraction layer 3b.

As described above with reference to FIGS. 2 and 9, the light diffraction layers 3a and 3b reflect and diffract the light LT2 and LT31 having mutually different wavelength bands toward the optical waveguide layer 1, and thus more rays of the light LT1 (light in a wider wavelength band) incident to the optical device 100A can be allowed to enter the optical waveguide layer 1 from the light diffraction layers 3a and 3b. That is, the transfer efficiency of light to the optical waveguide layer 1 can be further improved.

Here, the spatial phases of the helical structures 311 of the light diffraction layer 3a may differ from the spatial phases of the helical structures 311 of the light diffraction layer 3b. In this case, since the form (direction and inclination) of the reflective surfaces 321a of the light diffraction layer 3a and the form (direction and inclination) of the reflective surfaces 321b of the light diffraction layer 3b are different, the characteristics of reflection and diffraction of light differ between the reflective surfaces 321a and 321b. Therefore, more rays of the light LT1 (light in a wider wavelength band) incident to the optical device 100A can be allowed to enter the optical waveguide layer 1 from the light diffraction layers 3a and 3b. That is, the transfer efficiency of light to the optical waveguide layer 1 can be further improved.

According to the second embodiment as described above with reference to FIGS. 2, 3, 4, 9, and 10, at least one of the helical pitch of the helical structures 311, the refractive index of the elements 315, the helical direction of the helical structures 311, and the spatial phases of the helical structures 311 is differentiated across the light diffraction layers 3. As a result, the characteristics of reflection and diffraction of light differ across the light diffraction layers 3. Therefore, more rays of the light LT1 (light rays in a wider wavelength band, light rays in more various polarization states, or light rays at more various incident angles) incident to the optical device 100A can be allowed to enter the optical waveguide layer 1 from the light diffraction layers 3. That is, the transfer efficiency of light to the optical waveguide layer 1 can be further improved.

For example, in FIG. 9, for simplicity, an example is given in which the light LT1 is substantially perpendicularly incident to the optical device 100A, but light is incident at various incident angles in the optical device 100A. Accordingly, the incident angle θi (FIG. 3B) of light to the light diffraction layers 3 also varies. Therefore, the light diffraction layers 3 are arranged corresponding to the incident angle of light incident to the optical device 100A (light diffraction layers 3). Then, in each light diffraction layer 3, at least one of the helical pitch of the helical structures 311, the refractive index of the elements 315, the helical direction of the helical structures 311, and the spatial phases of the helical structures 311 is differentiated according to the incident angle of light incident to the optical device 100A (light diffraction layers 3). As a result, more rays of the light (light lays of more various incident angles) incident to the optical device 100A at various incident angles can be allowed to enter the optical waveguide layer 1 from the light diffraction layers 3.

The number of layered light diffraction layers 3 in the optical device 100A is not particularly limited and not limited to two light diffraction layers 3, and three or more light diffraction layers 3 may be arranged. Also, the configuration of the layered light diffraction layers 3 may be the same. For example, the helical pitch of the helical structures 311, the refractive index of the elements 315, the helical direction of the helical structures 311, and the spatial phases of the helical structures 311 may all be substantially identical across the light diffraction layers 3.

The optical device 100A may include light diffraction layers 3X described with reference to FIG. 4 instead of the light diffraction layers 3. Also, for example, in each of the light diffraction layers 3, the helical pitch p and the refractive index of the helical structures 311 are preferably set according to the wavelength of invisible light so that the helical structures 311 reflect the invisible light. Then, the light diffraction layers 3 preferably transmit visible light. Note that the visible light and invisible light are similar to the visible light and invisible light in the first embodiment, respectively.

### Third Embodiment

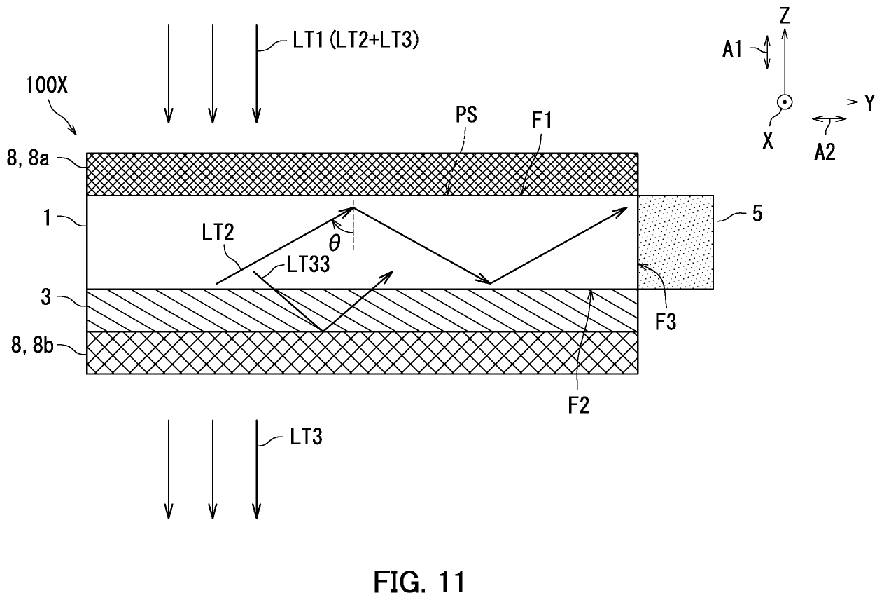

An optical device 100X according to a third embodiment of the present invention is described with reference to FIG. 11. The third embodiment mainly differs from the first embodiment in that the optical device 100X according to the third embodiment includes a plurality of light reflection layers 8. The following describes the main points of difference between the third embodiment and the first embodiment.

FIG. 11 is a schematic cross-sectional view of the optical device 100X according to the third embodiment. As illustrated in FIG. 11, the optical device 100X includes an optical waveguide layer 1, a light diffraction layer 3, a light receiving body 5, and at least one light reflection layer 8. The optical waveguide layer 1 corresponds to an example of an “optical waveguide section”. The light diffraction layer 3 corresponds to an example of a “light diffracting section”. The light reflection layer 8 corresponds to an example of a “light reflecting section”.

The light reflection layer 8 may be flexible, for example. In the example of FIG. 11, the optical device 100X includes two light reflection layers 8. In the following, one of the two light reflection layers 8 may be referred to as a “light reflection layer 8a” and the other light reflection layer 8 may be referred to as a “light reflection layer 8b”. The optical waveguide layer 1 and the light diffraction layer 3 are arranged between the light reflection layers 8a and 8b. By contrast, the light reflection layer 8a transmits the light LT1. The light LT1 preferably includes visible and invisible light. In this preferable example, the light reflection layer 8a is transparent.

The light reflection layer 8a is opposite to the optical waveguide layer 1 in the first direction A1. The light reflection layer 8a reflects the light LT2 entering the optical waveguide layer 1 from the light diffraction layer 3 toward the optical waveguide layer 1 so that the light LT2 entering the optical waveguide layer 1 is totally reflected in the optical waveguide layer 1. Therefore, according to the third embodiment, the light LT2 can be inhibited from leaking out of the optical waveguide layer 1. As a result, a light quantity received per unit of time by the light receiving body 5 can be increased. In particular, in a case where the light receiving body 5 is a solar cell, the amount of electricity generated by the solar cell can be increased. In the case where the light receiving body 5 is a solar cell, the optical device 100X functions as a “solar cell device”. By contrast, the light reflection layer 8a transmits the light LT3. The light LT3 is preferably visible light.

The light reflection layer 8b is opposite to the light diffraction layer 3 in the first direction A1. The light reflection layer 8b reflects, of the light LT2 entering the optical waveguide layer 1 from the light diffraction layer 3, light LT33 emitted from the optical waveguide layer 1 toward the optical waveguide layer 1 so that the light LT33 emitted from the optical waveguide layer 1 is totally reflected in the optical waveguide layer 1. Therefore, according to the third embodiment, the light LT33 leaking from the optical waveguide layer 1 can be allowed to re-enter the optical waveguide layer 1. As a result, a light quantity received per unit of time by the light receiving body 5 can be further increased. In particular, in a case where the light receiving body 5 is a solar cell, the amount of electricity generated by the solar cell can be further increased. By contrast, the light reflection layer 8b transmits the light LT3. The light LT3 is preferably visible light. In this preferable example, the light reflection layer 8b is transparent.

In particular, in the third embodiment, by providing the light reflection layers 8, the light LT2 and LT33 can be effectively allowed to enter the optical waveguide layer 1 and be guided even when there are defects (e.g., scratches or bumps) in the optical waveguide layer 1 or the optical waveguide layer 1 is bent.

A first example of the light reflection layers 8 is described. In the first example, the refractive index of the light reflection layer 8a is smaller than the refractive index of the optical waveguide layer 1. Accordingly, the light reflection layer 8a serves as a cladding layer. As a result, in the optical waveguide layer 1, the light LT2 satisfies a total reflection condition and the light LT2 is guided toward the light receiving body 5 while being totally reflected. The material of the light reflection layer 8a is glass or synthetic resin, for example. Preferably, the material of the light reflection layer 8a is glass or synthetic resin which transmits visible light, for example. Note that the configuration of the light reflection layer 8b may be similar to the configuration of the light reflection layer 8a.

A second example of the light reflection layers 8 is described. In the second example, the light reflection layers 8a and 8b are mirrors with a dependency on the wavelength of light and a dependency on the incident angle of light in light reflection and transmits light (e.g., visible light) in a wavelength band which is a portion of the wavelength band of the incident light. That is, the light reflection layers 8a and 8b reflect light in a wavelength band (reflection wavelength band) determined according to the incident angle of light. Therefore, in the light reflection layers 8a and 8b, the reflection wavelength band differs according to the incident angle of the light. Specifically, the light reflection layers 8a and 8b may shift the reflection wavelength band toward a shorter wavelength according to the incident angle of the light, or may shift the reflection wavelength band toward a longer wavelength according to the incident angle of the light. In the third embodiment, the reflection wavelength bands of the light reflection layers 8a and 8b and the wavelength band of light which can be diffracted by the light diffraction layer 3 differ for light incident at the same angle.

In the second example, the incident angle (approximately 90 degrees in the example of FIG. 11) of the light LT1 which is directly incident to the light reflection layer 8a from outside the optical device 100X differs from the approach angle θ of the light LT2 entering the optical waveguide layer 1 from the light diffraction layer 3. Therefore, the reflection wavelength band according to the light reflection layer 8a can be differentiated for the light LT1 and LT2. Accordingly, the light reflection layer 8a can reflect light in a different wavelength band from that of the light LT3, of the light LT1, transmitted by the optical device 100X, and can totally reflect the light LT2 guided by the optical waveguide layer 1.

In the second example, since the incident angle (approximately 90 degrees in FIG. 11) of light (referred to in the following as “light LT34”) incident to the light reflection layer 8b through the optical waveguide layer 1 from outside the optical device without being diffracted and reflected according to the light diffraction layer 3 differs from the incident angle of the light LT33 to the light reflection layer 8b, the reflection wavelength band by the light reflection layer 8b can be differentiated between the light LT34 (not illustrated) and the light LT33. Therefore, the light reflection layer 8b can reflect light in a different wavelength band from that of the light LT3, of the light LT34, transmitted by the optical device 100X, and can reflect the light LT33 toward the optical waveguide layer 1 so that the light LT33 is totally reflected by the optical waveguide layer 1.

The light reflection layers 8a and 8b according to the second example are dielectric multilayer film, for example. Dielectric multilayer film includes a plurality of dielectric layers having mutually different dielectric constants. The dielectric layers are layered so that dielectric layers having different dielectric constants are opposite to each other. For example, the dielectric multilayer film includes a plurality of first dielectric layers having a first dielectric constant and a plurality of second dielectric layers having a second dielectric constant. The first dielectric constant differs from the second dielectric constant. The first dielectric layer and the second dielectric layer are alternately layered. Note that the light reflection layers 8a and 8b may be made of uniformly oriented molecules of cholesteric liquid crystal.

In a case where the light reflection layers 8a and 8b form a dielectric multilayer film, when the incident angle of light to the light reflection layers 8a and 8b is set to θx, the reflection wavelength bands of the light reflection layers 8a and 8b shift toward a shorter wavelength side depending on approximately cosθx. An incident angle θx indicates an angle relative to a perpendicular line perpendicular to the light reflection layers 8a and 8b. In the following, the incident angle θx of light to the light reflection layer 8a may be referred to as an incident angle θxa, and the incident angle θx of light to the light reflection layer 8b may be referred to as an incident angle θxb.

An example is described in which the light reflection layers 8a and 8b form a dielectric multilayer film. Relative to the light LT1 directly incident to the light reflection layer 8a from outside the optical device 100X, the light reflection characteristics of the light reflection layer 8a are set so that the reflection wavelength band of the light reflection layer 8a is a longer wavelength band than the reflection wavelength band of the light diffraction layer 3. Specifically, when the light diffraction layer 3 transmits visible light and reflects invisible light LT2 (e.g., near-infrared light) with a longer wavelength than the visible light region, relative to the light LT1, the light reflection characteristics of the light reflection layer 8a are set so as to reflect the invisible light in a longer wavelength bans than the reflection wavelength band of the light diffraction layer 3.

Since the light LT2 incident to the light reflection layer 8a from the optical waveguide layer 1 is deflected by being reflected and diffracted by the light diffraction layer 3, the incident angle θxa (=approach angle θ) of the light LT2 to the light reflection layer 8a is larger than the incident angle (approximately 0 degrees in the example of FIG. 11) of the light LT1 to the light reflection layer 8a. Therefore, relative to the light LT2, the reflection wavelength band of the light reflection layer 8a shifts to a shorter wavelength side depending on cosθxa and becomes substantially equal to the reflection wavelength band of the light diffraction layer 3. As a result, the light reflection layer 8a totally reflects the light LT2 entering the optical waveguide layer 1 by reflection by the light diffraction layer 3. Therefore, leakage of the light LT2 from the optical waveguide layer 1 can be inhibited.

By contrast, relative to the light LT34 (not illustrated) incident to the light reflection layer 8b through the optical waveguide layer 1 from outside the optical device without being diffracted and reflected by the light diffraction layer 3, the light reflection characteristics of the light reflection layer 8b are set such that the reflection wavelength band of the light reflection layer 8b becomes a longer wavelength band than the reflection wavelength band of the light diffraction layer 3. Specifically, when the light diffraction layer 3 transmits visible light and reflects invisible light (e.g., near-infrared light) with a longer wavelength than that in the visible light region, relative to the light LT34, the light reflection characteristics of the light reflection layer 8b are set so as to reflect the invisible light in a longer wavelength band than the reflection wavelength band of the light diffraction layer 3.

Since the light LT33 incident to the light reflection layer 8b from the optical waveguide layer 1 is deflected by being reflected and diffracted by the light diffraction layer 3, the incident angle θxb of the light LT33 to the light reflection layer 8b is larger than the incident angle (approximately 0 degrees in the example of FIG. 11) of the light LT34 incident to the light diffraction layer 8b from outside the optical device 10 through the optical waveguide layer 1 without being diffracted and reflected by the light diffraction layer 3. Therefore, relative to the light LT33, the reflection wavelength band of the light reflection layer 8b shifts to a shorter wavelength side depending on cosθxb and becomes substantially equal to the reflection wavelength band of the light diffraction layer 3. As a result, the light reflection layer 8b reflects the light LT33 having a wavelength similar to that of the light LT2 toward the optical waveguide layer 1 and allows the light LT33 to enter the optical waveguide layer 1 so as to be totally reflected inside the optical waveguide layer 1. Therefore, leakage of the light LT33 from the optical waveguide layer 1 can be inhibited.

Note that the optical device 100X may include only the light reflection layer 8a or only the light reflection layer 8b. Furthermore, the optical device 100A according to the second embodiment described with reference to FIGS. 9 and 10 may include either or both of the light reflection layers 8a and 8b similarly to the third embodiment.

### Fourth Embodiment

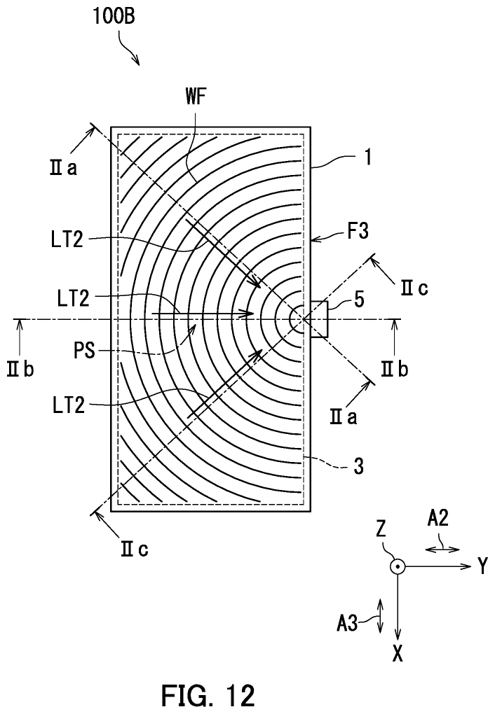

An optical device 100B according to a fourth embodiment of the present invention is described with reference to FIG. 12. The fourth embodiment mainly differs from the first embodiment in that the optical device 100B according to the fourth embodiment concentrates light guided by the optical waveguide layer 1 to the light receiving body 5. The following describes the main points of difference between the fourth embodiment and the first embodiment.

FIG. 12 is a schematic plan view of the optical device 100B according to the fourth embodiment. FIG. 12 illustrates the wavefront WF of the light LT2 to facilitate understanding of propagation of the light LT2.

As illustrated in FIG. 12, the optical device 100B includes an optical waveguide layer 1, a light diffraction layer 3, and a light receiving body 5. The optical waveguide layer 1 corresponds to an example of an “optical waveguide section”. The light diffraction layer 3 corresponds to an example of a “light diffracting section”.

The light diffraction layer 3 diffracts (specifically, reflects and diffracts) the light LT2 toward the optical waveguide layer 1 so that the light LT2 guided by the optical waveguide layer 1 is concentrated toward the light receiving body 5, and allows the light LT2 to enter inside the optical waveguide layer 1. Accordingly, the optical waveguide layer 1 guides the light LT2 so that the light LT2 is concentrated toward the light receiving body 5. As a result, the light receiving body 5 receives the light LT2 concentrated by the optical waveguide layer 1. Note that the cross sections of the optical device 100B taken along lines IIa-IIa, Ilb-IIb, and IIc-IIc in FIG. 12 are similar to the cross section of the optical 100 illustrated in FIG. 1. The cross sections of the light diffraction layer 3 taken along the lines IIa-IIa, IIb-IIb, and IIc-IIc line in FIG. 12 are also similar to the cross section of the light diffraction layer 3 illustrated in FIG. 2.

According to the fourth embodiment as described above with reference to FIG. 12, the optical waveguide layer 1 concentrates the light LT2 to the light receiving body 5, thus enabling the light quantity received per unit of time by the light receiving body 5 to be increased. Therefore, the light receiving body 5 can be miniaturized. Furthermore, for example, in a case where the light receiving body 5 is a solar cell, the amount of electricity generated by the solar cell can be increased while maintaining the transparency of the optical waveguide layer 1. In the case where the light receiving body 5 is a solar cell, the optical device 100B functions as a “solar cell device”. Also, for example, in a case where the light receiving body 5 is an optical sensor, the detection accuracy of the optical sensor can be improved while maintaining the transparency of the optical waveguide layer 1.

Note that the optical device 100B may include the light diffraction layer 3X described with reference to FIG. 7 instead of the light diffraction layer 3. Furthermore, in the optical device 100B, a plurality of light diffraction layers 3 may be layered similarly to those of the second embodiment described with reference to FIG. 9. In addition, the optical device 100B may include either or both of the light reflection layers 8a and 8b described with reference to FIG. 11.

### Fifth Embodiment

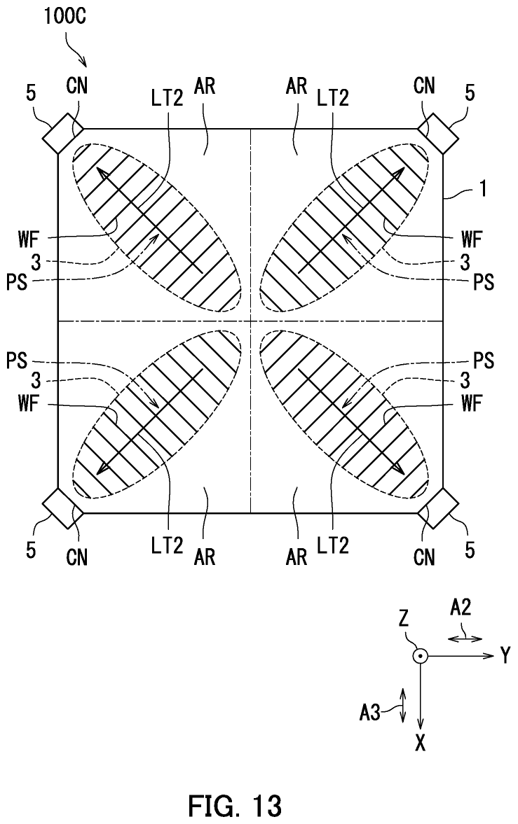

An optical device 100C according to a fifth embodiment of the present invention is described with reference to FIG. 13. The fifth embodiment mainly differs from the first embodiment in that the optical device 100C according to the fifth embodiment differentiates the direction in which light is guided for each of a plurality of optical waveguide regions AR in the optical waveguide layer 1. The following describes the main points of difference between the fifth embodiment and the first embodiment.

FIG. 13 is a schematic plan view of the optical device 100C according to the fifth embodiment. As illustrated in FIG. 13, the optical device 100C includes an optical waveguide layer 1, a plurality of light diffraction layers 3, and a plurality of light receiving bodies 5. The optical waveguide layer 1 corresponds to an example of an “optical waveguide section”. The light diffraction layer 3 corresponds to an example of a “light diffracting section”. In the case where the light receiving bodies 5 are solar cells, the optical device 100C functions as a “solar cell device”.

The optical waveguide layer 1 is divided into a plurality of optical waveguide regions AR. In the example of FIG. 13, the optical waveguide layer 1 has a substantially rectangular flat shape. Then, the optical waveguide layer 1 is divided into four optical waveguide regions AR. Each of the optical waveguide regions AR has a substantially rectangular shape. In FIG. 13, the boundaries of the optical waveguide regions AR are indicated by dashed and dotted lines. Each of the optical waveguide regions AR guides the light LT2. FIG. 13 illustrates the wavefront WF of the light LT2 to facilitate understanding of propagation of the light LT2.

The light receiving bodies 5 are arranged corresponding to the respective optical waveguide regions AR. Specifically, each of the light receiving bodies 5 is arranged in a corner CN of the corresponding optical waveguide region AR. The corner CN is an example of the end surface F3 in FIG. 1.

The light diffraction layers 3 are arranged corresponding to the respective optical waveguide regions AR. The light diffraction layers 3 are also arranged corresponding to the respective light receiving bodies 5. In addition, the light diffraction layers 3 are arranged in the same layer level as each other.

Each of the light diffraction layers 3 is opposite to the corresponding optical waveguide region AR in the first direction A1 (FIG. 1). Then, each of the light diffraction layers 3 diffracts (specifically, reflects and diffracts) the light LT2 toward the corresponding optical waveguide region AR so that the light LT2 is guided inside the corresponding optical waveguide region AR toward the corresponding light receiving body 5, and allows the light LT2 to enter inside the corresponding optical waveguide region AR. Accordingly, each of the optical waveguide regions AR guides the light LT2 toward the corresponding light receiving body 5. As a result, each of the light receiving bodies 5 receives the light LT2 guided by the corresponding optical waveguide region AR.

According to the fifth embodiment as described above with reference to FIG. 13, the optical waveguide layer 1 is divided into a plurality of optical waveguide regions AR. Then, the optical waveguide regions AR guide the light LT2 toward the corresponding light receiving bodies 5. Therefore, the distance from where the light LT2 enters the optical waveguide layer 1 to where the light LT2 reaches a light receiving body 5 via the light diffraction layers 3 is shorter than that in a case where the light LT2 is guided from an end to the other end of the optical waveguide layer 1. As a result, loss of the light LT2 guided by the optical waveguide layer 1 can be suppressed.

Here, in each of the light diffraction layers 3, the reflective surfaces 321 (FIG. 2) are inclined so as to face the side of the corresponding light receiving bodies 5. Therefore, the direction of the reflective surfaces 321 differs between the light diffraction layers 3.

The number of optical waveguide regions AR (number of divisions in the optical waveguide layer 1) is not particularly limited. In this case, the optical device 100C preferably includes the same number of light receiving bodies 5 and the same number of light diffraction layers 3 as the number of optical waveguide regions AR.

The optical device 100C may include light diffraction layers 3X described with reference to FIG. 7 instead of the light diffraction layers 3. Furthermore, a plurality of light diffraction layers 3 may be arranged for each of the optical waveguide regions AR and layered similarly to those in the second embodiment described with reference to FIG. 9. In addition, the optical device 100C may include either or both of the light reflection layers 8a and 8b described with reference to FIG. 11. Furthermore, the light diffraction layers 3 may have a structure that concentrates light onto the light receiving bodies 5 for each of the optical waveguide regions AR similarly to those in the fourth embodiment described with reference to FIG. 12.

(Variation)

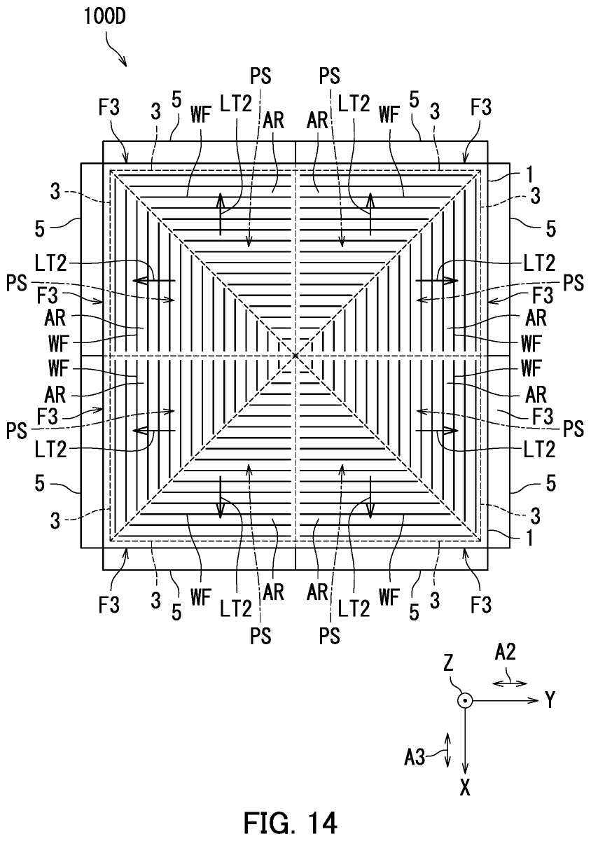

An optical device 100D according to a variation of the fifth embodiment of the present invention is described with reference to FIG. 14. The variation mainly differs from the fifth embodiment described with reference to FIG. 13 in that the light receiving bodies 5 are arranged along each edge of the optical waveguide layer 1 of the optical device 100D according to the variation. The following describes the main points of difference between the variation and the fifth embodiment.

FIG. 14 is a schematic plan view of the optical device 100D according to the variation of the fifth embodiment. As illustrated in FIG. 14, the optical waveguide layer 1 is divided into a plurality of optical waveguide regions AR. In the example of FIG. 14, the optical waveguide layer 1 is divided into eight optical waveguide regions AR. The light diffraction layers 3 are arranged corresponding to the respective optical waveguide regions AR. The light receiving bodies 5 are arranged corresponding to the respective optical waveguide regions AR. Specifically, the light receiving bodies 5 are each arranged along the end surface F3 of the corresponding optical waveguide region AR. In the example of FIG. 14, the end surface F3 indicates an outer edge surface of the optical waveguide region AR.

In the optical device 100D according to the variation similar to the optical device 100C according to the fifth embodiment, the optical waveguide regions AR guide the light LT2 toward the corresponding light receiving bodies 5. Accordingly, the distance from where the light LT2 enters the optical waveguide layer 1 to where the light LT reaches the light receiving bodies 5 via the light diffraction layers 3 is shortened. As a result, loss of the light LT2 guided by the optical waveguide layer 1 can be reduced. In the case where the light receiving bodies 5 are solar cells, the optical device 100D functions as a “solar cell device”.

In the first to fifth embodiments and variations described with reference to FIGS. 1 to 14, each light receiving body 5 was arranged on the end surface F3 of the optical waveguide layer 1. However, the position of the light receiving body 5 is not particularly limited as long as the light receiving body 5 can receive light guided by the optical waveguide layer 1. Therefore, the light receiving body 5 may be disposed on a part other than the end surface F3 of the optical waveguide layer 1. For example, as illustrated in FIGS. 1, 3, 9, and 11 to 14, the light receiving body 5 may be disposed at a position PS in the optical waveguide layer 1. In this case, for example, the light receiving body 5 is embedded in the optical waveguide layer 1 at the position PS. Furthermore, in this case, the light diffraction layer 3 diffracts (specifically, reflects and diffracts) light toward the optical waveguide layer 1 so that the light is guided toward the light receiving body 5 in the optical waveguide layer 1. Specifically, the reflective surfaces 321 of the light diffraction layer 3 are constituted by differentiating the spatial phases of the helical structures 311 so that the light is guided toward the light receiving body 5 in the optical waveguide layer 1.

### Sixth Embodiment

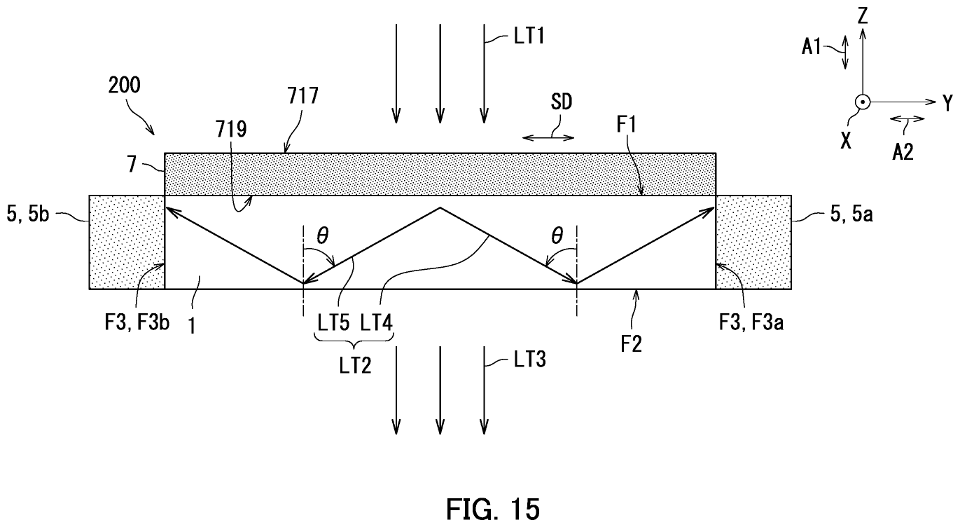

An optical device 200 according to a sixth embodiment of the present invention is described with reference to FIGS. 15 to 17. The optical device 200 according to the sixth embodiment mainly differs from the optical device 100 according to the first embodiment in which the light diffraction layer 3 is a reflective diffractive element in that a light diffraction layer 7 of the optical device 200 according to the sixth embodiment is a transmissive diffractive element. The following describes the main points of difference between the sixth embodiment and the first embodiment.

First, the optical device 200 is described with reference to FIG. 15. FIG. 15 is a schematic cross-sectional view of the optical device 200 according to the sixth embodiment. As illustrated in FIG. 15, the optical device 200 includes an optical waveguide layer 1, a light diffraction layer 7, and a plurality of light receiving bodies 5. In the example of FIG. 15, the optical device 200 includes two light receiving bodies 5a and 5b. The optical waveguide layer 1 corresponds to an example of an “optical waveguide section”. The light diffraction layer 7 corresponds to an example of a “light diffracting section”.

The optical waveguide layer 1 guides the light LT2 which satisfies an optical waveguide condition in the optical waveguide layer 1. This point is similar to that in the first embodiment. In particular, in the sixth embodiment, the optical waveguide condition indicates that the approach angle θ of the light LT2, which is diffracted (specifically transmitted and diffracted) by the light diffraction layer 7 and enters the optical waveguide layer 1, is equal to or larger than the critical angle θc at which total reflection occurs. The light LT2 includes light LT4 and LT5 which are guided in mutually opposite directions.

The optical waveguide layer 1 has a plurality of end surfaces F3. In the example of FIG. 15, the optical waveguide layer 1 has two end surfaces F3. The two end surfaces F3 are opposite to each other in the direction SD. In the example of FIG. 15, the two end surfaces F3 are opposite to each other in the second direction A2. One of the two end surfaces F3 may be referred to as an “end surface F3a” and the other may be referred to as an “end surface F3b”. The light LT4 guided inside the optical waveguide layer 1 is emitted from the end surface F3a and the light LT5 guided inside the optical waveguide layer 1 is emitted from the end surface F4b.

The light diffraction layer 7 diffracts the light LT2 in at least a portion of the wavelength band of the light LT1 incident to the light diffraction layer 7 toward the optical waveguide layer 1, and allows the light LT2 to enter the optical waveguide layer 1. Specifically, the light diffraction layer 7 has optical anisotropy (birefringence) and a plurality of optic axes (referred to in the following as “optic axes 400”). The light diffraction layer 7 is disposed in a different layer level from the optical waveguide layer 1. The light diffraction layer 7 is opposite to the optical waveguide layer 1 (specifically, the first main surface F1) in the first direction A1. The light diffraction layer 7 has a first boundary surface 717 and a second boundary surface 719.

The light diffraction layer 7 diffracts the light LT2 in at least a portion of the wavelength band of the light LT1 incident to the light diffraction layer 7 toward the optical waveguide layer 1 according to the distribution of the orientations of the optic axes 400, and allows the light LT2 to enter the optical waveguide layer 1. In this case, the light diffraction layer 7 allows the light LT2 to enter the optical waveguide layer 1 at an acute angle. By contrast, the light diffraction layer 7 allows the light LT3, which is a portion of the light LT1, to penetrate and enter the optical waveguide layer 1 without being diffracted. The light LT3 then penetrates the optical waveguide layer 1.

In particular, in the sixth embodiment, the light diffraction layer 7 transmits the light LT1 incident to the light diffraction layer 7. In transmitting the light LT2, the light diffraction layer 7 diffracts the light LT2 toward the optical waveguide layer 1 according to the distribution of the orientations of the optic axes 400, and allows the light LT2 to enter the optical waveguide layer 1 at an acute angle. By contrast, the light diffraction layer 7 preferably transmits the light LT3 in at least a portion of in at least a portion of the wavelength band in the visible light region of the light LT1 incident to the light diffraction layer 7 without diffracting the light LT3. In this preferable example, the light diffraction layer 7 is transparent because the light LT3 includes visible light.

Here, as long as “transparent” is as defined in the first embodiment, the clarity of an image of an object visible via the light diffraction layer 7 does not matter in the present specification. That is, not all portion of the light transmitted and diffracted by the light diffraction layer 7 is totally reflected by the optical waveguide layer 1, but a portion of the light transmitted and diffracted by the light diffraction layer 7 penetrates the light diffraction layer 7. As a result, the image of the object visible via the light diffraction layer 7 is diffracted and visible. Even in this case, the light diffraction layer 7 is transparent.

The light diffraction layer 7 may also be flexible, for example. The light diffraction layer 7 may be in contact with the optical waveguide layer 1 (specifically, the first main surface F1), or a transparent layer such as an adhesive layer may be interposed between the light diffraction layer 7 and the optical waveguide layer 1. The refractive index of the layer interposed between the light diffraction layer 7 and the optical waveguide layer 1 is preferably, substantially equal to the refractive index of the optical waveguide layer 1. The light diffraction layer 7 is configured as a film, for example, similarly to the light diffraction layer 3 in the first embodiment.

The light receiving body 5a is opposite to the end surface F3a of the optical waveguide layer 1 in the direction SD (second direction A2) and receives the light LT4 emitted from the end surface F3a. The light receiving body 5b is opposite to the end surface F3b of the optical waveguide layer 1 in the direction SD (second direction A2) and receives the light LT5 emitted from the end surface F3b. The light receiving bodies 5a and 5b are solar cells, optical sensors, or image sensors, for example. In a case where the light receiving bodies 5a and 5b are solar cells, the optical device 200 functions as a “solar cell device”.

Operation of the optical device 200 is described with continued reference to FIG. 15. The light LT1 is incident to the optical device 200 from a side on which the light diffraction layer 7 is disposed. That is, the light LT1 is incident from the first boundary surface 717 of the light diffraction layer 7. In the first embodiment, the light LT1 is sunlight. The incident angle of the light LT1 is not particularly limited.

The light diffraction layer 7 transmits and diffracts the light LT2 in at least a portion of the wavelength band of the light incident to the light diffraction layer 7 toward the optical waveguide layer 1. Specifically, the light diffraction layer 7 transmits and diffracts the light LT2 toward the optical waveguide layer 1 at the approach angle θ that yields total reflection inside the optical waveguide layer 1. That is, the light diffraction layer 7 transmits and diffracts the light LT2 toward the optical waveguide layer 1 at the approach angle θ which satisfies the optical waveguide condition in the optical waveguide layer 1. In this case, the light LT2 enters inside the optical waveguide layer 1 from the first main surface F1.

Then, the optical waveguide layer 1 guides the light LT2 entering inside the optical waveguide layer 1 by transmission and diffraction by the light diffraction layer 7, and guides the light LT2 to the light receiving body 5. As a result, the light receiving body 5 receives the light LT2 guided by the optical waveguide layer 1.

By contrast, the light diffraction layer 7 preferably transmits the light LT3 in at least a portion of the wavelength band in the visible light region of the light LT1 without diffraction. Therefore, according to this preferable example, the light diffraction layer 3 is transparent. Note that the light diffraction layer 7 may transmit the light LT3 in a wavelength band which is the entire visible light region of the light LT1 without diffraction.

According to the sixth embodiment as described above with reference to FIG. 15, the light diffraction layer 7 allows the light LT2 to enter the optical waveguide layer 1 by diffracting (specifically, transmitting and diffracting) the light LT2 and guides the light LT2 to the optical waveguide layer 1. Therefore, the optical device 200 can guide the light LT2 from the optical waveguide layer 1 toward the light receiving bodies 5 without including a phosphor in the optical waveguide layer 1. In particular, in the sixth embodiment, the light receiving bodies 5 are solar cells. Therefore, the solar cells can receive the light LT2 guided by the optical waveguide layer 1 and generate electricity.

In the sixth embodiment, the light diffraction layer 7 preferably transmits and diffracts light LT2 which includes invisible light. The light diffraction layer 7 more preferably transmits and diffracts light LT2 which includes no visible light and only invisible light.

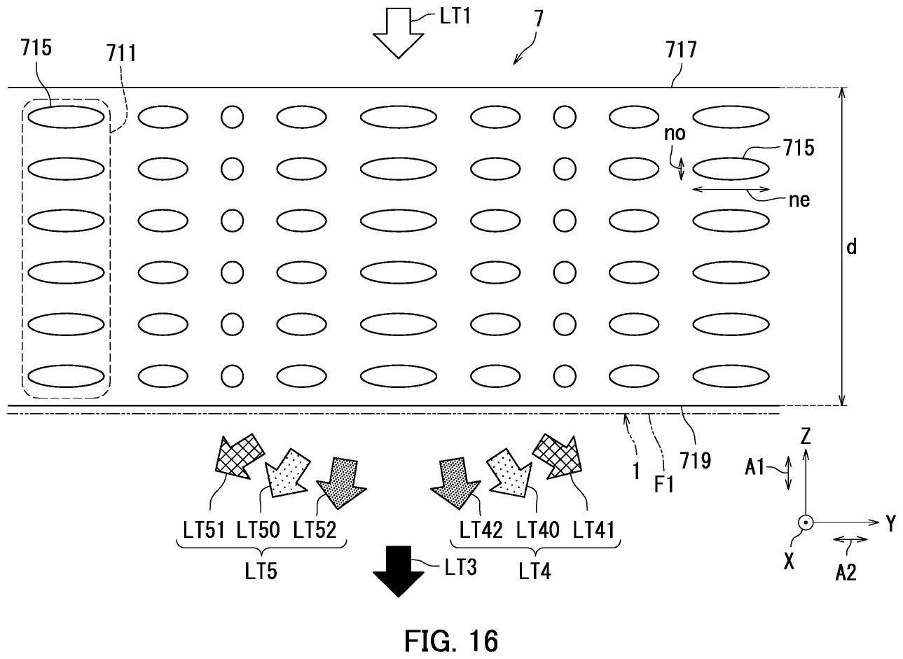

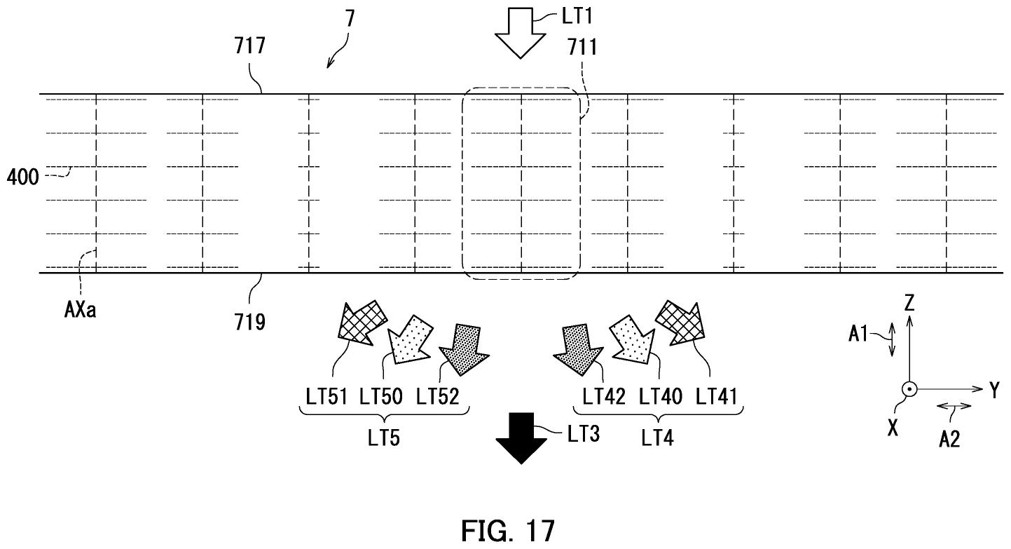

Next, the light diffraction layer 7 is described with reference to FIG. 16. FIG. 16 is a schematic cross-sectional view of the structure of the light diffraction layer 7. As illustrated in FIG. 16, the light diffraction layer 7 includes a plurality of structures 711. Each of the structures 711 extends in the first direction A1. That is, the axes of the structures 711 (referred to in the following as “axes AXa”) are substantially perpendicular to the optical waveguide layer 1 (specifically, the first main surface F1). Each axis AXa (FIG. 17 described below) is substantially parallel to the first direction A1. Each of the helical structures 711 contains a plurality of elements 715. In each of the structures 711, the elements 715 are layered in the first direction A1 without rotating. That is, in each of the structures 711, the directions of orientation of the elements 715 are substantially identical. Each element 715 is a molecule, for example.

The structures 711 are aligned in the second direction A2. In this case, the orientation of the structures 711 is changing (rotating) in the second direction A2. That is, in the structures 711, the direction of orientation of the elements 715 is changing (rotating) in the second direction A2. In the example of FIG. 16, the orientation of the structures 711 is changing (rotating) linearly in the second direction A2. That is, in the structures 711, the direction of orientation of the elements 715 is changing (rotating) linearly in the second direction A2. “Changing linearly” indicates, for example, that each amount of change in the orientation of the structures 711 and in the directions of orientation of the elements 715 are expressed as a linear function.

By contrast, although not appearing in FIG. 16, the orientation of the structures 711 aligned in the third direction A3 (direction perpendicular to the paper surface) which is orthogonal to the first and second directions A1 and A2, is substantially identical. That is, the directions of orientation of the elements 715 of the structures 711 aligned in the third direction A3 are substantially identical. For example, when the light diffraction layer 7 is cut in XY planes, the orientations of the elements 715 in all of the cut planes is similar in the Z axis direction to the orientation of the elements 315 illustrated in FIG. 3.

The light diffraction layer 7 (specifically, the structures 711 and elements 715) has optical anisotropy (uniaxial anisotropy in the example of FIG. 16). Then, the elements 715 have a refractive index ne for extraordinary light and a refractive index no for ordinary light. The refractive index ne indicates the refractive index of the elements 715 in a long axial direction. The refractive index no indicates the refractive index of the elements 715 in a short axial direction. Birefringence Δn of the light diffraction layer 7 is expressed by formula (4). Also, retardation R of the light diffraction layer 7 is expressed by formula (5). In formula (5), “d” indicates a length of the light diffraction layer 7 in the first direction A1. That is, “d” indicates thickness of the light diffraction layer 7.

Δn=ne−no (4)

R=Δn×d (5)

Here, as illustrated in FIG. 16, the light diffraction layer 7 diffracts the light LT4 and LT5 of the light LT1. The light LT4 includes, for example, light LT40, LT41, and LT42 with different wavelengths and diffraction angles. Furthermore, the light LT5 includes, for example, light LT50, LT51, and LT52 with different wavelengths and diffraction angles. The light LT40 to LT42 included in the light LT4 and the light LT50 to LT52 included in the light LT5 exhibit diffraction efficiencies that depend on the ratio (R/λ) of retardation to the wavelengths of the light LT40 to LT42 and LT50 to LT52. When the relationship in formula (6) is satisfied, the diffraction efficiency is theoretically 100%. Although the light LT40 to LT42 respectively included in the light LT4 and the light LT50 to LT52 included in the light LT5 may exhibit different respective diffraction efficiencies, each of the light LT40 to LT42 and LT50 to LT52 preferably satisfies the relationship of formula (6) and exhibit high diffraction efficiency of 100%.

R/λ=½ (6)

Light of the light LT1 that is not diffracted penetrates the light diffraction layer 7. The light diffraction layer 7 diffracts or transmits light rays with different wavelengths, depending on the ratio of the retardation R of the light diffraction layer 7 to the wavelength λ of the light included in the light LT1. Of all light rays included in the light LT1, the proportion (diffraction efficiency) of diffracted light rays is given by formula (7), and the proportion of light rays transmitted without diffraction is given by formula (8).

sin²(πR/λ) (7)

cos²(πR/λ) (8)

In the sixth embodiment, the retardation R of the light diffraction layer 7 preferably satisfies formula (6) for all wavelengths λ if the light lays included in the light LT1. According to this preferable example, light rays in the entire wavelength range of the light LT1 is diffracted.

The light diffraction layer 7 with the retardation R satisfying formula (6) divides light, of the light LT1, with the wavelength λ into right-handed circularly polarized light LT40 and left-handed circularly polarized light LT50, and diffracts (specifically, ±first order diffraction) the light LT40 and LT50 in directions away from each other (opposite directions).

In addition, the light diffraction layer 7 divides light, of the light LT1, with a wavelength near the wavelength λ and longer than the wavelength λ into right-handed circularly polarized light LT41 and left-handed circularly polarized light LT51, and diffracts the light LT41 and LT51 in directions away from each other (opposite directions). In addition, the light diffraction layer 7 divides light, of the light LT1, with a wavelength near the wavelength λ and shorter than the wavelength λ into right-handed circularly polarized light LT42 and left-handed circularly polarized light LT52 and diffracts the light LT42 and LT52 in directions away from each other (opposite directions). As such, the light diffraction layer 7 diffracts light with a wavelength near the wavelength λ at a larger angle as the wavelength increases.

In particular, in the sixth embodiment, the light diffraction layer 7 is made of liquid crystal. Specifically, the light diffraction layer 7 is made of nematic liquid crystal. That is, the structures 711 of the light diffraction layer 7 are made of nematic liquid crystal. Therefore, each of the elements 715 included in a structure 711 is a liquid crystal molecule. Note that the liquid crystal of the light diffraction layer 7 is not limited to nematic liquid crystal as long as it can transmit and diffract light. For example, the liquid crystal of the light diffraction layer 7 may be smectic liquid crystal, discotic liquid crystal, columnar liquid crystal, or liquid crystal with a chirality of these liquid crystals. Also, when the light diffraction layer 7 is made of liquid crystal, for example, the light diffraction layer 7 is formed as a film. This point is similar to the first embodiment.

The light diffraction layer 7 is not limited to being made of liquid crystal as long as it can transmit and diffract light. For example, the light diffraction layer 7 is a structural birefringent medium.

Next, optic axes 400 of the light diffraction layer 7 are described with reference to FIGS. 16 and 17. FIG. 17 is a schematic cross-sectional view of the optic axes 400 of the light diffraction layer 7. In FIG. 17, each optic axis 400 is indicated by a dashed line. As illustrated in FIGS. 16 and 17, a plurality of optic axes 400 correspond to a plurality of respective elements (plurality of liquid crystal molecules) 715. That is, each of the elements 715 has an optic axis 400. The orientation of the optic axis 400 substantially coincides with the direction of orientation of the corresponding element 715. Specifically, the orientation of the optic axis 400 substantially coincides with the orientation of the major axis of the corresponding element 715.

The plurality of optic axes 400 includes two or more optic axes 400 with mutually different orientations. Specifically, the orientations of two or more of the optic axes 400 correspond to respective two or more elements 715 with mutually different directions of orientation among the elements 715. Accordingly, a plurality of optic axes 400 are distributed in the light diffraction layer 7. Specifically, the optic axes 400 are distributed corresponding to the spatial distribution of the elements 715. The light diffraction layer 7 then diffracts the light LT4 and LT5 according to the distribution of the optic axes 400. In the sixth embodiment, the light diffraction layer 7 transmits and diffracts the light LT4 and LT5 according to the distribution of the optic axes 400.

(Variation)

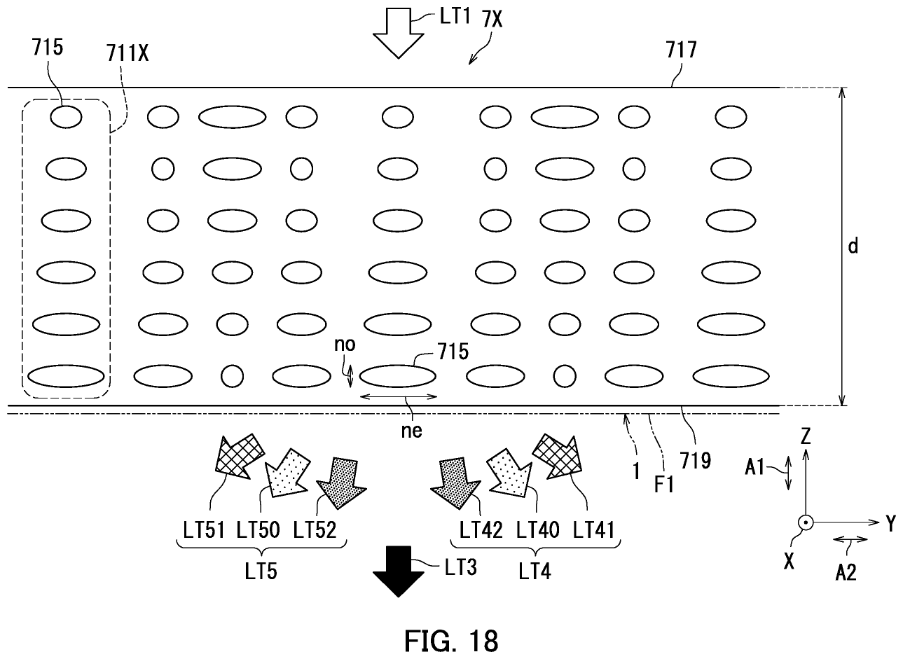

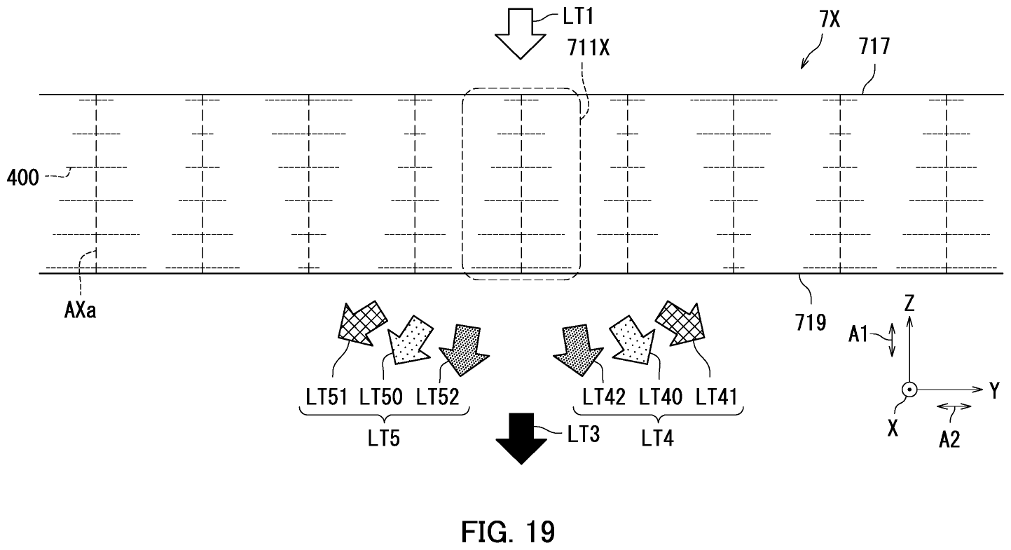

An optical device 200 according to a variation of the sixth embodiment of the present invention is described with reference to FIGS. 18 and 19. The variation mainly differs from the sixth embodiment described with reference to FIGS. 17 and 18 in that the structures 711 of the optical device 200 according to the variation are twisted. The following describes the main points of difference between the variation and the sixth embodiment.

FIG. 18 is a schematic cross-sectional view of a light diffraction layer 7X of the optical device 200 according to the variation. As illustrated in FIG. 18, the light diffraction layer 7X includes a plurality of structures 711X. The light diffraction layer 7X corresponds to an example of a “light diffracting section”.

Each of the structures 711X extends in the first direction A1. Each of the structures 711X includes a plurality of elements 715. In each of the structures 711X, the elements 715 are layered in the first direction A1 in a twisting manner. The twist of the structures 711 in the first direction A1 is less than one period (less than 360 degrees). Note that the twist of the structures 711 in the first direction A1 may be one period or greater, but the number of periods is relatively small. Specifically, the number of periods of the twist of the structures 711X is a small number. When the twist of the structures 711X is less than one period, or the number of periods of the twist of the structures 711X is relatively small, the light diffraction layer 7 functions as a transmissive diffraction element which transmits light. The light diffraction layer 7X transmits and diffracts the light LT2 of the light LT1 and transmits the light LT3 of the light LT1 without diffraction, similarly to the light diffraction layer 7 described with reference to FIG. 16.

The structures 711X are aligned in the second direction A2. In this case, in the structures 711X, the directions of orientation of the elements 715 are changing in the second direction A2. By contrast, although not appearing in FIG. 18, in the structures 711 aligned in the third direction A3 (perpendicular to the paper surface) which is orthogonal to the first and second directions A1 and A2, the directions of orientation of the elements 715 opposite to each other in the third direction A3 are substantially identical. For example, when the light diffraction layer 7X is cut in XY planes, the directions of orientation of the elements 715 aligned in the X axial direction (third direction A3) are substantially identical in the cut planes.

The light diffraction layer 7X (specifically, the structures 711X and elements 715) has optical anisotropy (uniaxial optical anisotropy in the example of FIG. 18) similarly to the light diffraction layer 7. Then, the effective retardation R of the light diffraction layer 7X is expressed by formula (5), for example. As an example, the diffraction characteristics of the light diffraction layer 7X are similar to the diffraction characteristics of the light diffraction layer 7 in FIG. 16.

In particular, in the variation, the light diffraction layer 7X is made of twisted nematic liquid crystal. That is, the structures 711X of the light diffraction layer 7X each are twisted nematic liquid crystal.

Next, optic axes 400 of the light diffraction layer 7X are described with reference to FIGS. 18 and 19. FIG. 19 is a schematic cross-sectional view of the optic axis 400 of the light diffraction layer 7X. In FIG. 19, each optic axis 400 is indicated by a dashed line. As illustrated in FIGS. 18 and 19, a plurality of optic axes 400 correspond to a plurality of respective elements (plurality of liquid crystal molecules) 715. Then, in each structure 711X, the optic axes 400 are twisted corresponding to the elements 715.

The optic axes 400 are distributed corresponding to the spatial distribution of the elements 715. The light diffraction layer 7X then diffracts the light LT4 and LT5 according to the distribution of the optic axes 400. In the variation, the light diffraction layer 7X transmits and diffracts the light LT4 and LT5 according to the distribution of the optic axes 400.

In the optical devices 200 according to the sixth embodiment and the variation, a plurality of light diffraction layers 7 (plurality of light diffraction layers 7X) may be layered similarly to those in the second embodiment described with reference to FIG. 9. In this case, at least one of the structure of the structures 711 (structures 711X) and the refractive index and the retardation R of the elements 715 is differentiated across the light diffraction layers 7 (light diffraction layers 7X). As a result, the characteristics of light transmission and diffraction differ across the light diffraction layers 7 (light diffraction layers 7X). Thus, more light rays (light lays in a wider wavelength band, light rays in more various polarization states, and light rays at more various incident angles) of the light LT1 incident to the optical device 200 can be allowed to enter the optical waveguide layer 1 from the light diffraction layer 7 (light diffraction layer 7X), further improving the transfer efficiency of light to the optical waveguide layer 1. Also, for example, light diffraction layers 7X in which the twist directions of the elements 715 are mutually reversed may be layered, or a light diffraction layer 7X including elements 715 with a rightward twist, a light diffraction layer 7 including elements 715 with no twist, and a light diffraction layer 7X including elements 715 with a leftward twist may be layered.

The optical device 200 may also include either or both of the light reflection layers 8a and 8b described with reference to FIG. 11. In this case, the light diffraction layer 7 or 7X and the optical waveguide layer 1 may be arranged between the light reflection layers 8a and 8b, only the light reflection layer 8a may be disposed opposite to the first boundary surface 717 of the light diffraction layer 7 or 7X, or only the light reflection layer 8b may be disposed opposite to the second main surface F2 of the optical waveguide layer 1. In addition, the optical device 200 according to the sixth embodiment or the variation thereof can be applied to the fourth and fifth embodiments and variations described with reference to FIGS. 12 to 14.

### Seventh Embodiment

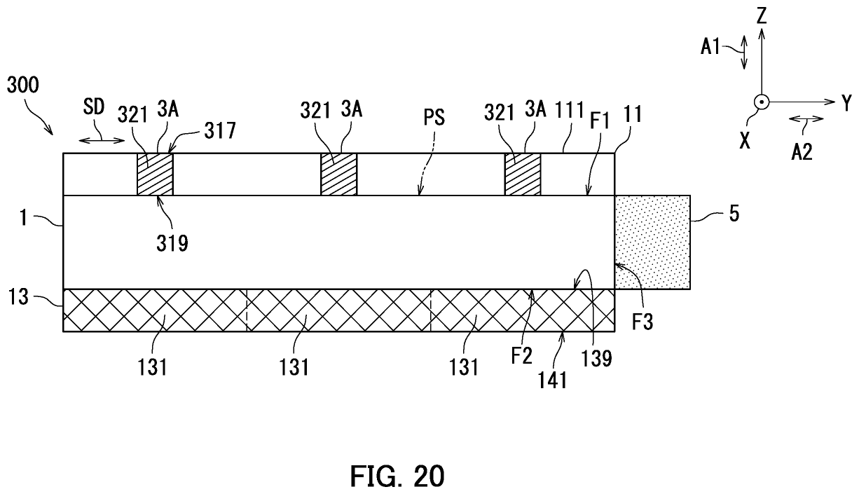

An optical device 300 according to a seventh embodiment of the present invention is described with reference to FIGS. 20 to 25B. The optical device 300 according to the seventh embodiment mainly differs from the optical device 100 according to the first embodiment described with reference to FIGS. 1 to 6B in that the optical device 300 according to the seventh embodiment includes a light concentration layer 13. The following describes the main points of difference between the seventh embodiment and the first embodiment.

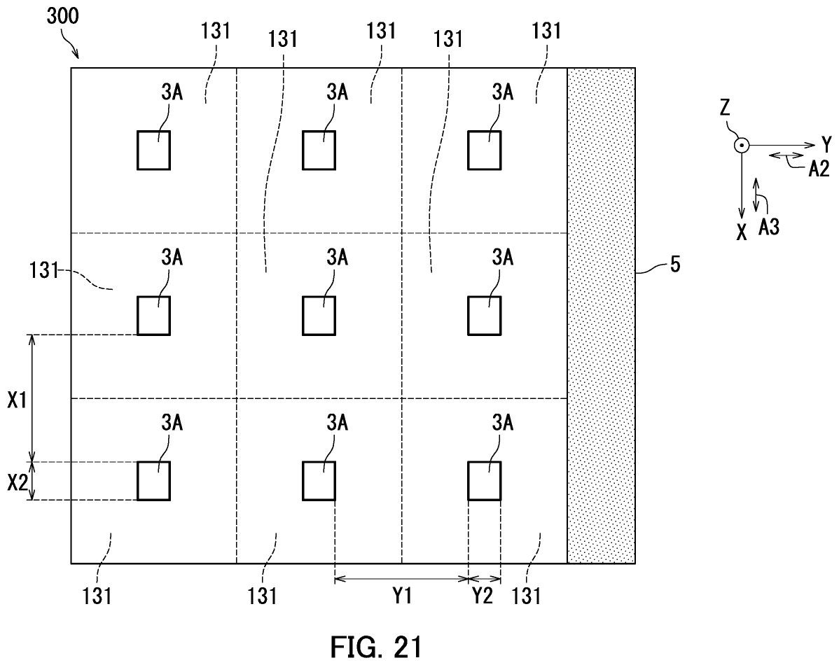

First, the optical device 300 is described with reference to FIGS. 20 and 21. FIG. 20 is a schematic cross-sectional view of the optical device 300 according to the seventh embodiment. As illustrated in FIG. 20, the optical device 300 includes an optical waveguide layer 1, at least one light diffracting section 3A, a light receiving body 5, a retention layer 11, and a light concentration layer 13. In the example of FIG. 20, the optical device 300 includes a plurality of light diffracting sections 3A. The number of the light diffracting sections 3A is not particularly limited and may be two, or four or more. The optical waveguide layer 1 corresponds to an example of an “optical waveguide section”. The light diffracting section 3A corresponds to an example of a “light diffracting section”. The light concentration layer 13 corresponds to an example of a “light concentrating section”.

The optical waveguide layer 1 is disposed between the light diffracting sections 3A and the light concentration layer 13. Note that, for example, even when one or more layers are disposed between the light diffracting sections 3A and the optical waveguide layer 1, the optical waveguide layer 1 can be perceived as being disposed between the light diffracting sections 3A and the light concentration layer 13. Furthermore, even when one or more layers are disposed between the optical waveguide layer 1 and the light concentration layer 13, the optical waveguide layer 1 can be perceived as being disposed between the light diffracting sections 3A and the light concentration layer 13.

The retention layer 11 transmits light. For example, the retention layer 11 transmits visible and invisible light. The retention layer 11 is made of synthetic resin or liquid crystal, for example. The retention layer 11 retains the light diffracting sections 3A. For example, the light diffracting sections 3A are retained in the retention layer 11 by being buried in the retention layer 11. In the example of FIG. 20, the retention layer 11 is disposed in the same layer level as the light diffracting sections 3A. The retention layer 11 is opposite to the optical waveguide layer 1 (specifically, the first main surface F1) in the first direction A1. Note that the retention layer 11 can be perceived as a “retention section”.

Each of the light diffracting sections 3A diffracts (specifically, reflects and diffracts) light. Each of the light diffracting sections 3A has optical anisotropy (birefringence) and a plurality of optic axes (not illustrated). The light diffracting sections 3A are arranged in a different layer level from the optical waveguide layer 1. Each of the light diffracting sections 3A is opposite to the optical waveguide layer 1 (specifically, the first main surface F1) in the first direction A1. Each of the light diffracting sections 3A has a first boundary surface 317, a second boundary surface 319, and a plurality of reflective surfaces 321. Otherwise, the configuration and optical properties of each of the light diffracting sections 3A are similar to the configuration and optical properties of the light diffraction layer 3 according to the first embodiment described with reference to FIGS. 1 to 5.

The light diffracting sections 3A are arranged on the same layer level. The light diffracting sections 3A cover a portion of the first main surface F1 of the optical waveguide layer 1. Specifically, the light diffracting sections 3A are arranged at regular intervals in the second direction A20. The first main surface F1 of the optical waveguide layer 1 corresponds to an example of a “main surface of an optical waveguide section”.

In reflecting light, the light concentration layer 13 concentrates the light toward the light diffracting sections 3A. The light concentration layer 13 is disposed in a different layer level from the light diffracting sections 3A and the optical waveguide layer 1. The light concentration layer 13 is opposite to the optical waveguide layer 1 (specifically, the second main surface F2) in the first direction A1. The light concentration layer 13 is disposed on the opposite side of the light diffracting sections 3A relative to the optical waveguide layer 1. The material of the light concentration layer 13 is not particularly limited as long as light can be concentrated toward the light diffracting sections 3A. An example of the material of the light concentration layer 13 is described below.

FIG. 21 is a plan view of the optical device 300. Note that in FIG. 21, the light diffracting sections 3A are indicated by bold lines to clarify the drawing. As illustrated in FIG. 21, the light diffracting sections 3A each have a substantially rectangular shape in plan view. The light diffracting sections 3A are arranged in a square lattice with intervals therebetween in the second direction A2 and the third direction A3. Specifically, an interval Y1 between a light diffracting section 3A and an adjacent light diffracting section 3A in the second direction A2 among the light diffracting sections 3A is preferably larger than a width Y2 of the light diffracting sections 3A. Furthermore, an interval X1 between a light diffracting section 3A and an adjacent light diffracting section 3A in the third direction A3 among the light diffracting sections 3A is preferably larger than a width X2 of the light diffracting sections 3A. According to these preferable examples, the light quantity of light incident to the optical waveguide layer 1 without penetrating the light diffracting sections 3A can be greater than those in a case where the interval Y1 is equal to or smaller than the width Y2 and a case where the interval X1 is equal to or smaller than the width X2. Accordingly, the optical waveguide layer 1 can guide light in a greater light quantity. As a result, the light receiving body 5 can receive light in a greater light quantity. For example, in a case where the light receiving body 5 is a solar cell, the amount of electricity generated by the solar cell can be increased. In the case where the light receiving body 5 is a solar cell, the optical device 300 functions as a “solar cell device”. Note that the width Y2 indicates the width of the light diffracting sections 3A in the second direction A2. The width X2 indicates a width of the light diffracting sections 3A in the third direction A3.

The arrangement of the light diffracting sections 3A is not limited to a square lattice, but may be a triangular or rectangular lattice, for example. Also, the shape of the light diffracting sections 3A is not particularly limited. For example, each of the light diffracting sections 3A may be substantially circular or substantially polygonal in plan view. For example, each of the light diffracting sections 3A may be substantially band-shaped and extend in the third direction A3 in plan view.

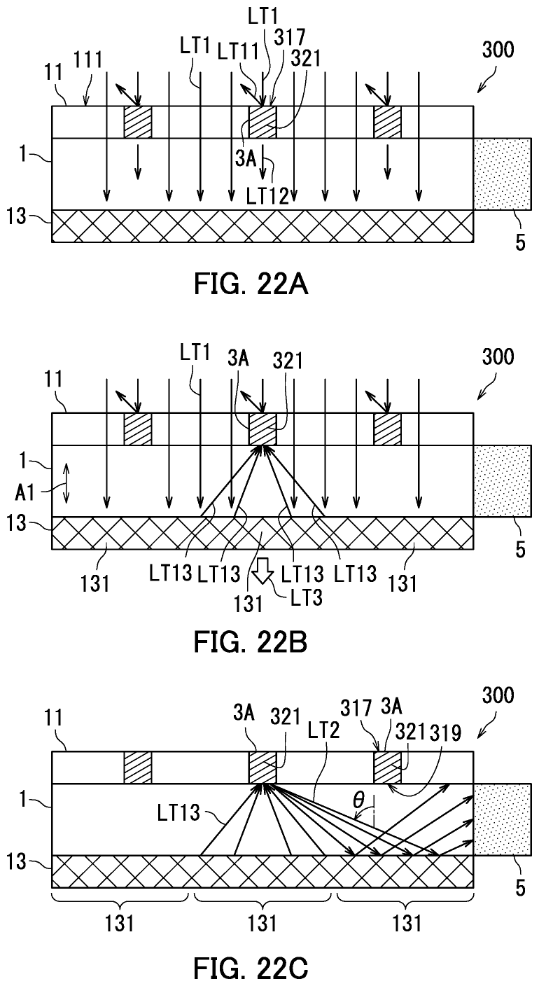

Next, the operation of the optical device 300 is described with reference to FIGS. 22A to 22C. FIGS. 22A to 22C are diagrams for describing the operation of the optical device 300. Note that light unnecessary for description of FIGS. 22A to 22C is appropriately omitted in each of FIGS. 22A to 22C to simplify the drawings. Accordingly, all of the light illustrated in FIGS. 22A to 22C is actually present in the optical device 300.

As illustrated in FIG. 22A, the light LT1 is incident to the light diffracting sections 3A and the retention layer 11 from a side opposite to the side on which the light concentration layer 13 is disposed. In the seventh embodiment, the light LT1 is sunlight. In the example of FIG. 22A, to facilitate understanding, the light LT1 is substantially perpendicularly incident to the light diffracting sections 3A and the retention layer 11. Note that the incident angle of the light LT1 is not particularly limited.

The light diffracting sections 3A (specifically, each reflective surface 321) diffract (specifically, reflect and diffract) light LT11 in a wavelength band which is a portion of the wavelength band of the light LT1 toward a side opposite to the side on which the optical waveguide layer 1 is located. For example, the light LT11 is invisible light. By contrast, the light diffracting sections 3A transmit light LT12 in a different wavelength band from that of the light LT11 of the light LT1 and allows the light LT12 to enter the optical waveguide layer 1. The light LT12 includes, for example, light in at least a portion of the wavelength band in the visible light region of the light LT1. The light LT12 may include, for example, light in a wavelength band which is the entire visible light region of the light LT1.

By contrast, the retention layer 11 transmits the light LT1 and allows the light LT1 to enter the optical waveguide layer 1. Since the surface area of a main surface 111 of the retention layer 11 is larger than the total surface area of the first boundary surface 317 of the light diffracting sections 3A, almost all portion of the light LT1 penetrates the retention layer 11 and enters the optical waveguide layer 1. That is, the light LT1 passing between mutually adjacent light diffracting sections 3A enters the optical waveguide layer 1.

Then, the optical waveguide layer 1 transmits the light LT1 and allows the light LT1 to be incident to the light concentration layer 13.

Furthermore, as illustrated in FIG. 22B, the light concentration layer 13 allows light LT13 in at least a portion of the wavelength band of the light LT1 incident to the light concentration layer 13 from the optical waveguide layer 1 between the light diffracting section 3A and the adjacent light diffracting section 3A to be incident to the light diffracting sections 3A via the optical waveguide layer 1 while concentrating the light LT13 toward the light diffracting sections 3A. That is, the light concentration layer 13 allows the light LT13 in at least a portion of the wavelength band of the light LT1 incident to the light concentration layer 13 through the optical waveguide layer 1 from a side on which the light diffracting sections 3A are located to be incident to the light diffracting sections 3A via the optical waveguide layer 1 while concentrating the light LT13 toward the light diffracting sections 3A. Specifically, the light LT13 reflected by the light concentration layer 13 is incident to the light diffracting sections 3A through the optical waveguide layer 1. For example, the light LT13 preferably includes invisible light of the light LT1. Note that the light LT13 may include light in a wavelength band which is a portion of the visible light region, for example. The light concentration layer 13 may also allow a portion or all of the light LT12 (FIG. 22A) to be incident to the light diffracting sections 3A while concentrating the light LT12 toward the light diffracting sections 3A.

Specifically, as illustrated in FIGS. 20 and 21, the light concentration layer 13 includes a plurality of light concentration units 131. The light concentration units 131 are arranged corresponding to the respective light diffracting sections 3A. Note that in FIGS. 20 and 21, delimiters of the light concentration units 131 are indicated by dashed lines to facilitate understanding. As illustrated in FIG. 22B, each of the light concentration units 131 allows the light LT13 to be incident to a corresponding one of the light diffracting sections 3A while concentrating the light LT13 toward the light diffracting section 3A. Preferably, the positions of the light diffracting sections 3A relative to the light concentration unit 131 in the first direction A1 is substantially identical with the positions of the focal points of the respective light concentration units 131. This is because the light LT13 can be concentrated more effectively on the light diffracting sections 3A. Note that in FIG. 22B, only the light LT13 concentrated on one light diffracting section 3A is illustrated to simplify the drawing.

As illustrated in FIG. 22B, the light concentration layer 13 transmits the light LT3 in a wavelength band different from that of the light LT13 of the incident light LT1. Preferably, the light concentration layer 13 transmits the light LT3 in a wavelength band which is different from that of the light LT13 and which is at least a portion of the visible light region of the incident light LT1. In this case, the light concentration layer 13 is transparent. Accordingly, the optical device 300 is transparent. Note that the light concentration layer 13 may transmit the light LT3 in a wavelength band which is different from that of the light LT13 and which is the entire wavelength band of the visible light region of the incident light LT1. Furthermore, for example, the light concentration layer 13 may transmit a portion or all of the light LT12 (FIG. 22A).

Additionally, as illustrated in FIG. 22C, each light diffracting section 3A diffracts (specifically, reflects and diffracts) the light LT2 in a wavelength band which is a portion or the entirety of the wavelength band of the light LT13 incident to the light diffracting section 3A from the light concentration layer 13 toward the optical waveguide layer 1, and allows the light LT2 to enter the optical waveguide layer 1. Specifically, the light diffracting section 3A diffracts (specifically, reflects and diffracts) the light LT2 toward the optical waveguide layer 1 according to the distribution of the orientations of a plurality of optic axes (not illustrated), and allows the light LT2 to enter the optical waveguide layer 1. In this case, the light diffraction section 3A allows the light LT2 to enter the optical waveguide layer 1 at an acute angle. Specifically, each reflective surface 321 of the light diffracting sections 3A diffracts (specifically, reflects and diffracts) the light LT2. The light LT2 is preferably invisible light, but may include visible light.

The optical waveguide layer 1 guides the light LT2 diffracted (specifically, reflected and diffracted) by the light diffracting section 3A and entering inside the optical waveguide layer 1. The light LT2 satisfies the optical waveguide condition in the optical waveguide layer 1. Note that the approach angle θ of the light LT2 has a value corresponding to the incident angle of the light LT13 to the light diffracting section 3A.

The light receiving body 5 receives the light LT2 guided inside the optical waveguide layer 1. In a case where the light receiving body 5 is a solar cell, the solar cell receives the light LT2 guided by the optical waveguide layer 1 and converts the energy of the received light LT2 to electric power.

According to the seventh embodiment as described above with reference to FIGS. 22A to 22C, the light LT2 can be guided from the optical waveguide layer 1 to the light receiving body 5 without including a phosphor in the optical waveguide layer 1 similarly to in the first embodiment. Otherwise, the optical device 300 according to the seventh embodiment has effects similar to the optical device 100 according to the first embodiment.

Here, for example, in the optical device 100 illustrated in FIG. 1, a portion (referred to in the following as “light LTP”) of the light LT2 guided by the optical waveguide layer 1 can enter the light diffraction layer 3 without being totally reflected inside the optical waveguide layer 1. The light LTP is then totally reflected at the interface between the second boundary surface 319 of the light diffraction layer 3 and air. Furthermore, a portion of the light LTP that is totally reflected at the interface enters the optical waveguide layer 1 so as to satisfy the optical waveguide condition of the optical waveguide layer 1. By contrast, the possibility is not 0% that another portion of the light LTP that is totally reflected at the interface will be reflected by the reflective surface 321 without reaching the optical waveguide layer 1 and will leak outside through the second boundary surface 319.

By contrast, even in the seventh embodiment, a portion (referred to in the following as “light LTP”) of the light LT2 guided by the optical waveguide layer 1 illustrated in FIG. 22C can enter the light diffracting sections 3A without being totally reflected inside the optical waveguide layer 1 similarly to the first embodiment. A portion of the light LTP is then totally reflected at the interface between the first boundary surface 317 of the light diffracting sections 3A and air. Furthermore, the portion of the light LTP that is totally reflected at the interface enters the optical waveguide layer 1 so as to satisfy the optical waveguide condition of the optical waveguide layer 1. By contrast, the possibility is not 0% that another portion of the light LTP that is totally reflected at the interface will be reflected by a reflective surface 321 without reaching the optical waveguide layer 1 and will leak outside through the first boundary surface 317.

However, as illustrated in FIGS. 20 and 21 in the seventh embodiment, the plurality of light diffracting sections 3A only partially cover the first main surface R1 of the optical waveguide layer 1, rather than all of it. Therefore, the quantity of the light LTP leaking to the outside can be reduced when compared to a case where most of the second main surface F2 of the optical waveguide layer 1 is covered with the light diffraction layer 3 as in the first embodiment illustrated in FIG. 1.

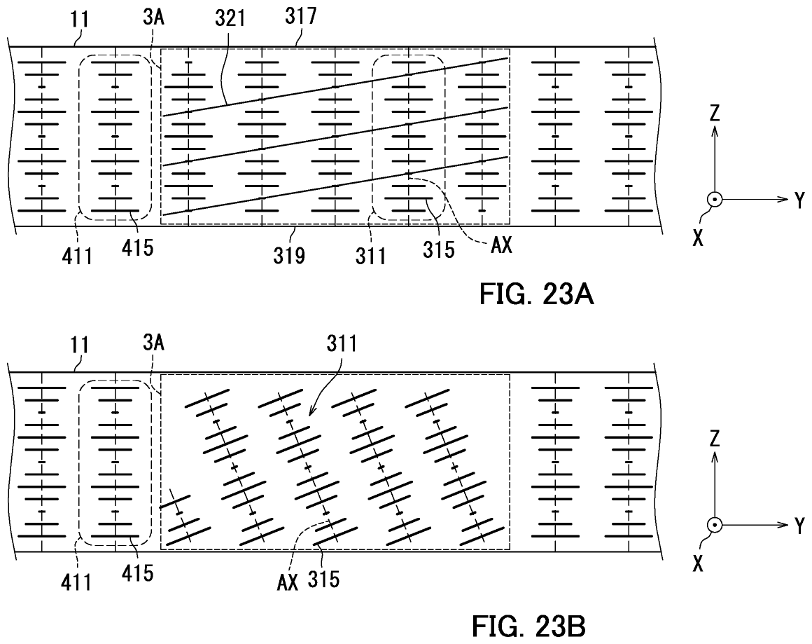

Next, each light diffracting section 3A and the retention layer 11 are described with reference to FIGS. 23A and 23B.

FIG. 23A is a schematic cross-sectional view of an example of the light diffracting section 3A and the retention layer 11. As illustrated in FIG. 23A, the configuration of the light diffracting section 3A is similar to the configuration of the light diffraction layer 3 described with reference to FIG. 2. Accordingly, the spatial phases of two or more of the helical structures 311 of the light diffracting section 3A are mutually different. As a result, a plurality of reflective surfaces 321 are formed. The light diffracting section 3A (helical structures 311) is made of cholesteric liquid crystal, for example. Otherwise, the light diffracting section 3A may be constituted by that in examples similar to the examples of the light diffraction layer 3 indicated in the first embodiment.

The retention layer 11 includes a plurality of helical structures 411. Each helical structure 411 includes a plurality of elements 415. Each element 415 is a molecule (e.g., a liquid crystal molecule), for example. The helical structures 411 are uniformly oriented. Note that the helical structures 411 need not be uniformly oriented. The retention layer 11 (helical structures 411) is made of cholesteric liquid crystal, for example, but is not particularly limited.

FIG. 23B is a schematic cross-sectional view of another example of the light diffracting section 3A and the retention layer 11. As illustrated in FIG. 23B, the configuration of the light diffracting section 3A is similar to the configuration of the light diffraction layer 3X according to the variation described with reference to FIG. 7. Accordingly, each helical axis AX of the helical structures 311 of the light diffracting section 3A is inclined with respect to the optical waveguide layer 1 (specifically, the first main surface F1 in FIG. 20). The light diffracting section 3A (helical structures 311) is made of cholesteric liquid crystal, for example.

In a case where the retention layer 11 and the light diffracting section 3A are made of liquid crystal, for example, the retention layer 11 and the light diffracting section 3A are formed as a film, similarly to the light diffraction layer 3 in the first embodiment. Furthermore, although not illustrated in FIGS. 23A and 23B, the light diffracting section 3A has a plurality of optic axes similarly to the light diffraction layer 3 of the first embodiment. Then, the optic axes correspond to the respective elements 315. Otherwise, the optic axes of the light diffracting section 3A in FIG. 23A are similar to the optic axes 400 of the light diffraction layer 3 illustrated in FIG. 4, and the optic axes of the light diffracting section 3A in FIG. 23B are similar to the optic axes 400 of the light diffraction layer 3X illustrated in FIG. 8 but reversed left to right.

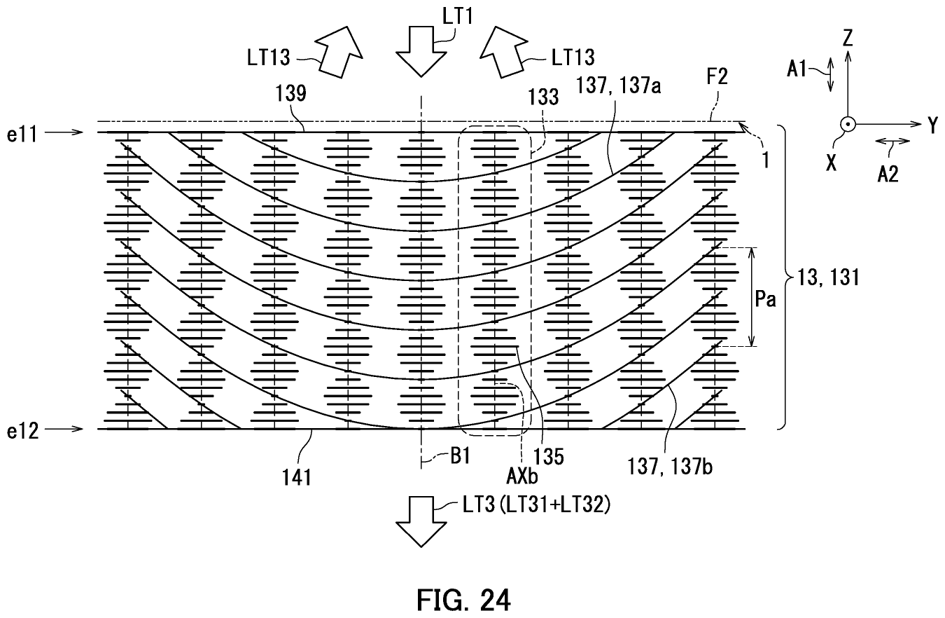

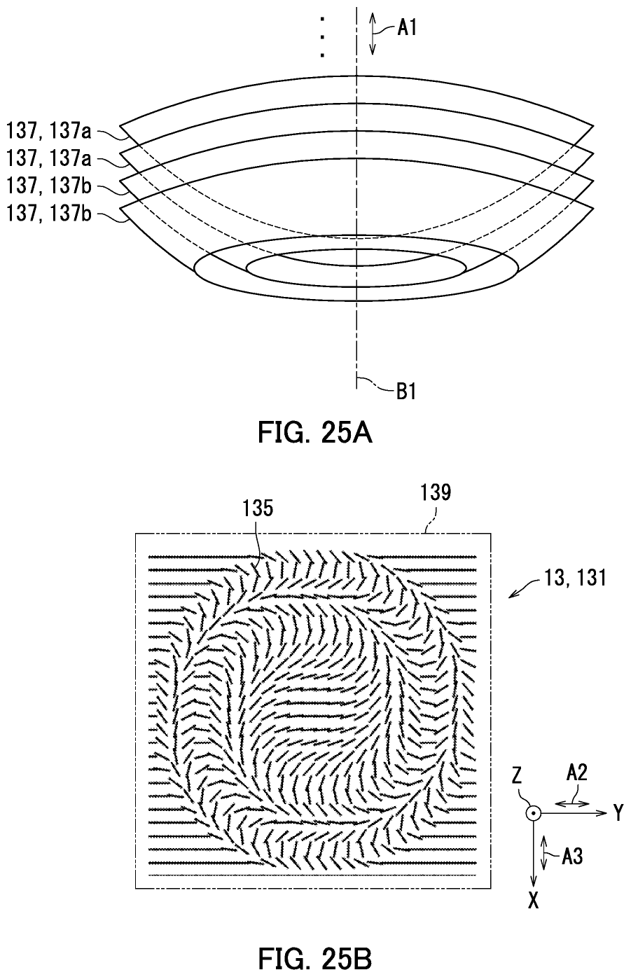

Next, an example of the light concentration layer 13 is described with reference to FIGS. 24 to 25B. FIG. 24 is a schematic cross-sectional view of a light concentration unit 131 of the light concentration layer 13. As illustrated in FIG. 24, the light concentration unit 131 includes a plurality of helical structures 133. Each of the helical structures 133 extends in the first direction A1. That is, a helical axis AXb of each of the helical structures 133 is substantially perpendicular to the optical waveguide layer 1 (specifically, the second main surface F2). A pitch pa of the helical structures 133 indicates one helical period (360 degrees). Each of the helical structures 133 includes a plurality of elements 135. The elements 135 are layered rotating in a helix in the first direction A1.

Each element 135 is a molecule, for example. Specifically, to simplify the drawings of the present application, one element 135 represents and indicates a molecule which is oriented in a direction of average orientation among a plurality of molecules (referred to in the following as a “molecule group”) located on one plane orthogonal to the first direction A1. Accordingly, in each of the helical structures 133, a molecule group is located on one plane orthogonal to the first direction A1. Then, in each helical structure 133, a plurality of molecule groups are lined up in a helix in the first direction A1 with the directions of orientation twisting. Therefore, the element 135 can also be perceived as a molecule group. “Average” in the direction of average orientation refers to “average in time and space”. Here, when the elements 135 are liquid crystal molecules, for example, the one element 135 represents and indicates a liquid crystal molecule oriented toward a director among the plurality of liquid crystal molecules (referred to in the following as a “liquid crystal molecule group”) located on one plane orthogonal to the first direction A1. Therefore, the elements 135 can also be perceived as liquid crystal molecule groups.

The helical structures 133 have selective reflectivity to light similar to the helical structures 311 illustrated in FIG. 2. Specifically, each of the helical structures 133 reflects the light LT13 having a wavelength in the band (i.e., selective reflection band) corresponding to the helical pitch pa and the refractive index of the helical structures 133, and having circular polarization in a direction of circulation that is the same direction as the helical direction of the helix of the helical structures 133. By contrast, each of the helical structures 133 transmits the light LT3. The light LT31 of the light LT3 has the same wavelength as the reflected light LT13 and has circular polarization in a direction of circulation that is opposite to the helical direction of the helix of the helical structures 133. The light LT32 of the light LT3 has a wavelength different from the wavelength of the reflected light LT13.

For example, the helical pitch pa and the refractive index of the helical structures 133 are set according to the wavelength of invisible light so that the helical structures 133 reflect invisible light. In this case, for example, the helical pitch pa and the refractive index of the helical structures 133 are set according to the wavelength of infrared light (e.g., near-infrared light) or ultraviolet light so that the helical structures 133 reflect the infrared light (e.g., near-infrared light) or the ultraviolet light.

Each light concentration unit 131 has a first boundary surface 139, a second boundary surface 141, and a plurality of reflective surfaces 137. In other words, the light concentration layer 13 has the first boundary surface 139, the second boundary surface 141, and the plurality of reflective surfaces 137. The first and second boundary surfaces 139 and 141 are substantially perpendicular to the helical axes AXb of the helical structures 133 and substantially parallel to the optical waveguide layer 1 (specifically, the second main surface F2). In addition, the light concentration unit 131 has a plurality of helical structures 311.

The first boundary surface 139 includes an element 135 located at one end e11 among both ends of each respective helical structure 133. The second boundary surface 141 includes an element 135 located at the other end e12 of both ends of each respective helical structures 133.

Each of the reflective surfaces 137 reflects the light LT13. Specifically, each of the reflective surfaces 137 forms a concave surface recessing toward the second boundary surface 141. Accordingly, the reflective surfaces 137 reflect the light L13 such that the light L13 is concentrated. Specifically, the reflective surfaces 137 reflect the light L13 so as to concentrate the light L13 toward the light diffracting section 3A (FIG. 20). In particular, in the vicinity of the light concentration units 131 where the first boundary surface 139 is in contact with the second main surface F2 of the optical waveguide layer 1 and inside the light concentration unit 131, the reflective surface 137 forms a curved surface. By contrast, in the vicinity of the second boundary surface 141 on the side from which the light LT3 is emitted, the reflective surface 137 may not form a curved surface. That is, in the vicinity of the second boundary surface 141 on the side from which the light LT3 is emitted, the reflective surface 137 may be substantially parallel to the second boundary surface 141. In this case, a light dispersion phenomenon that occurs when the optical device 300 is viewed from the side from which the light LT3 is emitted (from the side of the second boundary surface 141) can be inhibited.

More specifically, the reflective surface 137 can be defined as follows. That is, since the refractive index perceived by the light LT13 (e.g., circularly polarized light) in each light concentration unit 131 gradually changes as the light LT13 progresses in the light concentration unit 131, Fresnel reflection gradually occurs in the light concentration units 131. At a position where the refractive index perceived by the light LT13 changes the most in the light concentration unit 131 (helical structures 133), Fresnel reflection occurs strongest. The reflective surface 137 is a surface where Fresnel reflection occurs strongest in the light concentration unit 131.

In each of the reflective surfaces 137, the directions of orientation of the elements 135 located on the reflective surface 137 are aligned across the helical structures 133. In addition, the spatial phases of two or more of the helical structures 133 are mutually different. As a result, a plurality of reflective surfaces 137 are formed. Therefore, the optical properties of the reflective surfaces 137 indicate the optical properties of the helical structure s133. The spatial phases of the helical structures 133 are described later.

FIG. 25A is a schematic perspective view of the reflective surfaces 137. As illustrated in FIG. 25A, the reflective surfaces 137 are formed spaced at regular intervals and layered along a symmetric axis B1. In the seventh embodiment, the symmetric axis B1 is substantially parallel to the first direction A1. The reflective surfaces 137 are symmetrical to the symmetric axis B1. The reflective surfaces 137 include an inverted dome-shaped reflective surface 137a and an inverted truncated dome-shaped reflective surface 137b.

FIG. 25B is a schematic plan view of a light concentration unit 131 of the light concentration layer 13. As illustrated in FIG. 25B, the spatial phase of a helical structure 133 (FIG. 24) indicates a direction of orientation of a element 135 included in the helical structure 133 on the first boundary surface 139. That is, the spatial phase of a helical structure 133 indicates the direction of orientation of an element 135 located at the end e11 (FIG. 24) of the helical structure 133.

In the seventh embodiment, the light concentration layer 13 is made of liquid crystal. Specifically, the light concentration layer 13 is made of cholesteric liquid crystal. That is, the helical structures 133 of the light concentration layer 13 each are cholesteric liquid crystal. Therefore, each of the elements 135 included in the helical structures 133 is a liquid crystal molecule, for example. In a case where the light concentration layer 13 is made of liquid crystal, for example, the light concentration layer 13 is formed as a film, similarly to the light diffraction layer 3 according to the first embodiment. Otherwise, the light concentration layer 13 (helical structures 133) may be constituted by that in the examples similar to the light diffraction layer 3 (helical structures 311) indicated in the first embodiment.

(Variation)

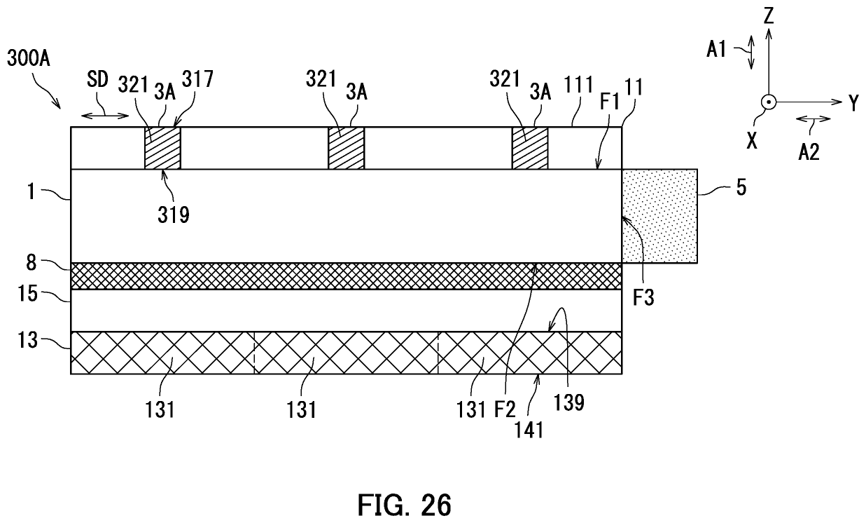

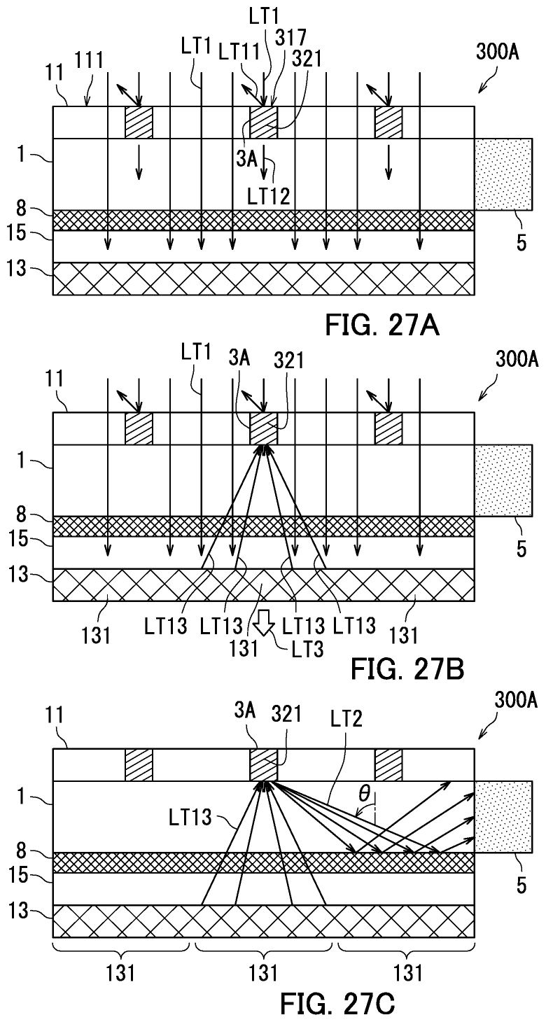

An optical device 300A according to a variation of the seventh embodiment of the present invention is described with reference to FIGS. 26 and 27A to 27C. The variation differs from the seventh embodiment described with reference to FIGS. 20 to 25B in that the optical device 300A according to the variation includes a light reflection layer 8. The following describes the main points of difference between the variation and the seventh embodiment.

FIG. 26 is a schematic cross-sectional view of the optical device 300A according to the variation of the seventh embodiment. As illustrated in FIG. 26, the optical device 300A includes an optical waveguide layer 1, at least one light diffracting section 3A, a light receiving body 5, a retention layer 11, a light concentration layer 13, a light reflection layer 8, and an intermediate layer 15. The optical waveguide layer 1 corresponds to an example of an “optical waveguide section”. The light diffraction section 3A corresponds to an example of a “light diffracting section”. The light concentration layer 13 corresponds to an example of a “light concentrating section”. The light reflection layer 8 corresponds to an example of a “light reflecting section”.

The light reflection layer 8 reflects a portion of the light incident to the light reflection layer 8 and transmits another portion of the light. Otherwise, the configuration and optical properties of the light reflection layer 8 are similar to the configuration and optical properties of the light reflection layer 8 illustrated in FIG. 11. The light reflection layer 8 is opposite to the optical waveguide layer 1 (specifically, the second main surface F2) in the first direction A1. Accordingly, the light reflection layer 8 is opposite to a plurality of light diffracting sections 3A via the optical waveguide layer 1 in the first direction A1. That is, the optical waveguide layer 1 is disposed between the light diffracting sections 3A and the light reflection layer 8.

The intermediate layer 15 transmits light. Specifically, the intermediate layer transmits visible and invisible light. Accordingly, the intermediate layer 15 is transparent. The intermediate layer 15 is composed of synthetic resin or glass, for example. The intermediate layer 15 is disposed between the light reflection layer 8 and the light concentration layer 13. Note that the optical device 300A need not include an intermediate layer 15.

The light concentration layer 13 is opposite to the light reflection layer 8 with the intermediate layer 15 therebetween in the first direction A1. The light concentration layer 13 is disposed at a position more separated from the optical waveguide layer 1 than the light reflection layer 8. The light reflection layer 8 and the intermediate layer 15 are arranged between the optical waveguide layer 1 and the light concentration layer 13. The light reflection layer 8 and the intermediate layer 15 are arranged between the light diffracting sections 3A and the light concentration layer 16.

Next, the operation of the optical device 300A is described with reference to FIGS. 27A to 27C. FIGS. 27A to 27C are diagrams for describing the operation of the optical device 300A. Note that in the description of FIGS. 27A to 27C, light is appropriately omitted for similar reasons to those for FIGS. 22A to 22C.

As illustrated in FIG. 27A, the light LT1 is incident to the light diffracting sections 3A and the retention layer 11 from a side opposite to the side on which the light concentration layer 13 and the light reflection layer 8 are arranged.

The light diffracting section 3A diffracts (specifically, reflects and diffracts) the light LT11 in a wavelength band which is a portion of the wavelength band of the light LT1 toward a side opposite to the side on which the optical waveguide layer 1 is located. This point is similar to the seventh embodiment described with reference to FIG. 22A.

By contrast, the retention layer 11 transmits the light LT1 and allows the light LT1 to enter the optical waveguide layer 1. This point is similar to the seventh embodiment described with reference to FIG. 22A.

Then, the optical waveguide layer 1 transmits the light LT1 and allows the light LT1 to be incident to the light concentration layer 13 via the light reflection layer 8 and the intermediate layer 15. Specifically, the optical waveguide layer 1 transmits the light LT1 and allows the light LT1 to be incident to the light reflection layer 8. The light reflection layer 8 transmits the light LT1 and allows the light LT1 to be incident to the intermediate layer 15. The intermediate layer 15 transmits the light LT1 and allows the light LT1 to be incident to the light concentration layer 13. The light LT1 preferably includes visible and invisible light.

Furthermore, as illustrated in FIG. 27B, the light concentration layer 13 allows the light LT13 in at least a portion of the wavelength band of the light LT1 incident to the light concentration layer 13 from the retention layer 11, the optical waveguide layer 1, the light reflection layer 8, and the intermediate layer 15 between adjacent light diffracting sections 3A to be incident to the light diffracting sections 3A via the optical waveguide layer 1 while concentrating the light LT13 toward the light diffracting sections 3A. That is, the light concentration layer 13 allows the light LT13 in at least a portion of the wavelength band of the light LT1 incident to the light concentration layer 13 through the optical waveguide layer 1 from a side on which the light diffracting sections 3A are located to be incident to the light diffracting sections 3A via the optical waveguide layer 1 while concentrating the light LT13 toward the light diffracting sections 3A. Specifically, the light LT13 reflected by the light concentration layer 13 enters the optical waveguide layer 1 through the intermediate layer 15 and the light reflection layer 8 and is further incident to the light diffracting sections 3A. Note that the intermediate layer 15 and the light reflection layer 8 transmit the light LT13 reflected by the light concentration layer 13.

The light concentration layer 13 transmits the light LT3 in a different wavelength band from that of the light LT13 of the incident light LT1. This point is similar to the seventh embodiment described with reference to FIG. 22B.

Furthermore, as illustrated in FIG. 27C, the light diffracting sections 3A diffract (specifically, reflect and diffract) the light LT2 in a wavelength band which is a portion or the entirety of the wavelength band of the light LT13 incident to the light diffracting sections 3A from the light concentration layer 13 toward the optical waveguide layer 1, and allow the light LT2 to enter the optical waveguide layer 1. This point is similar to the seventh embodiment described with reference to FIG. 22C.

The optical waveguide layer 1 guides the light LT2 diffracted (specifically, reflected and diffracted) by the light diffracting sections 3A and entering inside the optical waveguide layer 1. This point is similar to the seventh embodiment described with reference to FIG. 22C. Also, the light reflection layer 8 reflects the light LT2 entering the light optical waveguide layer 1 toward the optical waveguide layer 1 such that the light LT2 entering the optical waveguide layer 1 from the light diffracting sections 3A is totally reflected in the optical waveguide layer 1. Therefore, according to the variation, the light LT2 can be effectively inhibited from leaking out of the optical waveguide layer 1. As a result, a light quantity received per unit of time by the light receiving body 5 can be increased. In particular, in a case where the light receiving body 5 is a solar cell, the amount of electricity generated by the solar cell can be increased.

In the seventh embodiment and the variation described with reference to FIGS. 20 to 27C, the optical devices 300 and 300A need not include the retention layer 11. Furthermore, in the optical device 300A according to the variation, the light reflection layer 8 may be an air layer made from a void. In this case, for example, a spacer is disposed between the optical waveguide layer 1 and the intermediate layer 15. Note that in a case where the optical device 300A does not include an intermediate layer 15, for example, a spacer is disposed between the optical waveguide layer 1 and the light concentration layer 13.

In the seventh embodiment and the variation, the light diffracting sections 3A may be layered in the first direction A1 similarly to the second embodiment described with reference to FIG. 9. The optical devices 300 and 300A may also include either or both of the light reflection layers 8a and 8b described with reference to FIG. 11. In this case, the light diffraction sections 3A and the light concentration layer 13 may be arranged between the light reflection layers 8a and 8b, only the light reflection layer 8a may be disposed opposite to the first boundary surface 317 of the light diffracting sections 317 and the main surface 111 of the retention layer 11, or only the light reflection layer 8b may be disposed opposite to the second boundary surface 141 of the light concentration layer 13. In addition, the optical devices 300 and 300A according to the seventh embodiment and the variation can be applied to the fourth and fifth embodiments and the variations described with reference to FIGS. 12 to 14.

Here, in the first to seventh embodiments (including the variations) described with reference to FIGS. 1 to 27C, the refractive index of the optical waveguide layer 1 is substantially identical across the entire optical waveguide layer 1. However, the refractive index may change inside the optical waveguide layer 1. That is, the optical waveguide layer 1 may have a distribution of refractive indices, and different refractive indices may be distributed inside the optical waveguide layer 1. That is, the optical waveguide layer 1 may be a refractive index-distributed element (graded-index (GRIN) element). In this case, for example, regions with a low refractive index and regions with a high refractive index may be present alternating in the second direction A2 inside the optical waveguide layer 1. Furthermore, the optical waveguide layer 1 may be single-layered or multi-layered.

Either or both of an anti-reflection coating and a protective layer may be arranged on the first main surface F1 of the optical waveguide layer 1 in FIGS. 1, 9, and 12 to 14 to facilitate the entry of light to the optical waveguide layer 1. A protective layer may be disposed on the second boundary surface 319 of the light diffraction layers 3 and 3X in FIGS. 1, 7, 9, and 12 to 14. Either or both of an anti-reflection coating and a protective layer may also be arranged on the surface of the light reflection layer 8a in FIG. 11 to facilitate the entry of light to the light reflection layer 8a. A protective layer may be disposed on the surface of the light reflection layer 8b in FIG. 11. In addition, either or both of an anti-reflection coating and a protective layer may be arranged on the first boundary surface 717 of each light diffraction layer 7 and 7X in FIGS. 16 and 18 to facilitate the entry of light to the light diffraction layers 7 and 7X. A protective layer may be disposed on the second main surface F2 of the optical waveguide layer 1 in FIG. 15. Either or both of an anti-reflection coating and a protective layer may be arranged on the first boundary surface 317 of each light diffracting section 3A and the main surface 111 of the retention layer 11 in FIGS. 20 and 26. A protective layer may be disposed on the second boundary surface 141 of the light concentration layer 13.

An additional functional layer (e.g., heat ray cutting film) may also be disposed on any of the first main surface F1 of the optical waveguide layer 1 in FIGS. 1, 9, and 12 to 14, the second boundary surface 319 of the light diffraction layer 3 or 3X in FIGS. 1, 7, 9, and 12 to 14, the surface of the light reflection layer 8a or 8b in FIG. 11, the first boundary surface 717 of the light diffraction layer 7 or 7X in FIGS. 16 and 18, the second main surface F2 of the optical waveguide layer 1 in FIG. 15, the first boundary surface 317 of each light diffracting section 3A and the main surface 111 of the retention layer 11 in FIGS. 20 and 26, and the second boundary surface 141 of the light concentration layer 13 in FIGS. 20 and 26.

When the light diffraction layers 3, 3X, 7, and 7X, the light diffracting sections 3A, the retention layer 11, and the light concentration layer 13 is made of liquid crystal as described with reference to FIGS. 1 to 27C, the optical devices 100, 100A to 100D, 100X, 200, 300, and 300A include orientation layers, which are omitted for simplification of the drawings.

Next, the present invention is specifically described based on a practical example, but the present invention is not limited by the following practical example.

### Practical Example

An optical device 100 including a light diffraction layer 3 according to a practical example of the present invention is described with reference to FIGS. 1 to 3 and 28 to 30. In the present practical example, the light diffraction layer 3 having the structure illustrated in FIGS. 2 and 3 was made of cholesteric liquid crystal. A mixture of a photopolymerizable liquid crystal monomer (RM257, product of Synthon Chemicals), a chiral agent (R-5011, product of HCCH), a surface modifier (BYK-361N, product of BASF), and a polymerization initiator (Irgacure 819, product of BASF) was used as the liquid crystal material of the cholesteric liquid crystal. Note that non-polymerizable liquid crystal or a thermally polymerizable monomer that do not exhibit photopolymerizability may be used as the liquid crystal material. A material that exhibits photopolymerizability may also be used as a chiral agent to induce helical structures of cholesteric liquid crystal. Specifically, a cholesteric liquid crystal film was prepared as follows.

First, a photo-orientation agent (B0783, product of Tokyo Chemical Industry Co., Ltd.) was applied and deposited on a glass substrate. The thickness of the glass substrate was 0.7 mm.

Next, after deposition with the photo-orientation agent, a spatial distribution of linearly polarized light was formed by interference of circularly polarized laser light (wavelength: 488 nm) on the glass substrate, and pattern orientation treatment was performed on the orientation film on the glass substrate. As a result, an orientation film in which orientation-regulating force on the liquid crystal has been patterned was formed on the glass substrate. Note that other than the azobenzene-based material used in the present practical example, a photopolymerization-type material or a photodegradation-type material can be used as the photo-orientation agent. When a photo-orientation agent is used, the laser light used for the pattern orientation treatment preferably has an absorption wavelength band that overlaps with the absorption wavelength band of the photo-orientation agent.

Next, a cholesteric liquid crystal film was prepared by bringing the liquid crystal material into contact with the orientation film. Specifically, a cholesteric liquid crystal film was prepared by dropping a toluene solution which dissolved the cholesteric liquid crystal onto the glass substrate subjected to the pattern orientation treatment and spin coating the glass substrate. The thickness of the cholesteric liquid crystal film was approximately 3 μm.

The liquid crystal deposition method may be a coating deposition method such as spin coating. Alternatively, a sandwich structure may be adopted in which an orientation film is formed on each of two glass substrates and the liquid crystal material is injected between the orientation films of the two glass substrates.

Specifically, an orientation-regulating orientation (orientation easy axis) of the long axis of the liquid crystal molecules in contact with the orientation film was linearly changed with a period A (refer to FIG. 3A) of approximately 600 nm. As a result, a cholesteric liquid crystal film with the orientation pattern illustrated in FIG. 3A were prepared. In the present practical example, the cholesteric liquid crystal film was used as the light diffraction layer 3 in FIG. 1.

In the present practical example, the glass substrate on which an orientation film has been formed was used as the optical waveguide layer 1 in FIG. 1. The refractive index of the glass substrate was approximately 1.53.

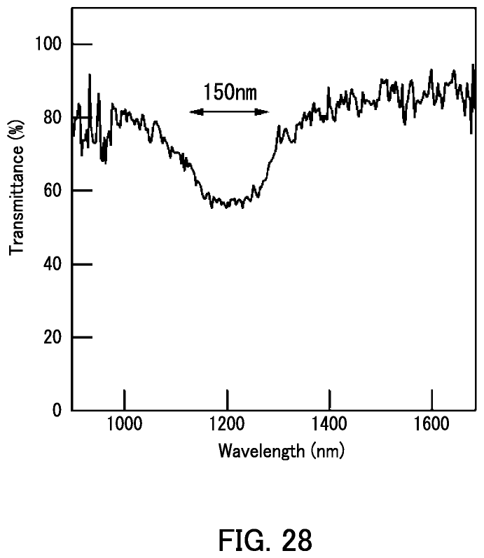

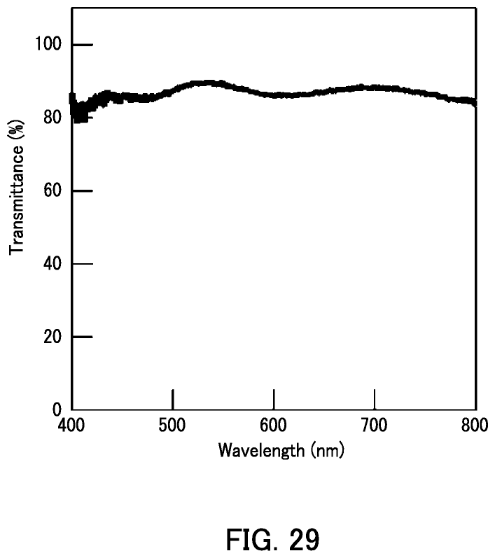

The light transmittance characteristics of the cholesteric liquid crystal film according to the present practical example were verified. Verification results are shown in FIGS. 28 and 29.

FIG. 28 is a diagram illustrating the light transmittance characteristics (near-infrared wavelength range) of the cholesteric liquid crystal film according to the present practical example. The horizontal axis indicates the wavelength (nm) of light and the vertical axis indicates the transmittance (%) of light in the cholesteric liquid crystal film. FIG. 28 illustrates light transmittance in the near-infrared wavelength range (i.e., the invisible wavelength range).

As illustrated in FIG. 28, a drop in transmittance with a bandwidth of about 150 nm, originating in the periodic structure of the cholesteric liquid crystal, was observed around a wavelength of 1200 nm. In other words, a Bragg reflection with a bandwidth of about 150 nm, originating in the periodic structure of the cholesteric liquid crystal, was observed around a wavelength of 1200 nm. In yet other words, it was confirmed that the cholesteric liquid crystal film according to the present practical example reflected light in the invisible wavelength range.

FIG. 29 is a diagram illustrating the light transmittance characteristics (visible wavelength range) of the cholesteric liquid crystal film according to the present practical example. The horizontal axis indicates the wavelength (nm) of light and the vertical axis indicates the transmittance (%) of light in the cholesteric liquid crystal film. FIG. 29 illustrates light transmittance in the visible wavelength range.

As illustrated in FIG. 29, the transmittance of light in the cholesteric liquid crystal film according to the present practical example indicated 80% or greater in the visible wavelength range. In other words, it was confirmed that the cholesteric liquid crystal film according to the present practical example transmitted light in the invisible wavelength range.

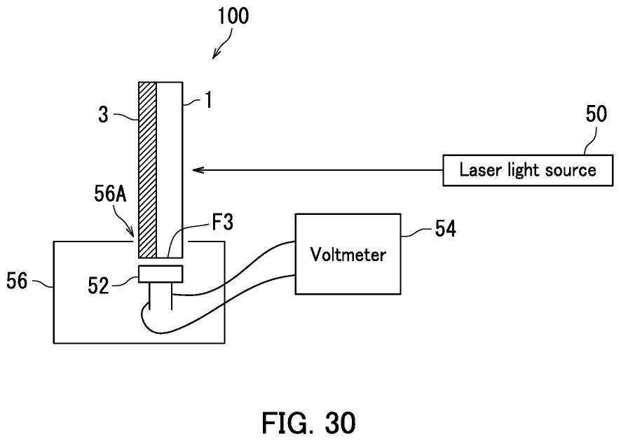

The operation of the optical device 100 was verified by making the cholesteric liquid crystal film and the glass substrate according to the present practical example function as the light diffraction layer 3 and the optical waveguide layer 1 in FIG. 1, respectively. The experimental facilities for this case are illustrated in FIG. 30.

FIG. 30 is a diagram illustrating facilities for performing operation experiments on the optical device 100 including the light diffraction layer 3 and the optical waveguide layer 1 according to the present practical example. As illustrated in FIG. 30, the light diffraction layer 3 (cholesteric liquid crystal film in the present practical example), the optical waveguide layer 1 (glass substrate in the present practical example), a laser light source 50, a photodetector 52, a voltmeter 54, and a box 56 were prepared.

The photodetector 52 corresponded to the light receiving body 5 in FIG. 1. Thus, the optical waveguide layer 1, the light diffraction layer 3, and the photodetector 52 substantially constituted the optical device 100.

The wavelength of the laser light emitted by the laser light source 50 was approximately 1020 nm, which is an invisible wavelength. The photodetector 52 included a photodiode. A slit-shaped opening 56A was formed in the box 56.

An end (including the end surface F3 of the optical waveguide layer 1) of the optical device 100 was inserted into the box 56 through the opening 56A. Also, the photodetector 52 was installed inside the box 56. Accordingly, ambient light was prevented from being incident to the photodetector 52. Furthermore, the photodetector 52 was opposite to the end surface F3 of the optical waveguide layer 1. The voltage output by the photodetector 52 was observed with the voltmeter 54. The photodetector 52 was an optical sensor that output a voltage with a magnitude proportional to the quantity of received light. In other words, the photodetector 52 corresponded to a solar cell which generates an electromotive force with a magnitude proportional to the quantity of the received light.

In a state where the optical waveguide layer 1 and the light diffraction layer 3 were not irradiated with laser light, the voltage output by the photodetector 52 was approximately 0 V according to the voltmeter 54. That is, the photodetector 52 did not detect light. As such, it was confirmed that no light was not emitted from the end surface F3 of the optical waveguide layer 1 in the state where the optical waveguide layer 1 and the light diffraction layer 3 were not irradiated with laser light. In addition, the optical device 100 was visually transparent. That is, it was confirmed that the optical waveguide layer 1 and the light diffraction layer 3 transmitted visible light.

By contrast, the laser light source 50 irradiated laser light substantially perpendicular to the optical waveguide layer 1 and the light diffraction layer 3. In a state where the optical waveguide layer 1 and the light diffraction layer 3 were irradiated with laser light, the maximum voltage output by the photodetector 52 was about 0.4 V according to the voltmeter 54. That is, the photodetector 52 detected (received) light and generated electromotive force. As such, it was confirmed that in a state where the optical waveguide layer 1 and the light diffraction layer 3 were irradiated with laser light, light was emitted from the end surface F3 of the optical waveguide layer 1 and the photodetector 52 generated electromotive force. In addition, the optical device 100 was visually transparent. That is, it was confirmed that the optical waveguide layer 1 and the light diffraction layer 3 transmitted visible light.

That is, it was observed that when the light diffraction layer 3 deflected invisible light and the optical waveguide layer 1 guided and emitted the deflected invisible light from the end surface F3, the invisible light was incident to the photodetector 52 and the photodetector 52 generated electromotive force by the incidence of the invisible light. In addition, it was observed that the optical device 100 was transparent when viewed by a person even while the photodetector 52 generated electromotive force by the incidence of the invisible light.

Furthermore, it was confirmed that light was guided to the photodetector 52 by the optical waveguide layer 1 even when the photodetector 52 was installed in a shaded place. This indicated, for example, that the optical waveguide layer 1 guided light (e.g., sunlight) to the light receiving body 5 (corresponding to photodetector 52) such as a solar cell even when the light receiving body 5 such as a solar cell was installed in a place where light (e.g., sunlight) had difficulty reaching or a shaded place. For example, in a case where the present invention is applied to a window, it was inferred that sunlight could be guided from window glass functioning as the optical waveguide layer 1 to the light receiving body 5 as a solar cell even when the light receiving body 5 as a solar cell was disposed on the window frame.

As described above, it was observed that the optical device 100 reflected and deflected light according to the orientation pattern of the cholesteric liquid crystal film constituting the light diffraction layer 3.

Embodiments of the present invention are described above with reference to the accompanying drawings. However, the present invention is not limited to the above embodiments and can be implemented in various forms without departing from the gist thereof. Furthermore, a plurality of constituent elements disclosed in the above embodiments can be appropriately altered. For example, a constituent element among all the constituent elements illustrated in an embodiment may be added to the constituent elements in another embodiment, or some constituent elements among all the constituent elements illustrated in an embodiment may be removed from the embodiment.

In order to facilitate understanding of the invention, the drawings illustrate respective constituent elements mainly schematically, and aspects such as the thickness, length, number, and interval of each illustrated constituent element may differ from actual ones for the convenience of drawing preparation. It goes without saying that the configuration of each constituent element illustrated in the above embodiments is an example and is not a particular limitation, and that various changes are possible to the extent that they do not substantially deviate from the effects of the present invention.

### INDUSTRIAL APPLICABILITY

The present invention provides a solar cell device and an optical device, and has industrial applicability.

### REFERENCE SIGNS LIST

1 Optical waveguide layer (optical waveguide section)
3, 3a, 3b, 3X, 7, 7X Light diffraction layer (light diffracting section)
3A Light diffracting section
5, 5a, 5b Light receiving body (solar cell)
8, 8a, 8b Light reflection layer (light reflecting section)
13 Light concentration layer (light concentrating section)
100, 100A to 100D, 100X Optical device (solar cell device)
200 Optical device (solar cell device)
300, 300A Optical device (solar cell device)
311 Helical structure
400 Optic axis
AX Helical axis
   AR Optical waveguide region

1. A solar cell device comprising:
an optical waveguide section;
a solar cell; and
a light diffracting section disposed in a different layer level from the optical waveguide section and opposite to the optical waveguide section, wherein
the light diffracting section diffracts light in at least a portion of a wavelength band of light incident to the light diffracting section toward the optical waveguide section, and allows the light in at least the portion of the wavelength band to enter the optical waveguide section,
the optical waveguide section guides the light entering inside the optical waveguide section by diffraction by the light diffracting section, and
the solar cell receives the light guided by the optical waveguide section and converts energy of the received light to electrical power.

2. The solar cell device according to claim 1, wherein
the light diffracting section has optical anisotropy and a plurality of optic axes, and
the light diffracting section diffracts the light in at least the portion of the wavelength band of the light incident to the light diffracting section toward the optical waveguide section according to a distribution of orientations of the optic axes.

3. The solar cell device according to claim 1, wherein
the optical waveguide section transmits light including visible light, and
the light diffracting section
reflects and diffracts the light in at least the portion of the wavelength band of the light incident to the light diffracting section through the optical waveguide section toward the optical waveguide section, and
transmits light in at least a portion of a wavelength band of a visible light region of the light incident to the light diffracting section, and
the optical waveguide section guides the light entering inside the optical waveguide section by reflection and diffraction by the light diffracting section.

4. The solar cell device according to claim 1, wherein
the light diffracting section transmits and diffracts the light in at least the portion of the wavelength band of the light incident to the light diffracting section toward the optical waveguide section, and
the optical waveguide section guides the light entering inside the optical waveguide section by transmission and diffraction by the light diffracting section.

5. The solar cell device according to claim 1, further comprising
a light concentrating section, wherein
the optical waveguide section is disposed between the light diffracting section and the light concentrating section,
the light diffracting section covers a portion of a main surface of the optical waveguide section, and
the light concentrating section allows, while concentrating toward the light diffracting section, the light in at least a portion of a wavelength band of light incident to the light concentrating section through the optical waveguide section from a side on which the light diffracting section is located to be incident to the light diffracting section.

6. The solar cell device according to claim 1, wherein
the light diffracting section is provided as a plurality of light diffracting sections,
the light diffracting sections are layered, and
the light diffracting sections diffract either or both of light rays in mutually different wavelength bands and light rays having mutually different polarization toward the optical waveguide section, and allow the light rays to enter inside the optical waveguide section.

7. The solar cell device according to claim 1, further comprising
at least one light reflecting section, wherein
the at least one light reflecting section reflects the light entering the optical waveguide section from the light diffracting section toward the optical waveguide section so that the light entering the optical waveguide section is totally reflected in the optical waveguide section, or reflects, of the light entering the optical waveguide section from the light diffracting section, light emitted from the optical waveguide section toward the optical waveguide section so that the light emitted from the optical waveguide section is totally reflected in the optical waveguide section.

8. The solar cell device according to claim 7, wherein
a refractive index of the at least one light reflecting section is smaller than a refractive index of the optical waveguide section.

9. The solar cell device according to claim 7, wherein
the at least one light reflecting section is a mirror with a dependency on a wavelength of light in light reflection and a dependency on an incident angle of light in the light reflection.

10. The solar cell device according to claim 1, wherein
the light diffracting section diffracts the light in at least the portion of the wavelength band toward the optical waveguide section so that the light guided by the optical waveguide section is concentrated toward the solar cell, and allows the light in at least the portion of the wavelength band to enter inside the optical waveguide section.

11. The solar cell device according to claim 1, wherein
the solar cell is provided as a plurality of solar cells,
the light diffracting section is provided as a plurality of light diffraction sections arranged on the same layer level as each other,
the optical waveguide section is divided into a plurality of optical waveguide regions,
the solar cells are arranged corresponding to the respective optical waveguide regions,
the light diffracting sections are arranged corresponding to the respective optical waveguide regions,
the light diffracting sections each are opposite to a corresponding one of the optical waveguide regions,
the light diffracting sections each diffract light toward the corresponding one of the optical waveguide regions so that the light is guided inside the corresponding one of the optical waveguide regions toward a corresponding one of the solar cells and allows the light to enter inside the corresponding one of the optical waveguide regions, and
the solar cells each receive the light guided by the corresponding one of the optical waveguide regions.

12. The solar cell device according to claim 1, wherein
the light diffracting section includes a plurality of helical structures,
helical axes of the helical structures are substantially perpendicular to the optical waveguide section and spatial phases of two or more of the helical structures are mutually different, or
the helical axes of the helical structures are inclined relative to the optical waveguide section.

13. An optical device comprising:
an optical waveguide section;
a light receiving body; and
a light diffracting section disposed in a different layer level from the optical waveguide section and located opposite to the optical waveguide section, wherein
the light diffracting section has optical anisotropy and a plurality of optic axes,
the light diffracting section diffracts light in at least a portion of a wavelength band of light incident to the light diffracting section toward the optical waveguide section according to a distribution of orientations of the optic axes, and allows the light in at least the portion of the wavelength band to enter the optical waveguide section,
the optical waveguide section guides the light entering inside the optical waveguide section by diffraction by the light diffracting section, and
the light receiving body receives the light guided by the optical waveguide section.

14. The optical device according to claim 13, wherein
the light diffracting section is made of liquid crystal.
